(19) United States
(12) Patent Application Publication
(10) Pub. No.: US 2025/0226227 A1
(43) Pub. Date: Jul. 10, 2025

(54) DEPOSITION OF METAL-CONTAINING FILMS AND CHAMBER CLEAN

(71) Applicant: Lam Research Corporation, Fremont, CA (US)

(72) Inventors: Dustin Zachary Austin, Tigard, OR (US); Bryce Isaiah Edmondson, Portland, OR (US); Dennis M. Hausmann, Lake Oswego, OR (US); Malak Khojasteh, Happy Valley, OR (US); Matthew Palmer Kwan, Pleasanton, CA (US); Esther Jeng, Los Altos, CA (US); Yuxi Wang, Beaverton, OR (US); Bo Gong, Sherwood, OR (US); Andrew John McKerrow, Lake Oswego, OR (US); Kyle Watt Hart, Beaverton, OR (US); Rachel E. Batzer, Tigard, OR (US); Tongtong Guo, Beaverton, OR (US); Hector Aaron Fuster, Portland, OR (US); Boris Volosskiy, San Jose, CA (US); Francisco J. Juarez, West Linn, OR (US); David Alan Tence, Tualatin, OR (US); Emile C. Draper, Molalla, OR (US); Jeya Prakash Ganesan, Beaverton, OR (US); Ann Erickson, Lake Oswego, OR (US); Phuong Kim Ta, Beaverton, OR (US)

(21) Appl. No.: 18/852,644

(22) PCT Filed: Apr. 5, 2023
(86) PCT No.: PCT/US2023/017635

§ 371 Date: Sep. 30, 2024

Related U.S. Application Data
(60) Provisional application No. 63/377,844, filed on Sep. 30, 2022.
(60) Provisional application No. 63/362,591, filed on Apr. 6, 2022.

(51) Int. Cl. H01L 21/285; B08B 7/00; B08B 9/00; C23C 16/44

(52) U.S. Cl. CPC H01L 21/28568; B08B 7/0035; B08B 9/00; C23C 16/4405

(57) ABSTRACT

Methods of forming a metal-containing layer on a semiconductor substrate are provided and may include performing multiple cycles of (a) co-flowing a metal-containing precursor and a reactant into a processing chamber housing the semiconductor substrate; and (b) after (a), flowing the reactant into a processing chamber housing the semiconductor substrate, wherein the reactant does not react with gas-phase metal-containing precursor. Methods of cleaning the processing chamber are also provided.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

In integrated circuit (IC) fabrication, deposition and etching techniques are used for forming patterns of materials, such as for forming metal lines embedded in dielectric layers. Some patterning schemes require conformal deposition of materials, where the deposited layer should follow the contour of protrusions and/or recessed features on the surface of the substrate. Atomic layer deposition (ALD) is often a preferred method of forming conformal films on a substrate, because ALD relies on adsorption of one or more reactants (precursors) to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, this method can provide thin conformal layers having excellent step coverage.

Chemical vapor deposition (CVD) is another deposition method widely used in semiconductor processing. In CVD, the reaction occurs in the volume of the process chamber and is not limited by the amount of reactants adsorbed to the substrate. As a result, CVD-deposited films are often less conformal than ALD-deposited films. CVD is typically used in applications where step coverage is less important.

ALD and CVD may employ plasma to promote the reactions of the deposition precursors resulting in the formation of the desired films. The methods that make use of the plasma are known as plasma enhanced ALD (PEALD) and plasma enhanced CVD (PECVD). The methods that do not employ plasma are referred to as thermal ALD and thermal CVD.

While ALD and CVD are most commonly used for deposition of silicon-containing films, such as silicon oxide, silicon nitride, and silicon carbide, these methods are also suitable for deposition of some metals, most notably tungsten and cobalt.

Some semiconductor fabrication processes deposit thin films on a substrate in a process chamber. The material of the thin films may also be deposited on the interior surfaces of a process chamber, thereby forming a wall deposit. After the wall deposit reaches a particular thickness or condition-typically after many wafers are processed in the process chamber—the deposit may interfere with the deposition process. Therefore, the wall deposit may need to be cleaned from the interior surfaces of the process chamber.

The background description provided herein is for the purposes of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

### SUMMARY

One aspect involves a method of forming a metal-containing layer on a semiconductor substrate, where the method includes performing multiple cycles of (a) co-flowing a metal-containing precursor and a reactant into a processing chamber housing the semiconductor substrate; and (b) after (a), flowing the reactant into a processing chamber housing the semiconductor substrate, wherein the reactant does not react with gas-phase metal-containing precursor.

In some embodiments, (b) comprises reacting surface-bound metal-containing precursor with the reactant in an absence of plasma to form a metal-containing layer on the semiconductor substrate.

In some embodiments, the formed metal-containing layer is a substantially carbon-free molybdenum-containing or tungsten-containing layer that has a carbon content of less than about 5 atomic %, wherein the layer is selected from the group consisting of Mo, W, MoN, WN, MoON, WON, MoB, WB, MoSi, WSi layer and combinations thereof.

In some embodiments, the metal-containing precursor is a halide-free, carbonyl-free compound that comprises at least one ligand, bound to a metal selected from the group consisting of molybdenum and tungsten.

In some embodiments, the halide-free, carbonyl-free compound does not include metal-carbon bonds and metal-oxygen double bonds.

In some embodiments, the formed metal-containing layer has a carbon content of less than about 2 atomic %.

In some embodiments, the metal-containing precursor does not include beta-hydrogen atoms.

In some embodiments, the formed metal-containing layer is selected from the group consisting of Mo, MoN, and MoON.

In some embodiments, the reactant is hydrogen (H₂).

In some embodiments, the reactant is introduced at a pressure of at least 10 Torr.

In some embodiments, the reactant is introduced at a pressure of at least 100 Torr.

Another aspect involves a method of cleaning a process chamber, where the method includes flowing a fluorine-containing species into the process chamber. The process chamber includes a molybdenum-containing film formed on interior surfaces of the process chamber. The method also includes flowing an oxygen-containing species into the process chamber with the fluorine-containing species cyclically or simultaneously to clean the process chamber, wherein the molybdenum-containing film is removed from the interior surfaces of the process chamber.

In some embodiments, the fluorine-containing species includes nitrogen trifluoride (NF₃), molecular fluorine (F₂), carbon tetrafluoride (CF₄), carbon hexafluoride (C₂F₆), xenon difluoride (XeF₂), fluoromethane (CH₃F), difluoromethane (CH₂F₂), tetrafluoroethylene (C₂F₄), hexafluoroethane (C₂F₆), octafluoropropane (C₃F₈), sulfur hexafluoride (SF₆), fluorine-containing plasma, or mixtures thereof.

In some embodiments, the oxygen-containing species includes oxygen (O₂), ozone (O₃), carbon monoxide (CO), carbon dioxide (CO₂), nitrous oxide (N₂O), nitrogen dioxide (NO₂), oxygen-containing plasma, or mixtures thereof.

In some embodiments, the method also includes generating fluorine-containing radicals in a remote plasma source. The fluorine-containing species includes the fluorine-containing radicals. The method also includes generating oxygen-containing radicals in the remote plasma source. The oxygen-containing species includes the oxygen-containing radicals.

In some embodiments, the fluorine-containing species and the oxygen-containing species are flowed cyclically towards the interior surfaces of the process chamber.

In some embodiments, the fluorine-containing species and the oxygen-containing species are co-flowed simultaneously towards the interior surfaces of the process chamber.

In some embodiments, the method also includes depositing, in the process chamber, a molybdenum-containing layer on a substrate. A molybdenum-containing film is formed on the interior surfaces of the process chamber after depositing the molybdenum-containing layer on the substrate.

In some embodiments, the molybdenum-containing layer is deposited on the substrate by atomic layer deposition (ALD), plasma-enhanced atomic layer deposition (PEALD), chemical vapor deposition (CVD), or plasma-enhanced chemical vapor deposition (PECVD).

In some embodiments, the method also includes transferring the substrate out of the process chamber after depositing the molybdenum-containing layer and prior to cleaning the process chamber; and adjusting a chamber pressure of the process chamber to a high-pressure regime between about 2 Torr and about 6 Torr or a low-pressure regime between about 0.5 Torr and about 2 Torr after transferring the substrate out of the process chamber.

In some embodiments, the process chamber is cleaned for a first duration at a first chamber pressure that is between about 2 Torr and about 6 Torr and for a second duration at a second chamber pressure that is between about 0.5 Torr and about 2 Torr.

In some embodiments, for the first duration, an argon gas flows at a flow rate of about 1 to about 2 standard liter per minute, a nitrogen trifluoride gas flows at a flow rate of about 0.5 to about 3 standard liter per minute, and an oxygen gas flows at a flow rate of about 0.5 to about 2 standard liter per minute.

In some embodiments, for the second duration, an argon gas flows at a flow rate of about 0.5 to about 2 standard liter per minute, a nitrogen trifluoride gas flows at a flow rate of about 0.5 to about 1.5 standard liter per minute, and an oxygen gas flows at a flow rate of about 0.5 to about 1.5 standard liter per minute.

In some embodiments, the molybdenum-containing film includes undoped or carbon-doped molybdenum oxide, undoped or carbon-doped molybdenum nitride, undoped or carbon-doped molybdenum oxynitride, or mixtures thereof. In some embodiments, the molybdenum-containing film includes molybdenum metal.

In some embodiments, the molybdenum-containing film includes carbon, and the oxygen-containing species oxidizes the carbon to remove the carbon from the interior surfaces of the process chamber.

In some embodiments, the process chamber is at a temperature of about 200° C. to about 650° C. during the clean of the process chamber.

In some embodiments, a first duration of the clean exposes the interior surfaces of the process chamber to plasma of the fluorine-containing species and plasma of the oxygen-containing species, and a second duration of the clean exposes the interior surfaces of the process chamber to the fluorine-containing species and the oxygen-containing species in a plasma-free environment.

In some embodiments, the molybdenum-containing film is formed by reducing a molybdenum oxynitride film by one or more reducing agents, and the one or more reducing agents include nitrogen, argon, hydrogen, ammonia, other hydrogen-containing gases, or mixtures thereof.

Still another aspect involves a method of cleaning a process chamber, the method including providing the process chamber including interior surfaces deposited with a carbon-containing molybdenum nitride film: exposing the interior surfaces of the process chamber to fluorine-containing radicals to react with the carbon-containing molybdenum nitride film and remove at least some of the carbon-containing molybdenum nitride film; and exposing the interior surfaces of the process chamber to oxygen-containing radicals to oxidize at least carbon in the carbon-containing molybdenum nitride film. The fluorine-containing radicals and the oxygen-containing radicals are generated from a remote plasma source fluidly coupled to the process chamber. The fluorine-containing radicals and the oxygen-containing radicals are flowed cyclically or co-flowed simultaneously towards the interior surfaces of the process chamber to clean the process chamber.

In some embodiments, oxidizing the carbon includes generating carbon oxide, carbon dioxide, or mixtures thereof from the carbon-containing molybdenum nitride film.

In some embodiments, the fluorine-containing radicals and the oxygen-containing radicals are generated in the remote plasma source and co-flowed simultaneously into the process chamber.

In some embodiments, the process chamber is cleaned for a first duration at a first chamber pressure that is between about 2 and about 6 Torr and for a second duration at a second chamber pressure that is between about 0.5 and about 2 Torr.

In some embodiments, the method also includes depositing, in the process chamber, a molybdenum-containing layer on a substrate. A carbon-containing molybdenum nitride film is formed on the interior surfaces of the process chamber. Depositing the molybdenum-containing layer includes flowing molybdenum-containing precursors from a first manifold into the process chamber. The method also includes cleaning, in the process chamber, the carbon-containing molybdenum nitride film from the interior surfaces of the process chamber by flowing the fluorine-containing radicals and the oxygen-containing radicals from a second manifold into the process chamber.

Still yet another aspect involves an apparatus, the apparatus including: a process chamber including a chuck configured to support a substrate: one or more gas outlets coupled to the process chamber and configured to introduce a fluorine-containing species and an oxygen-containing species into the process chamber: one or more remote plasma sources fluidly coupled to the process chamber by one or more gas inlets: one or more second gas outlets coupled to the process chamber and configured to introduce molybdenum-containing precursors into the process chamber; and a controller having at least one processor and a memory. The memory includes computer-executable instructions for controlling the at least one processor for: flowing the molybdenum-containing precursors into the process chamber via the one or more second gas outlets to expose the substrate to the molybdenum-containing precursors, wherein a molybdenum-containing film is deposited on interior surfaces of the process chamber: introducing a fluorine-containing source gas into the one or more remote plasma sources and generating plasma of the fluorine-containing species; introducing an oxygen-containing source gas into the one or more remote plasma sources and generating plasma of the oxygen-containing species; and flowing the plasma of the fluorine-containing species and the plasma of the oxygen-containing species into the process chamber via the one or more first gas outlets cyclically or simultaneously to remove the molybdenum-containing film from the interior surfaces of the process chamber.

In some embodiments, the apparatus also includes a chamber manometer configured to maintain a first pressure of the process chamber when flowing the molybdenum-containing precursors into the process chamber, and configured to maintain a second pressure of the process chamber when flowing the fluorine-containing species and the oxygen-containing species into the process chamber, wherein the second pressure is at a low-pressure regime between about 0.5 Torr and about 2 Torr or at a high-pressure regime between about 2 Torr and about 6 Torr.

In some embodiments, the fluorine-containing source gas includes nitrogen trifluoride (NF₃), molecular fluorine (F₂), carbon tetrafluoride (CF₄), carbon hexafluoride (C₂F₆), xenon difluoride (XeF₂), fluoromethane (CH₃F), difluoromethane (CH₂F₂), tetrafluoroethylene (C₂F₄), hexafluoroethane (C₂F₆), octafluoropropane (C₃F₈), sulfur hexafluoride (SF₆), or mixtures thereof.

In some embodiments, the oxygen-containing source gas includes oxygen (O₂), ozone (O₃), carbon monoxide (CO), carbon dioxide (CO₂), nitrous oxide (N₂O), nitrogen dioxide (NO₂), or mixtures thereof.

Still yet another aspect involves a method of cleaning a dielectric material from one or more components of a process chamber, the method including (a) introduce into the process chamber (i) a remote plasma containing a fluorine species, and (ii) a thermal etchant that undergoes a ligand exchange reaction with a fluorine-containing reaction product of the dielectric material to produce a volatile reaction product, and (b) remove the volatile reaction product from the process chamber.

In some embodiments, (a) includes co-flowing the remote plasma and the thermal etchant into the process chamber.

In some embodiments, the remote plasma and the thermal etchant may be introduced for about 0.1 to about 600 seconds.

In some embodiments, (a) includes introducing the remote plasma to the process chamber at a first time and introducing the thermal etchant later, at a second time. The method further includes repeating introducing the remote plasma to process chamber at the first time and introducing the thermal etchant at the second time.

In some embodiments, the remote plasma may be introduced for about 30 to about 300 seconds, and the thermal etchant may be introduced for about 30 to about 300 seconds.

In some embodiments, (a) further includes introducing water vapor, methyl alcohol, ethyl alcohol, or propyl alcohol to the process chamber.

In some embodiments, introducing into the process chamber (i) a remote plasma containing a fluorine species include forming the dielectric material including a fluorine ligand.

In some embodiments, undergoing the ligand exchange reaction includes replacing fluorine in the fluorine-containing reaction product with bromine or chlorine.

In some embodiments, the method further includes, before (a), pausing a semiconductor device fabrication process in the process chamber.

In some embodiments, the remote plasma is generated from a process gas including nitrogen trifluoride, fluorine (F₂), tetrafluoromethane, trifluoromethane, difluoromethane, fluoromethane, sulfur hexafluoride, octafluoropropane, octafluorocyclobutane, hexafluorocyclobutene. 1,2,3,3,4-pentafluorocyclobutene-4-ylradical, fluorine, or mixtures thereof.

In some embodiments, the thermal etchant includes hydrogen bromide, hydrogen chloride, boron trichloride, or mixtures thereof.

In some embodiments, the thermal etchant includes boron bromide, phosphorous trichloride, carbon tetrachloride, nitrogen trichloride, or mixtures thereof.

In some embodiments, the volatile reaction product includes Br or Cl ligand.

In some embodiments, a chamber temperature is about 50 to about 650° C.

In some embodiments, a chamber pressure is about 0.5 to about 100 Torr.

In some embodiments, an etch rate of the dielectric material is about 500 to about 1,000 angstroms per minute.

In some embodiments, the dielectric material includes hafnium oxide, zirconium oxide, tin oxide, aluminum oxide, hafnium nitride, zirconium nitride, aluminum nitride, yttrium oxide, lanthanum oxide, or mixtures thereof.

In some embodiments, (a) includes exposing the dielectric material in the process chamber to the remote plasma containing a fluorine species at a first time, and the thermal etchant at a second time.

In some embodiments, (a) includes exposing the dielectric material in the process chamber to a co-flow of the remote plasma and the thermal etchant.

Still yet another aspect involves a system, the system including a process chamber configured to perform a device fabrication operation that deposits a dielectric material on one or more components of the process chamber, a remote plasma source configured to produce a remote plasma including a fluorine-containing species and deliver the remote plasma to the process chamber; and a controller configured to cause (a) introduction into the process chamber of (i) a remote plasma containing a fluorine species, and (ii) a thermal etchant that undergoes a ligand exchange reaction with a fluorine-containing reaction product of the dielectric material to produce a volatile reaction product; and (b) removal of the volatile reaction product from the process chamber.

In some embodiments, the system further includes a first process gas supply that is fluidly coupled to the remote plasma source to deliver the process gas to the remote plasma source. The process gas includes nitrogen fluoride, tetrafluoromethane, trifluoromethane, difluoromethane, fluoromethane, sulfur hexafluoride, octafluoropropane, octafluorocyclobutane, hexafluorocyclobutene. 1,2,3,3,4-pentafluorocyclobutene-4-ylradical, fluorine, or mixtures thereof.

In some embodiments, the system further includes a second process gas supply that is fluidly coupled with the process chamber to deliver the thermal etchant in the process chamber. The thermal etchant includes hydrogen bromide, hydrogen chloride, boron trichloride, or mixtures thereof.

In some embodiments, the second process gas supply is fluidly coupled to the remote plasma source.

In some embodiments, the system further includes a vaporization point that is fluidly coupled with the process chamber to deliver the thermal etchant in the process chamber. The thermal etchant includes boron bromide, phosphorous trichloride, carbon tetrachloride, nitrogen trichloride, or mixtures thereof.

In some embodiments, (a) includes co-flowing the remote plasma and the thermal etchant into the process chamber.

In some embodiments, (a) includes introducing the remote plasma to the process chamber at a first time and introducing the thermal etchant later, at a second time.

In some embodiments, the controller is further configured to cause (c) control of the chamber temperature of about 50 to about 650° C.

In some embodiments, the system further includes a vacuum pump to remove the volatile reaction product from the process chamber.

In some embodiments, the controller is further configured to cause (d) control of a chamber pressure of about 0.5 to about 100 Torr.

In some embodiments, the controller is further configured to cause (e) control of an etch rate of the dielectric material of about 500 to about 1,000 angstroms per minute.

Still yet another aspect is a method of cleaning a process chamber. The method may include heating the process chamber to a predetermined temperature. A plasma flow may be delivered from a remote plasma source into the process chamber through a showerhead to clean the process chamber, wherein the remote plasma source is fluidly coupled with the process chamber through the showerhead and located upstream of the process chamber. The plasma flow limits diffusion of a gaseous contaminant from the showerhead.

In some embodiments, the plasma flow is delivered in a downward direction or substantially downward direction.

In some embodiments, the plasma source includes an inductively coupled plasma, a capacitively coupled plasma reactor, a microwave plasma reactor, a DC plasma reactor, or a laser-created plasma reactor.

In some embodiments, the plasma flow has a flow rate of between about 1 and about 50 liters per minute.

In some embodiments, the plasma flow includes an oxygen-containing species, a fluorine-containing species, and an inert gas.

In some embodiments, the gaseous contaminant includes metal fluoride. For example, the gaseous contaminant includes aluminum fluoride.

In some embodiments, the predetermined temperature ranges from about 450° C. to about 650° C.

In some embodiments, the predetermined temperature ranges from 500° C. to 600° C.

In some embodiments, heating the process chamber includes heating a pedestal.

In some embodiments, the plasma flow is delivered at a sufficient flow rate to substantially prevent the gaseous contaminant from depositing on the showerhead.

In some embodiments, the method further includes providing a substrate in the process chamber. The method still further includes depositing a film on the substrate prior to delivering the plasma flow to clean the process chamber. Prior to the depositing the film, a process chamber temperature is kept at the predetermined temperature. The film is deposited at the predetermined temperature. The method still yet further includes transferring the substrate out of the process chamber after depositing the film on the substrate and prior to delivering the plasma flow to clean the process chamber. Delivering the plasma flow to clean the process chamber includes removing deposition byproducts from the process chamber after depositing the film on the substrate.

Still yet another aspect of the disclosure relates to a method of cleaning a process chamber. The method includes heating a pedestal in the process chamber to a predetermined temperature, and depositing a film on a substrate in the reaction chamber. The method also includes transferring the substrate out of the process chamber, and generating a plasma flow in a remote plasma source. The remote plasma source is fluidly coupled to the process chamber through a showerhead and located upstream of the process chamber. The method also includes delivering the plasma flow in a downward direction from the remote plasma source through the showerhead to clean the process chamber of deposition byproducts formed in the process chamber during deposition of the film on the substrate. The plasma flow is delivered at a sufficient flow rate to substantially prevent a gaseous contaminant formed in the process chamber from depositing on the showerhead.

In some embodiments, the plasma flow has a flow rate of between about 1 and about 50 liters per minute.

In some embodiments, the plasma flow includes an oxygen-containing species, a fluorine-containing species, and an inert gas.

In some embodiments, the remote plasma source includes an inductively coupled plasma reactor, a capacitively coupled plasma reactor, a microwave plasma reactor, a DC plasma reactor, or a laser-created plasma reactor.

In some embodiments, the gaseous contaminant includes metal fluoride. In some embodiments, the gaseous contaminant includes aluminum fluoride.

In some embodiments, the predetermined temperature ranges from about 450° C. to about 650° C. In some embodiments, the predetermined temperature ranges from about 500° C. to about 600° C.

In some embodiments, depositing film on the substrate includes depositing a silicon based film on the substrate. Prior to and during the deposition, the pedestal temperature is kept at the predetermined temperature.

These and other features of the disclosed embodiments will be described in detail below with reference to the associated drawings.

### BRIEF DESCRIPTION OF THE DRAWINGS

FIG. 1A provides examples of molybdenum precursors that can be used in the deposition methods according to some embodiments.

FIG. 1B provides several specific examples of molybdenum precursors that can be used in the methods according to some embodiments.

FIG. 2 is a process flow diagram for a method of forming metal-containing films according to some embodiments.

FIG. 3A is a process flow diagram for a method of forming metal-containing films according to some embodiments.

FIGS. 3B and 3C are examples of timing sequences that may be used to deposit metal-containing layers.

FIG. 4A is a process flow diagram for a method of treating metal-containing films according to some embodiments.

FIG. 4B is a process flow diagram for a method of treating metal-containing films according to some embodiments.

FIG. 5 is a schematic cross-sectional view of a pMOS device structure containing a layer of substantially carbon-free metal-containing material, in accordance with some embodiments.

FIGS. 6A-6C are schematic cross-sectional views of a semiconductor device during fabrication, in accordance with some embodiments.

FIG. 7 is a schematic presentation of an apparatus that is suitable for depositing films according to some embodiments.

FIG. 8 shows a schematic view of a multi-station processing system according to some embodiments.

FIG. 9 shows a schematic view of a multi-station processing system according to some embodiments.

FIG. 10 shows a schematic side view with a cross-sectional insert of a flow mixer in accordance with some embodiments.

FIG. 11A shows a view of a portion of a dual-plenum showerhead assembly according to some embodiments.

FIG. 11B shows a view of a portion of a showerhead faceplate detached from the showerhead housing according to some embodiments.

FIG. 12 is a flow chart of an example method of cleaning interior surfaces of a process chamber according to some embodiments.

FIG. 13 is a flow chart of an example method of cleaning interior surfaces of a process chamber according to some embodiments.

FIG. 14 is a flow chart of an example method of cleaning interior surfaces of a process chamber deposited with a carbon- and molybdenum-containing film according to some embodiments.

FIG. 15 is a flow chart of an example method of cleaning interior surfaces of a process chamber deposited with a carbon- and molybdenum-containing film according to some embodiments.

FIG. 16 is schematic diagram of an example processing apparatus with a remote plasma source according to some embodiments.

FIG. 17 illustrates a flow chart of an example of removing a dielectric material in accordance with some embodiments.

FIG. 18 illustrates a flow chart of an example of removing a dielectric material in accordance with some embodiments.

FIG. 19 illustrates a flow chart of an example of removing a dielectric material in accordance with some embodiments.

FIG. 20 shows a cross-section of an example process chamber using an example remote plasma source in accordance with some embodiments.

FIG. 21 shows a cross-section of one station of a multi-station processing tool using an example remote plasma device in accordance with some embodiments.

FIG. 22 illustrates a flow diagram of operations according to one example embodiment.

FIG. 23 shows an image of a scanning electron microscope (SEM) of a portion of a ceramic coupon positioned on a showerhead after chamber cleaning by a plasma flow according to some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition (PVD), chemical vapor deposition (CVD), plasma enhanced chemical vapor deposition (PECVD), atomic layer deposition (ALD), plasma enhanced atomic layer deposition (PEALD), electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

In the present disclosure, the terms “depositing,” and “forming” are used interchangeably. Also, the terms “layer,” “film,” and “thin film” are used interchangeably. One of ordinary skill in the art would understand that “forming” a “layer” in any of many stages of integrated circuit fabrication can refer to “depositing” a “film” or “thin film” by one of various film forming methods such as CVD, PECVD, ALD, or PEALD due to the decreased feature sizes in a semiconductor device.

In the present disclosure, the term “cleaning.” “etching.” and “removing” are used interchangeably. In the context of an etch process, a person of ordinary skill would agree that etching a material from the interior surfaces of a process chamber is equivalent to “cleaning” or “removing” the material from the interior surfaces of the process chamber, thereby leaving the interior surfaces free of the material.

In the present disclosure, the term “remote plasma clean” refers to removing or etching a layer from interior surfaces of a process chamber using plasma activated species generated from a remote plasma source. The plasma activated species may include fluorine-containing species, and may actively react with the layer to form a non-volatile or volatile reaction product. Nitrogen trifluoride (NF₃) or fluorine (F₂) may be a process gas supplied to the remote plasma source to generate the fluorine-containing species. The layer may include metals, metal alloy, oxides, doped or undoped nitrides, doped or undoped carbides, or mixtures thereof.

In the present disclosure, the term “thermal etching” uses gas-phase reagents to react with a substrate surface and to etch materials from the substrate surface chemically and/or thermally. Thermal etching may also be referred to as “chemical etching.” In some cases, thermal etching does not employ plasma or radicals. In some cases, an etch rate for thermal etching is sensitive to temperature, proceeding faster at higher temperature.

Methods for depositing metal-containing films, including molybdenum-containing films and tungsten-containing films on semiconductor substrates are provided. In some embodiments, the films are substantially carbon-free. These methods can be used, for example, for depositing a blanket metal-containing layer on a planar substrate, for depositing a conformal metal-containing layer on a substrate having one or more recessed or protruding features, and for filling recessed features with metal-containing materials. In some embodiments, methods are provided for forming metal-containing layers as liners or diffusion barrier lavers on semiconductor substrates. In some embodiments, methods are provided for forming substantially metal-containing layers as electrode layers in device, such as pMOS devices. In some embodiments, the metal-containing layers may be used as hard masks.

The methods can be used for deposition of a variety of molybdenum-containing and tungsten-containing materials including, but not limited to molybdenum metal (Mo), molybdenum nitride (MoN), molybdenum boride (MoB), molybdenum silicide (MoSi), and molybdenum oxynitride (MoON), tungsten metal (W), tungsten nitride (WN), tungsten boride (WB), tungsten silicide (WSi), and tungsten oxynitride (WON), where the stoichiometry of these compounds may vary, and the listed formulas are not indicative of stoichiometry. For example, MoN can include, in various embodiments, between about 10-about 70 atomic % of nitrogen with the balance being molybdenum.

The term “substantially carbon-free” refers to materials with carbon content of less than about 5 atomic %, where hydrogen (if present) is excluded from the calculations. In some embodiments, provided substantially carbon-free films include less than about 3 atomic % carbon, such as less than about 2 atomic % carbon.

“Metal”, e.g. “metallic molybdenum” or “metallic tungsten” as used herein, refers to material that consists essentially of metal (e.g., Mo or W). Other elements (e.g., B, Si, N, or O) can be present in the metal in small quantities (e.g., with a total content of less than about 15 atomic %, or less than about 10%, where hydrogen is not included in the calculation).

Molybdenum nitride (MoN), molybdenum boride (MoB), molybdenum silicide (MoSi), molybdenum oxynitride (MoON), tungsten nitride (WN), tungsten boride (WB), tungsten silicide (WSi), tungsten oxynitride (WON), refer to materials that consist essentially of the listed elements, where the stoichiometry of these compounds may vary and is not determined by the listed formulas (e.g., MoN does not necessarily indicate 1:1 Mo:N stoichiometry). Other elements (e.g., boron, silicon, nitrogen, phosphorous, etc.) may be present in these compounds in small quantities, e.g., in an amount of less than about 10%, about 5%, or about 1% atomic, where hydrogen is excluded from the calculation.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

The term “about” when used in reference to numerical values includes a range of #10% of the recited numerical value, unless otherwise specified.

The term “alkyl”, as used herein, refers to saturated substituents containing exclusively carbon and hydrogen atoms. Alkyls include both linear, branched and cyclic groups. Examples of linear alkyl groups include without limitation, methyl groups, ethyl groups, n-propyl groups, n-butyl groups, etc. Examples of branched alkyls groups include without limitation, isopropyl, isobutyl, sec-butyl, and t-butyl. Examples of cycloalkyls include without limitation, cyclopropyl groups, cyclopentyl groups, cyclohexyl groups, etc.

The term “fluoroalkyl”, as used herein, refers alkyl groups containing one or more fluorine substituents. In some implementations fluoroalkyls contain exclusively fluorine substituents, such as in CF₃, C₂F₅, C₃F₇. Fluoroalkyls may be linear, branched and cyclic.

The term “alkylsilyl”, as used herein, refers to SiRs group, wherein at least one R is an alkyl, and each R is independently selected from H and an alkyl. Alkylsilyls include mono, bis, and tris alkylsilyls. Examples of alkylsilyls include trimethylsilyl, dimethylsilyl, methylsilyl, triethylsilyl, diethylsilyl, and ethylsilyl.

The term “alkylamino”, as used herein, refers to NR₂ group, wherein at least one R is an alkyl, and each R is independently selected from H and an alkyl. Examples of alkylamino substituents include dimethylamino and diethylamino substituents.

The term “alkoxy”, refers to an OR, group, where R is an alkyl. Examples of alkoxy groups include methoxy, ethoxy, propoxy groups.

The term “independently selected”, when referring to R substituent selection in a molecule containing multiple R groups, means that the selection of R substituents at different atoms of a molecule is independent and that the selection of R substituents at one atom having multiple R substituents is also independent.

The term “metalorganic precursors” as used herein refer to metal-containing compounds that include at least one carbon-containing ligand, where the compounds do not contain metal-carbon bonds.

### Deposition of Metal-Containing Films

One aspect of the disclosure relates to deposition of metal-containing films. In the description below, this is described primarily making reference to molybdenum-containing precursors and films as examples. It is understood that the general descriptions and principles also apply to tungsten-containing precursors and films.

Deposition of molybdenum-containing and tungsten-containing films with desirable properties on semiconductor substrates presented several problems, which hindered integration of these films in many of the device fabrication process flows. Specifically, the use of halide-containing molybdenum and tungsten CVD and ALD precursors can lead to inadvertent etching of the substrate. Metalorganic and organometallic precursors can eliminate the integration problems in semiconductor processing caused by halide-containing precursors, but because molybdenum and tungsten form very stable carbide phases, the use of carbon-containing precursors often leads to incorporation of large amounts of carbon into the formed films. Carbon-containing films are not desired for many applications, as presence of carbon may increase the resistivity of the films and lower the work function of the films.

Methods for deposition of substantially carbon-free molybdenum-containing and tungsten-containing films are provided. These methods are useful for depositing molybdenum-containing and tungsten-containing materials such as nitrides, borides, silicides, oxynitrides, and combinations thereof. Some materials deposited by these methods are used as MOSFET (metal-oxide-semiconductor field-effect transistor) gate electrode materials. Since carbon has a negative impact on effective work function in early transition metal films, these methods are advantageous for producing films which have a high work function (e.g., greater than about 5 eV) suitable for pMOS structures. Some materials deposited by these methods are also useful as ultrathin low resistivity liner and/or barrier materials. In some embodiments, these methods are carried out in an integrated multi-chamber apparatus including, for example, a deposition chamber and a plasma treatment chamber, where the substantially carbon-free film is deposited by CVD or ALD in an absence of plasma in a deposition chamber, and is treated with a plasma in a plasma treatment chamber. The plasma treatment can be used to tune the film composition, densify the formed film, and/or to tune the effective work function of the formed material.

The provided methods utilize a halide-free molybdenum-containing or tungsten-containing metalorganic compound as a CVD or ALD precursor, where the metalorganic compound does not include metal-carbon (molybdenum-carbon or tungsten-carbon) bonds and does not include carbonyl (CO) ligands. Further, in some embodiments the precursor does not include beta hydrogen atoms. The deposition is carried out by reacting the precursor with a reactant, in some embodiments, in an absence of plasma. In some embodiments the reaction is carried out at a temperature of less than about 450° C., such as less than about 420° C. in an absence of plasma. The careful selection of the precursor advantageously allows to avoid substantial incorporation of carbon into the formed film, and films with carbon content of less than about 5 atomic %, such as less than about 3 atomic % can be formed. This result is unexpected, because the metalorganic precursors contain carbon, and it can be expected that due to high affinity of molybdenum and tungsten to carbon, carbon incorporation in the films would necessarily occur at high levels. However, it was discovered that when metals in the precursors do not form direct bonds with carbon and when the precursors do not include carbonyl ligands, incorporation of carbon into the films can be avoided, particularly if plasma is not used during the deposition reactions. Another factor that can significantly reduce carbon incorporation into the films is an absence of beta-hydrogens in the ligands of the metal-containing precursor. It is believed that beta-hydrogen can lead to a low-energy reaction pathway leading to incorporation of carbon into the film even at low temperature deposition conditions. The absence of beta hydrogens may stabilize the ligands against decomposition and allow for the ligands to be removed intact during the subsequent reactant gas exposure.

While thermal (non-plasma)_deposition is used in many embodiments, the methods described herein may also be used with plasma-based deposition. In a plasma-enhanced CVD method (PECVD), a plasma can be generated or fed to the processing chamber to increase the reaction rates of the reagents and can allow deposition at lower temperatures. Plasma species can also be used to modify the resulting film properties. A plasma-enhanced ALD (PEALD) cycle may include the following operations: (i) delivery/adsorption of a precursor, (ii) purging of precursor from the chamber, (iii) delivery of a second reactant and ignition of plasma, and (iv) purging of byproducts from the chamber.

In some embodiments the metal-containing precursors, used herein include a metal (e.g., molybdenum or tungsten) that forms bonds only to elements selected from the group consisting of N, O, and S. In some embodiments the precursors preferably do not include beta hydrogen atoms. For example, in some embodiments the precursors include carbon bonded to three alkyl groups at beta positions. In some embodiments, the precursor does not include metal-oxygen double bonds (M—O).

In some embodiments precursors which can be used for deposition include halide-free molybdenum and tungsten complexes bearing at least one of a monodentate ligand such as an amine, a nitrile, an imide, a nitride, an alkoxide, or a thiolate, or halide-free molybdenum and tungsten complexes bearing multidentate ligands which bond to the metal through N, O, or S atoms. The ligands preferentially do not contain β-hydrogen atoms.

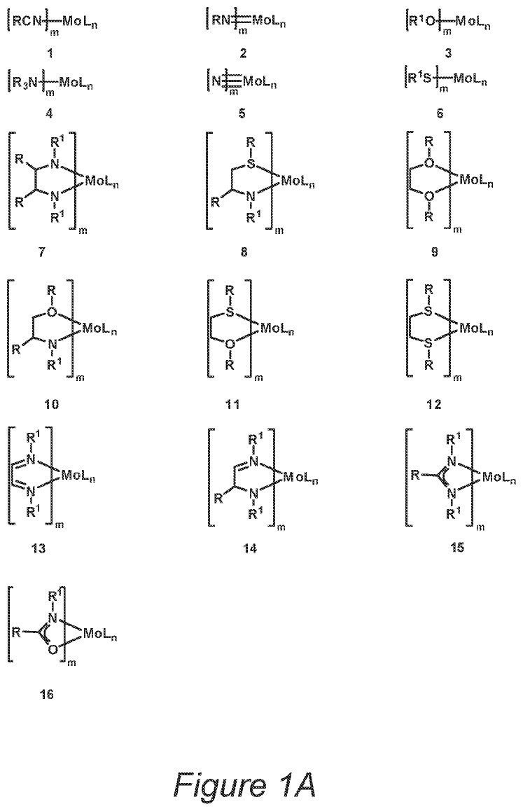

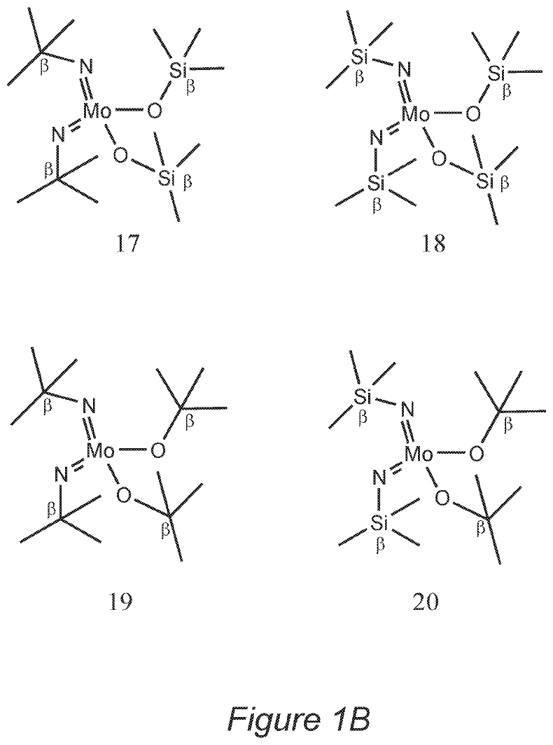

Examples of suitable molybdenum-containing precursors 1-16 are shown in FIG. 1A, where each L is a carbon-containing ligand that does not form metal-carbon bonds, and where m is in integer between 1-4, and n is an integer between 1-4. Each R and R1 is independently selected from the group consisting of an alkyl, fluoroalkyl, and alkylsilyl. In some embodiments, each R1 is selected such that it does not provide beta hydrogen atoms. Examples of such R1 substituents include t-butyl and trialkylsilyl substituents. It is noted that in some embodiments, R substituents at the O and S atoms, may provide beta hydrogen atoms, as at these positions the beta hydrogens are not readily eliminated and are not expected to lead to carbon contamination of the resulting films. Further, in compounds 7, 8, and 14, beta hydrogens at the alkyl-substituted carbon atoms adjacent to anionic nitrogen are also stabilized, and these stabilized compounds are also suitable for deposition of provided films.

In some embodiments, both R and R1 do not provide beta hydrogen atoms. In some embodiments the precursor does not include beta hydrogen atoms. For example, in some embodiments the precursor is any of the compounds 1, 2, 3, 4, 5, 6, 15, and 16, where each of R, R1 and L does not provide beta hydrogen atoms.

More specific examples of molybdenum-containing precursors are shown in FIG. 1B, which depicts structures 17-20. It can be seen that molybdenum forms bonds only to N and O atoms, and that the precursors do not include any hydrogen atoms at beta positions. The precursors can be synthesized by reacting a molybdenum starting material, such as a halide-containing molybdenum starting material with the deprotonated ligands. Exemplary synthetic routes are described in the US Patent Application Publication No. 2018/0355484, which is incorporated herein by reference for the purposes of describing synthetic routes.

The precursors used for deposition are amenable to vaporization and are stable at target temperatures and pressures. For example, in some embodiments the precursors are used in deposition reactions at temperatures of less than about 450° C., such as less than about 420° C. In order to maintain appropriate volatility, in many embodiments discussed herein, the precursors having molecular weights of less than about 450 g/mol, such as less than about 400 g/mol are selected.

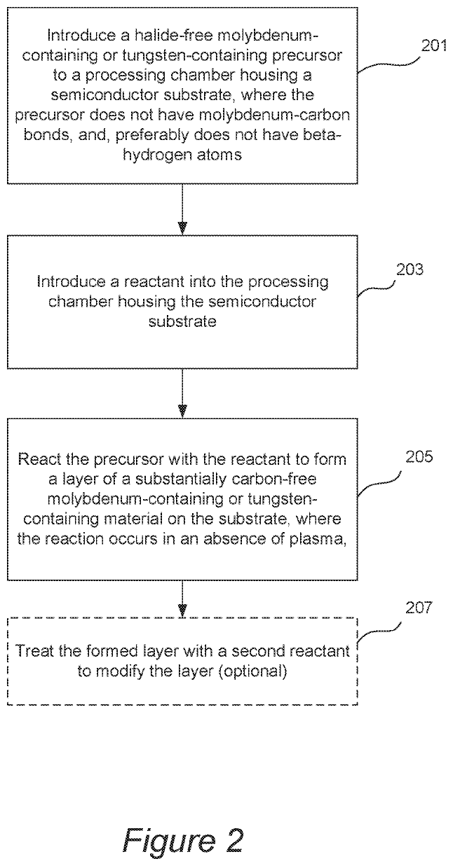

Substantially carbon-free molybdenum-containing and tungsten-containing materials can be deposited using the precursors described herein by a variety of deposition methods, such as CVD, and ALD. An exemplary method for deposition of a molybdenum-containing or tungsten-containing layer is illustrated by a process flow diagram shown in FIG. 2. The process starts in 201 by introducing a halide-free molybdenum-containing or tungsten-containing precursor into a process chamber housing the semiconductor substrate. The precursor does not include metal-carbon bonds, and, preferably does not include beta hydrogen atoms. The precursor can be introduced in a vaporized form in a flow of inert gas such as argon, helium, or nitrogen (N₂). In operation 203 (which can occur before, after, or during introduction of the molybdenum-containing precursor 201) a reactant is introduced into the process chamber housing the substrate. In some embodiments, introduction of the metal-containing precursor and of the reactant is sequential. The chemistry of the reactant depends on the chemistry of the target molybdenum-containing or tungsten-containing film. For example, for deposition of metal (Mo or W), the second reactant is typically a reducing reactant (e.g., H₂). Deposition of metal nitride can be carried out using a nitrogen-containing reactant (e.g., NH₃, or N₂H₄). In some embodiments, metal nitrides are deposited using H₂ as a reactant, and the requisite nitrogen can be supplied by the ligand. Deposition of metal boride can be performed using a boron-containing reactant (e.g., B₂H₆). Metal silicides can be formed using a silicon-containing reactant (e.g., SiH₄ or Si₂H₆).

In some embodiments the precursor and the reactant are allowed to mix in the body of the processing chamber. In other embodiments, after the metal-containing precursor has been introduced and has been adsorbed on the surface of the substrate, the processing chamber is purged with an inert gas and/or evacuated to remove the unadsorbed precursor from the process chamber. In some embodiments the layer of the precursor on the substrate is adsorption-limited. In other embodiments a thicker layer of precursor can be formed on the surface of the substrate prior to purging and/or evacuation of the process chamber. It is noted that when the precursor and the reactant are introduced sequentially, the sequence of introduction of the precursor and of the reactant may be reversed. In some embodiments the reactant is introduced first and is allowed to adsorb on the surface of the substrate. Then the process chamber is purged and/or evacuated to remove the second reactant from the volume of the process chamber, and the precursor is then introduced.

Referring to operation 205, the precursor is reacted with the reactant to form a layer of a substantially carbon-free molybdenum-containing material on the substrate, where the reaction occurs on the surface of the substrate and/or in the body of the processing chamber and is preferably performed in an absence of plasma. For example, in CVD processes the precursor and reactant may be introduced simultaneously into the body of the processing chamber, where reaction occurs continuously either the body of the processing chamber or on the surface. In ALD processes the reaction occurs only on the surface and is limited by the amount of the adsorbed material on the surface (by the amount of precursor and/or by the amount of adsorbed reactant). The temperature during the reaction process can be, for example, between about 20-about 600° C. Low temperature deposition at about 450° C. or less such as about 420° C. or less, e.g., between about 200-about 400° C. is conducted in some embodiments and is particularly advantageous for deposition of substantially carbon-free films. The pressure in the process chamber can be in a range of between about 0.1-about 100 Torr, such as between about 1-about 60) Torr in thermal ALD, such as about 10 Torr.

After the reaction is completed, the formed molybdenum-containing or tungsten-containing layer can be optionally treated with a second reactant to modify the layer, as shown in operation 207. The treatment may be performed in order to tune the properties of the layer, such as to densify the layer, modify the composition or electrical properties of the layer, reduce the resistivity of the layer, etc. The treatment is, in some embodiments, plasma-assisted. For example, the substrate may be treated with a direct plasma (formed in the compartment housing the substrate), or a remote plasma (formed away from the substrate and introduced into the compartment housing the substrate). The use of remote plasma is preferred in some cases as it reduces the damage to the substrate. In one of preferred embodiments, the substantially carbon-free molybdenum-containing or tungsten-containing layer is deposited in an absence of plasma. The substrate is then transferred to a plasma treatment process chamber without exposing the substrate to an ambient atmosphere, where the substrate is treated with a plasma treatment reactant. The choice of plasma treatment reactant depends on the desired properties of the final layer. The substrate may be treated for example with plasma-activated H₂, NH₃, N₂, BH₃, SiH₄, Ar, He, and mixtures thereof.

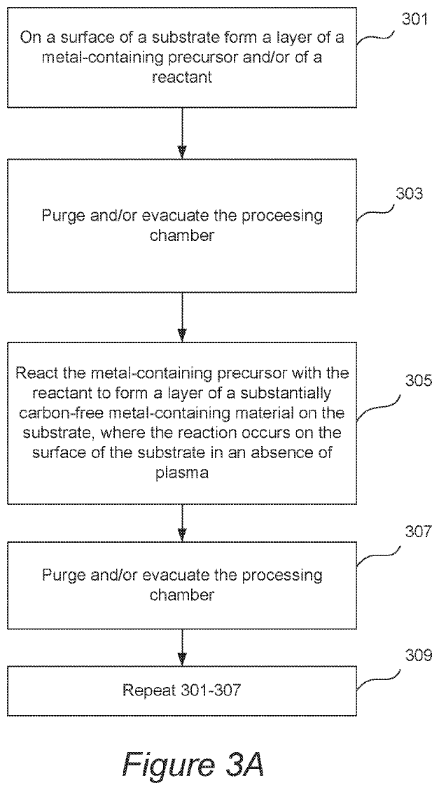

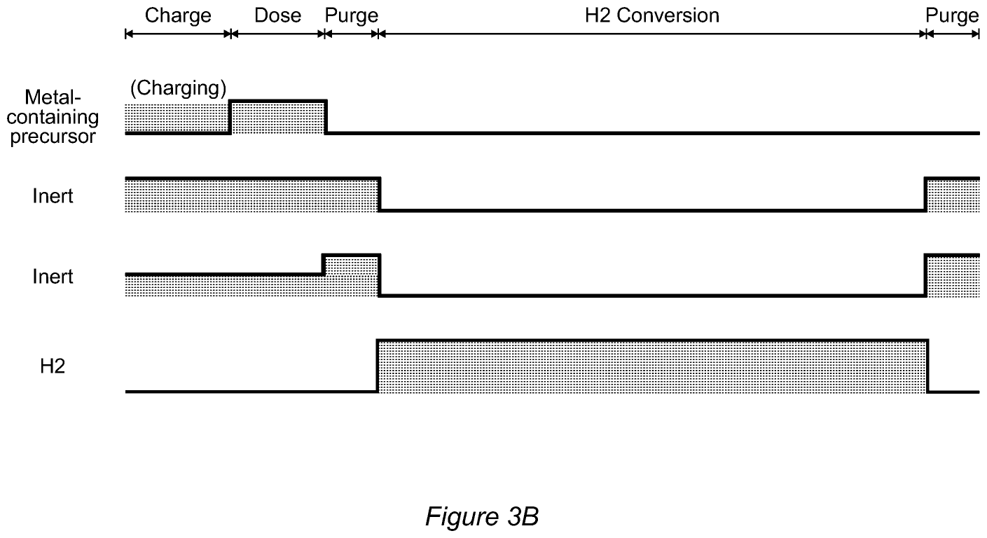

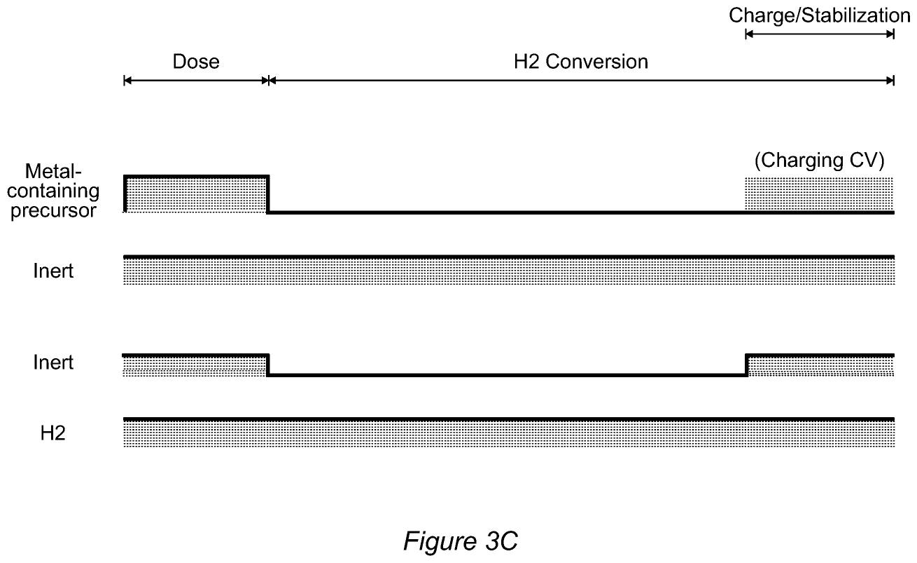

An example of a surface-based deposition process for forming a molybdenum-containing or tungsten-containing film on a substrate is illustrated by a process flow diagram shown in FIG. 3A. In operation 301, a layer of a metal-containing precursor and/or of a reactant is formed on a surface of a substrate. In some embodiments the layer is an adsorption-limited layer. Next in operation 303, the processing chamber is purged and/or evacuated. This step ensures that the precursor and/or reactant are present only on the surface of the substrate and not in the volume of the processing chamber. Next, in 305 the precursor is reacted with the reactant on the surface of the substrate. For example, if only a metal-containing precursor is adsorbed on the surface of the substrate in 301, a reactant may be introduced into the processing chamber and allowed to react with the precursor on the surface. If both the metal-containing precursor and the reactant layers are formed on the surface of the substrate in 301, in 313 the process conditions can be adjusted (e.g., using a temperature increase) to activate the reaction. Next, in 307 the processing chamber is purged and/or evacuated, and in 309 operations 301-307 are repeated to form more metal-containing material. In some embodiments each cycle of operations 301-307 deposits about 0.1-about 5 Å of metal-containing material on average. In some embodiments, 1-100, such as 2-100 cycles are performed. For example, 1-20, such as 2-20 cycles can be performed. Substantially carbon-free molybdenum-containing and tungsten-containing layers with thicknesses of between about 5-about 500 Å, such as 5-about 50 Å can be formed with high level of control over layer thickness. This method can be used to form conformal layers with excellent step coverage.

FIGS. 3B and 3C show examples of reactant timing sequences that may be employed to deposit a metal-containing film. In FIG. 3B, a metal-containing precursor flow is alternated with a reactant. In this example, the reactant is H₂. An inert gas may be flowed with the metal-containing precursor. In this example, the metal-containing precursor is charged in a charge volume prior to being inlet to a station containing the substrate on which the film is to be deposited. Exposure to the metal-containing precursor is referred to a dose in FIG. 3B. An inert gas may then purge the station. This is followed by an H₂ exposure, and a subsequent purge. The cycle may then repeat. The heights and lengths of the various operations are provided for illustration purposes and do not reflect actual flowrates or times. In some embodiments, the H₂ conversion may be significantly longer than the dose, e.g., at least 2 times, 3 times, 4 times, or 5 times longer.

In some embodiments, a process is performing while co-flowing a reactant such as hydrogen (H₂) during the dose. FIG. 3C shows an example, in which H₂ is flowed throughout the process, including during the dose as well as in a subsequent portion of the cycle in which the metal-containing precursor is not flowed into the station. According to various embodiments, an inert gas may or may not be flowed during all or part of the cycle.

The timing sequence shown in FIG. 3C may be used in some embodiments in which H₂ or other reactant does not react with gas-phase metal precursor. For example, H₂ does not react with certain gas-phase halide-free metalorganic precursors such as bis(tert-butylimido)bis(tert-butoxy) molybdenum, but does react with the deposited film. By co-flowing H₂ or other reactant with the metal-containing precursor, the throughput can be increased. Further, composition control can be enhanced with a longer portion of the cycle used to reduce the deposited film and/or control the content of oxygen, nitrogen, and/or carbon within the film. As described herein, this can be used to tune properties of the film including density, etch rate, resistivity, or effective work function.

In some embodiments, H₂ or other reactant is flowed at high pressure, e.g., at least 10 Torr, at least 20) Torr, at least 50 Torr, at least 100 Torr, at least 200 Torr, or at least 250 Torr. Examples of pressure are between 10 and 300 Torr, endpoints included. This may be done for both non-co-flow (e.g., FIG. 3B) or co-flow (e.g., FIG. 3C) embodiments. High pressure and/or long conversion operations can facilitate reduction of the deposited film.

In some embodiments the as-deposited substantially carbon-free molybdenum-containing and tungsten-containing films are treated with a second reactant to modify the properties of the film, such as density, resistivity, or effective work function.

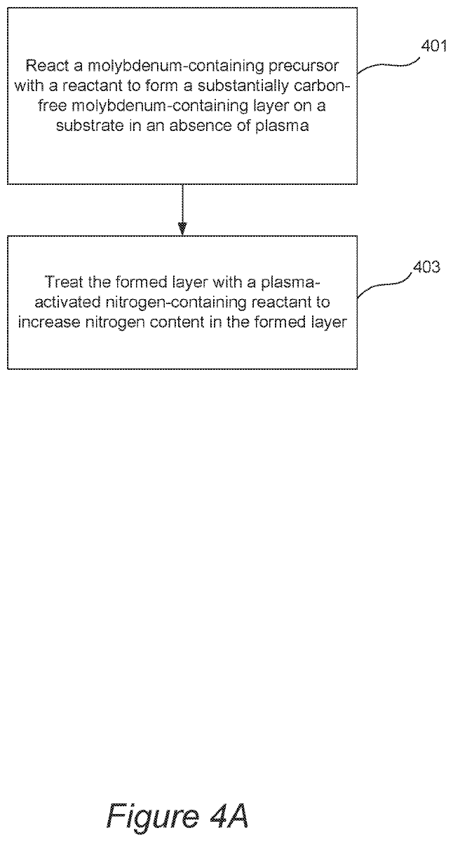

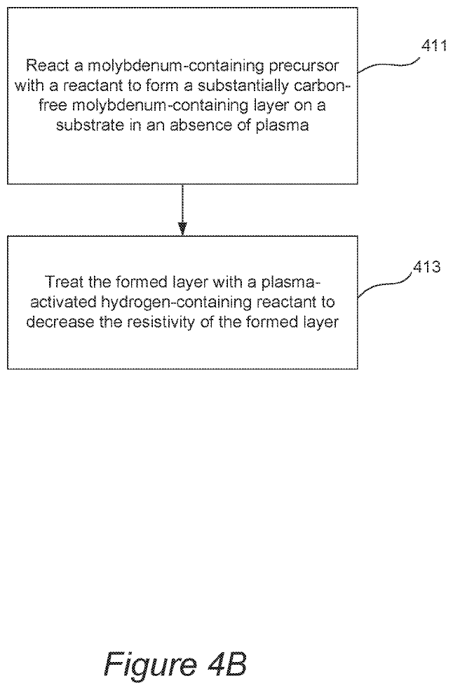

FIG. 4A provides a process flow diagram for one example of a film modifications. The process starts in 401 by reacting a molybdenum-containing precursor with a reactant to form a substantially carbon-free molybdenum-containing films on a substrate in an absence of plasma. For example, a MoN layer can be formed using several cycles of reacting a halide-free metalorganic molybdenum-containing precursor with NH₃ or H₂ in an absence of plasma on a surface of the substrate. Next, in operation 403, the film is treated with a plasma-activated nitrogen-containing reactant to increase the nitrogen content in the film. For example, the MoN film can be treated with a plasma formed in a process gas containing N₂ to increase the nitrogen content in the MoN layer. In some embodiments nitrogen content is increased by such treatment by at least 5%, such as by at least 10%. Increase of nitrogen content in the MoN layer is associated with an increase in work function. In some embodiments the work function increase due to this treatment is at least 30 meV, such as about 50-about 200 meV. In some embodiments, the MoN material obtained after the treatment has a nitrogen content of at least 25 atomic % and a work function of at least about 5.0 eV, such as at least about 5.2 eV.

Another example of a post-treatment is illustrated by the process diagram shown in FIG. 4B. In this example, the process starts as in FIG. 4A by reacting a molybdenum-containing precursor with a reactant to form a substantially carbon-free molybdenum-containing layer in 411. Next, in 413, the formed layer is treated with a plasma-activated hydrogen-containing reactant to decrease resistivity of the layer. For example, a substantially carbon-free molybdenum nitride layer may be treated with a plasma formed in a process gas that contains H₂, resulting in substantial decrease of the films' resistivity. In some embodiments the resistivity can be decreased by this treatment by at least 20%, such as at least 50%, or even at least 80%. In some embodiments, the H₂ plasma treatment decreases the resistivity of the film at least two-fold, three-fold, or five-fold. In some embodiments, films with resistivities of less than about 1,000 μΩ·cm, such as less than about 800 μΩ·cm are obtained after H₂ plasma treatment. In some embodiments, plasma treatment (e.g., plasma treatment using hydrogen-containing reactants, such as H₂) is further used to densify the as-deposited films. For example, density of the film can be increased by at least 20%, such as by at least 40% by H₂ plasma post-treatment.

The provided substantially carbon-free molybdenum-containing and tungsten-containing films can be deposited on a variety of surfaces including on metals (e.g., copper, nickel, cobalt, tungsten, etc.), dielectrics (e.g., silicon oxide based dielectrics, silicon nitride, silicon carbide, metal oxides, metal nitrides, etc.), and on amorphous and crystalline silicon. In some embodiments the films are deposited as liners or diffusion barrier layers.

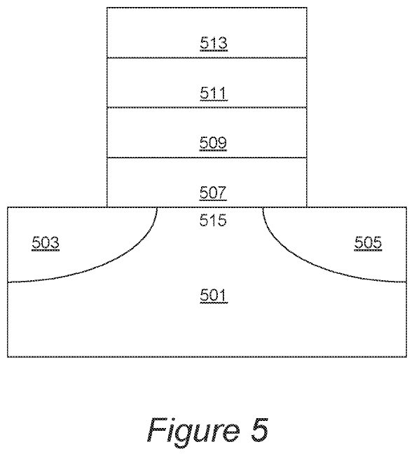

In one implementation, provided substantially carbon-free metal-containing films are used as MOSFET gate electrode materials. In one example, the provided films are integrated into a pMOS device structure. A schematic cross-sectional view of a pMOS device is shown in FIG. 5. The device (e.g., a transistor) includes a semiconductor layer 501, a source region 501, a drain region 503, and a gate dielectric layer 505 formed over the semiconductor layer 501, and defining a channel region 515 in the semiconductor layer 501 between the source region 501 and a drain region 503. The semiconductor layer 501 includes a semiconductor material, such as silicon (Si), germanium (Ge), or silicon germanium (SiGe). The gate dielectric layer 505 includes, in one embodiment, a high-k dielectric having a dielectric constant of greater than about 3.9. For example, the gate dielectric layer 505 may include high-k materials, such as HfO, HfSiO, HfSiON, and the like. The gate dielectric layer is typically very thin, e.g., between about 10 about 15 Å thick. Layers 509, 511 and 513 are disposed over the gate dielectric layer 505, and collectively form the gate electrode. Layer 509 is an optional capping layer formed directly over and in contact with the gate dielectric layer 505. The capping layer 509 includes, in some embodiments TiN. TaN and/or WN, and has a thickness of between about 10-about 20 Å. The layer 511 over the capping layer 509 is referred to a work function metal-containing layer. The layer 511 includes a substantially carbon-free molybdenum-containing or tungsten-containing material provided herein, where the material has a high work function, such as a work function of greater than about 4.9 eV, greater than about 5.0 eV, or greater than about 5.1 eV. In some embodiments, the layer 511 is a substantially carbon-free MoN layer having an effective work function of greater than about 5.0. The substantially carbon-free layer is deposited by ALD or CVD methods described herein, and in some embodiments, is additionally treated with a plasma treatment reactant, to increase its work function. For example, in some embodiments, the as-deposited substantially carbon-free molybdenum-containing or tungsten-containing material is treated with a plasma-activated nitrogen-containing reactant (e.g., N₂) to increase nitrogen content, and work function of the formed layer. The layer 511, in some embodiments, has a thickness of between about 5-about 50 Å, or about 5-about 15 Å. In one implementation the work function metal-containing layer 511 has a thickness of about 30 Å. In some embodiments the substantially carbon-free metal-containing layer 511 is deposited directly onto the capping layer 509. When capping layer 509 is absent, the layer 511 may be deposited directly onto the gate dielectric layer 507. Finally, the device optionally may include one or more conductive layers 513 formed over the substantially carbon-free metal-containing layer 511. In some embodiments the conductive layer 513 includes one or more of TiAl, TiAlC, TiAlON, and/or a conductive metal fill, such as Mo, Co, or W. The device shown in FIG. 5 is a schematic view of a partially fabricated device that does not depict contacts formed to source and drain regions, which can be formed after formation of the electrode layers.

The provided substantially carbon-free molybdenum-containing and tungsten-containing layers may be used in a planar pMOS device, a FinFET pMOS device or in a gate all-around (GAA) pMOS device. Films with work functions of greater than 5.0 eV, such as between about 5.0-about 5.5 eV, can be obtained.

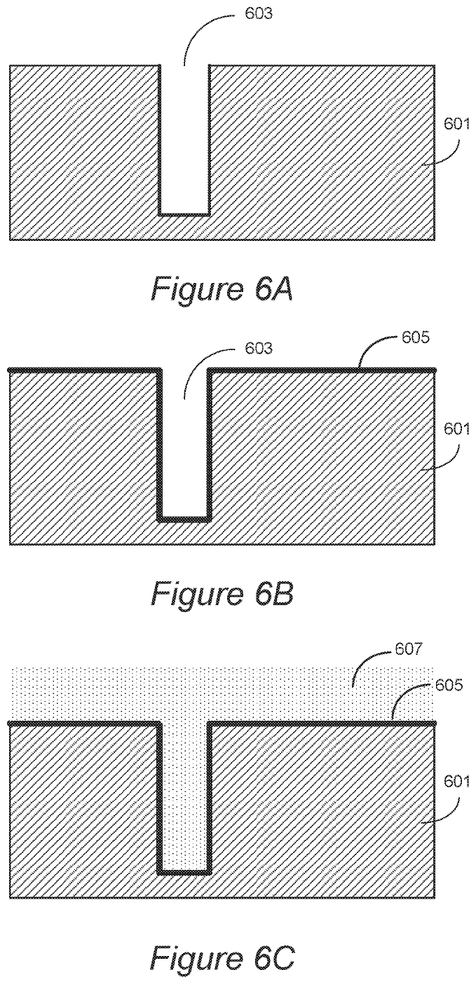

In another application, the substantially carbon-free films are deposited as diffusion barrier layers on a substrate containing recessed features, such as vias and trenches. Schematic cross-sectional views of an exemplary substrate during fabrication are shown in FIGS. 6A-6B. Referring to FIG. 6A, a substrate containing a dielectric layer 601 is provided, where the dielectric may be a silicon oxide based inter layer dielectric, e.g., a low-k dielectric, having a recessed feature 603 formed therein. Referring to FIG. 6B, a substantially carbon-free molybdenum-containing or tungsten-containing film 605 is deposited conformally over the dielectric 601, where the film lines the recessed features. Conformal films are preferably deposited by ALD using the precursors as described herein. In some embodiments the film 605 is deposited directly onto the dielectric. In other embodiments, one or more additional layers, such as adhesion layers may be formed on the dielectric before film 605 is deposited. Next, referring to FIG. 6C, the recessed feature 603 is filled with metal 607, such as with copper or cobalt. Copper or cobalt may be deposited, for example, by electrodeposition onto a thin conformal metal seed layer (not shown). The formed structure includes a thin layer of substantially carbon-free molybdenum-containing or tungsten-containing layer positioned between a dielectric layer and a metal-filled via or a trench. In some embodiments, the film 605 has a thickness of between about 5-about 50 Å, such as between about 10-about 30 Å. In some embodiments the film 605 is a diffusion barrier layer, which prevents diffusion of metals, such as copper, into the dielectric. Examples of suitable diffusion barrier materials include MoN, and WN. In some embodiments the film 605 is an adhesion layer that may promote adhesion of a conventional diffusion barrier layer (e.g., TaN, TiN) to a conductive seed layer. Examples of suitable adhesion layer materials include Mo, and MoN with a relatively low nitrogen content. In many embodiments it is preferable that the film 605 is a low-resistivity film, such as a film with a resistivity of less than about 1000 μΩ·cm, such as less than about 500 μΩ·cm. In some embodiments, these films are formed using a plasma post-treatment of as-deposited substantially carbon-free films, where the post-treatment reduces the resistivity of the as-deposited film. For example, in some embodiments deposited films (e.g., MoN or WN films) are post treated with a plasma formed in a hydrogen-containing gas (e.g., H₂), as described with reference to FIG. 4B.

It is noted that while the description provided herein uses molybdenum deposition as an example, tungsten-containing layers can be deposited using similar precursors and conditions. For example, tungsten-containing precursors having the same structures as shown in FIGS. 1A and 1B (with molybdenum substituted for tungsten) can be used.

### EXPERIMENTAL EXAMPLES

Example 1. Substantially carbon-free MoN films were deposited on SiO₂ substrates using bis(tert-butylimido)bis(tert-butoxy) molybdenum (compound 19) shown in FIG. 1B, as a molybdenum-containing precursor. The substrates were exposed to the precursor 19 in an ALD process chamber; then the process chamber was purged to remove the nonsurface-bound precursor, and the substrates were then contacted with a reactant (NH₃ H₂ or a combination of NH₃ and H₂, either in a mixture or sequentially) to react the precursor on the surface of the substrate. The process chamber was purged, and the precursor and reactant dosing were repeated. Between 1 and 500 ALD cycles was used. The depositions were performed in an absence of plasma at temperatures of between about 300-about 400° C.

Composition analysis of deposited MoN films by both x-ray photoelectron spectroscopy (XPS) and secondary ion mass spectrometry (SIMS) showed carbon contents of between 0.2-2 atomic %. Film resistivities were 500-4,000 μΩ·cm for film thicknesses between 2-10 nm.

A 2 nm thick film was subjected to a H₂ plasma treatment for 60 seconds. The film was treated at 400° C. with a remotely generated plasma (13.56 MHZ, 2 KW) in a process gas comprising H₂. The resulting 1 nm film, as measured by TEM, had a resistivity of about 600μΩ·cm illustrating a 6-fold reduction in resistivity compared to the initial 3600 μΩ·cm resistivity for the as-deposited film.

Example 2 (comparative). Substantial carbon incorporation was demonstrated to occur when molybdenum precursor is treated with a reactant in a plasma. MoC films were deposited on SiO₂ substrates using bis(tert-butylimido)bis(tert-butoxy) molybdenum (compound 19) shown in FIG. 1B as a molybdenum-containing precursor. The substrate was exposed to the precursor 19 in an ALD process chamber; then the process chamber was purged to remove the non-surface bound precursor, and the substrate was then contacted with a plasma formed in H₂ to react the precursor on the surface of the substrate. The process chamber was purged, and the precursor and reactant dosing were repeated. 200 ALD cycles was used. The deposition was performed at a temperature of 250° C. Composition analysis of a 15 nm film by X-ray photoelectron spectroscopy showed 58 atomic % Mo and 41 atomic % C. It is believed that the energetic plasma reactant induces uncontrolled decomposition of organic ligands, which enables ready formation of highly thermodynamically stable Mo carbide films. Thus, it is difficult to achieve substantially carbon-free metallic Mo-containing films using a plasma reactant.

Example 3. A plasma treatment with a mixture of N₂ and argon was performed on a 3 nm substantially carbon-free MoN film at 400° C. for 150 seconds. The plasma was generated remotely at a power of 3 KW. MOS capacitors were fabricated and the effective work function was obtained by extrapolating the plot of flat-band voltage versus effective oxide thickness to zero. The plasma-treated film showed an effective work function increase of approximately 0.08 eV versus the untreated film. Separate experiments to determine the composition change due to the plasma treatment showed approximately 10% higher nitrogen content after plasma treatment.

### Apparatus

The deposition methods described herein can be carried out in a variety of apparatuses. A suitable apparatus includes a processing chamber having one or more inlets for introduction of reactants, a substrate holder in the process chamber configured to hold the substrate in place during deposition, and, optionally, a plasma generating mechanism configured for generating a plasma in a process gas. The apparatus may include a controller having program instructions for causing any of the method steps described herein.

For example, in some embodiments the apparatus includes a controller having program instructions that include instructions for: causing an introduction of a molybdenum or tungsten precursor to the processing chamber, wherein the precursor is any of the precursors described herein; and causing a reaction between the precursor and a reactant to form a layer of substantially carbon-free molybdenum-containing or tungsten-containing material on a substrate. The controller may include program instructions for causing any of the methods described herein.

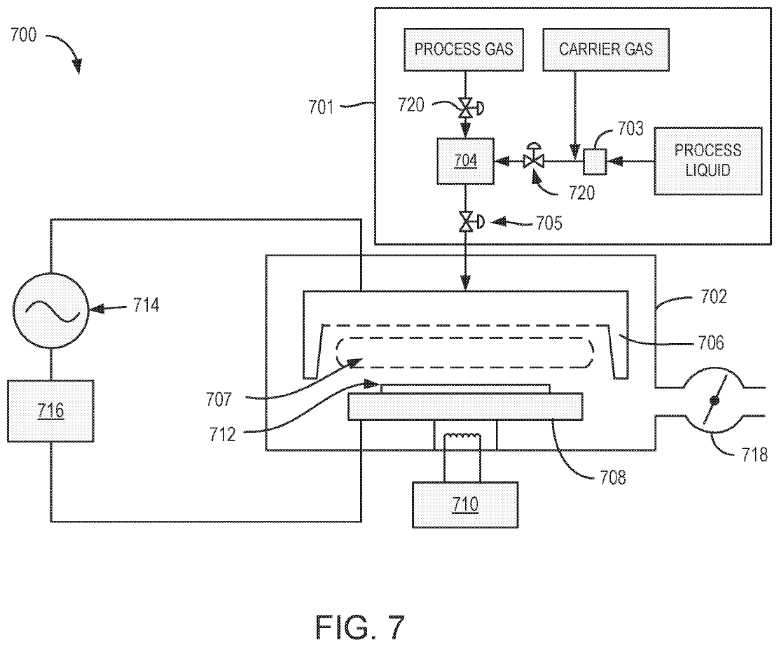

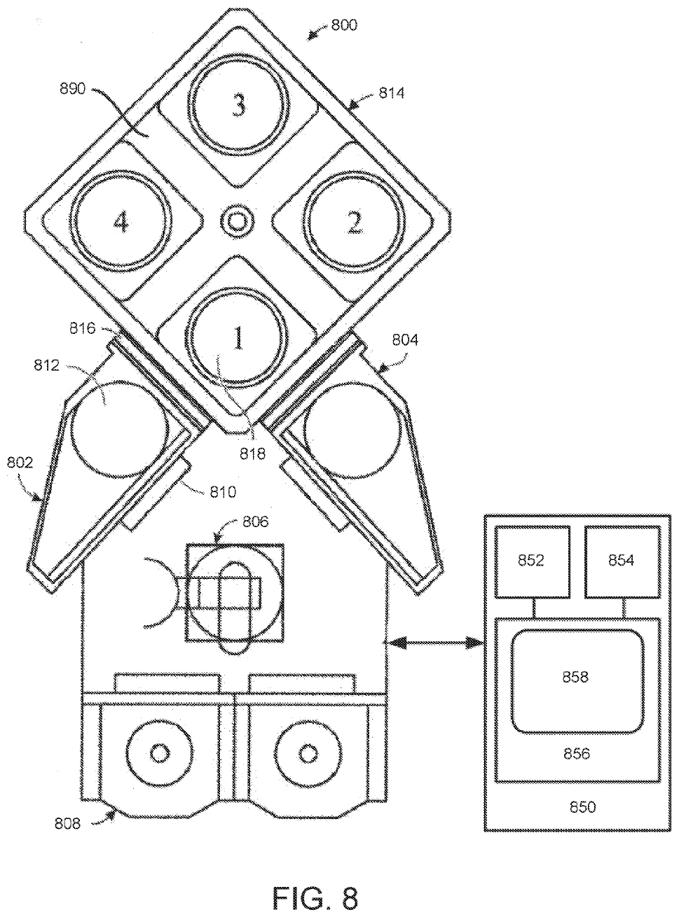

An example of a deposition apparatus suitable for depositing molybdenum-containing films using provided methods is shown in FIG. 7. FIG. 7 schematically shows an embodiment of a process station 700 that may be used to deposit material using ALD and/or CVD, either of which may be optionally plasma enhanced. It is noted that in many embodiments plasma-enhancement of deposition reaction is avoided to prevent incorporation of carbon into the films. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers.

Reactant delivery system 701 delivers process gases to a distribution showerhead 706 of the process station 700. Reactant delivery system 701 includes a mixing vessel 704 for blending and/or conditioning process gases for delivery to showerhead 706. One or more mixing vessel inlet valves 720 may control introduction of process gases to mixing vessel 704. Similarly, a showerhead inlet valve 705 may control introduction of process gasses to the showerhead 706.

Some metal-containing precursors may be stored in solid or liquid form prior to vaporization and subsequent delivery to the process station. For example, the embodiment of FIG. 7 includes a vaporization point 703 for vaporizing solid reactant to be supplied to mixing vessel 704. In some embodiments, vaporization point 703 may be a heated vaporizer. In some embodiments a flow of an inert gas is passed over the heated solid molybdenum or tungsten precursor, or bubbled through the heated liquid molybdenum or tungsten precursor, under subatmospheric pressure, and carries the precursor vapor to the process chamber. The precursor vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 200° C. at mixing vessel 704.

Showerhead 706 distributes process gases toward substrate 712. In the embodiment shown in FIG. 7, substrate 712 is located beneath showerhead 706, and is shown resting on a pedestal 708. It will be appreciated that showerhead 706 may have any suitable shape, and may have any suitable number and arrangement of ports for distributing processes gases to substrate 712. While not explicitly shown, in some embodiments the showerhead 706 is a dual plenum showerhead that includes at least two types of conduits, where the first type of conduit is dedicated to delivery of molybdenum-containing or tungsten-containing precursor vapor, and the second type of conduit is dedicated to delivery of the reactant (e.g., H₂, NH₃, etc.). In these embodiments the molybdenum-containing precursor and the reactant are not allowed to mix in the conduits prior to entry to the process chamber, and do not share the conduits if delivered to the chamber consecutively.

In some embodiments, a microvolume 707 is located beneath showerhead 706. Performing an ALD and/or CVD process in a microvolume rather than in the entire volume of a process station may reduce reactant exposure and sweep or purge times (i.e., the duration of a sweep or purge operation), may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some embodiments, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712 in an appropriate direction. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering a plasma. In other embodiments apparatuses without a plasma generator are used for depositing molybdenum-containing and tungsten-containing films using provided methods. In some embodiments, the plasma energy may be controlled by controlling one or more of a process station pressure, a gas concentration, a radio frequency (RF) source power, an RF source frequency, and a plasma power pulse timing. For example, RF power supply 714 and matching network 716 may be operated at any suitable power to form a plasma having a desired composition of radical species. Likewise, RF power supply 714 may provide RF power of any suitable frequency. In some embodiments, RF power supply 714 may be configured to control high- and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHZ and 2.45 GHZ. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas. In some embodiments the plasma is used for post-treatment of deposited substantially carbon-free films.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 708 may be temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to process station 700.

FIG. 8 shows a schematic view of an embodiment of a multi-station processing tool 800 with an inbound load lock 802 and an outbound load lock 804, either or both of which may comprise a remote plasma source. Such tool may be used for processing the substrates using the methods provided herein. A robot 806, at atmospheric pressure, is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 comprises a remote plasma source, the wafer may be exposed to a remote plasma treatment in the load lock prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc.

In some embodiments, system controller 850 controls all of the activities of process tool 800. System controller 850 executes system control software 858 stored in mass storage device 854, loaded into memory device 856, and executed on processor 852. System control software 858 may include instructions for controlling the timing, mixture of gases, chamber and/or station pressure, chamber and/or station temperature, purge conditions and timing, wafer temperature, RF power levels. RF frequencies, substrate, pedestal, chuck and/or susceptor position, and other parameters of a particular process performed by process tool 800. System control software 858 may be configured in any suitable way. For example, various process tool component subroutines or control objects may be written to control operation of the process tool components necessary to carry out various process tool processes in accordance with the disclosed methods. System control software 858 may be coded in any suitable computer readable programming language.

In some embodiments, system control software 858 may include input/output control (IOC) sequencing instructions for controlling the various parameters described above. For example, each phase of an ALD process may include one or more instructions for execution by system controller 850. The instructions for setting process conditions for an ALD process phase may be included in a corresponding ALD recipe phase. In some embodiments, the ALD recipe phases may be sequentially arranged, so that all instructions for a ALD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850) may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the Altus R product family, available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

In some embodiments, the apparatus includes a process chamber for deposition of substantially carbon-free films, and a different process chamber configured for treating these films with a remote plasma to densify the films, to decrease the resistivity of the films or to increase their work function. In some embodiments the apparatus is programmed or configured to transfer the substrate from a deposition process chamber to a plasma treatment process chamber without exposing the substrate to an ambient atmosphere, moisture or oxygen.

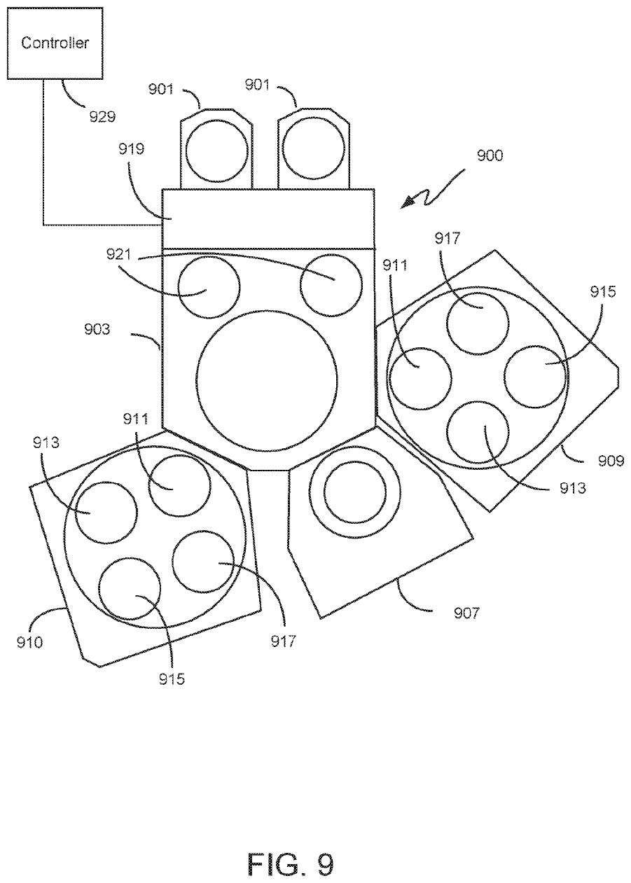

FIG. 9 is a block diagram of a processing system suitable for conducting thin film deposition processes in accordance with certain embodiments. The system 900 includes a transfer module 903. The transfer module 903 provides a clean, pressurized environment to minimize risk of contamination of substrates being processed as they are moved between various reactor modules. Mounted on the transfer module 903 are two multi-station reactors 909 and 910, each capable of performing ALD and/or CVD according to certain embodiments. Reactors 909 and 910 may include multiple stations 911, 913, 915, and 917 that may sequentially or non-sequentially perform operations in accordance with disclosed embodiments. The stations may include a heated pedestal or substrate support, one or more gas inlets or showerhead or dispersion plate.

Also mounted on the transfer module 903 may be one or more single or multi-station modules 907 capable of performing plasma or chemical (non-plasma) pre-cleans, or any other processes described in relation to the disclosed methods. The module 907 may in some cases be used for various treatments to, for example, prepare a substrate for a deposition process. The module 907 may also be designed/configured to perform various other processes such as etching or polishing. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the precursor flows, and other processes in a process sequence can be written in any conventional computer readable programming language: for example, assembly language, C, C++. Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems. RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Flow Mixer

In another aspect, a flow mixer for mixing a carrier gas and a metal-containing precursor prior to delivery to the processing chamber is provided. The described flow mixer is adapted to improve uniformity of delivery of the metal-containing precursor to the showerhead, and can be used for any metal-containing precursors, including, but not limited to molybdenum and tungsten precursors described herein.

Examples of Mo-containing precursors for ALD or CVD of molybdenum or molybdenum-containing materials include the precursors discussed above as well as MoF₆, MoCl₅, molybdenum dichloride dioxide (MoO₂Cl₂), molybdenum tetrachloride oxide (MoOCH₄), and molybdenum hexacarbonyl (Mo(CO)₆). Other Mo oxyhalides of the formula MoₓOₓH_{z} and H is a halogen (fluorine (F), chlorine (Cl), bromine (Br), or iodine (I)) and x, y, and z being any number greater than zero that can form a stable molecule. These include molybdenum tetrafluoride oxide (MoOF₄), molybdenum dibromide dioxide (MoO₂Br₂), and molybdenum oxyiodides MoO₂I and Mo₄O₁₁I. Organo-metallic precursors may also be used with examples including Mo precursors having cyclopentadienyl ligands. Further examples include precursors of the formula Mo₂Ln, wherein each L is independently selected from an amidate ligand, an amidinate ligand, and a guanidinate ligand, where n is 2-5. The Mo₂Ln precursor includes a multiple molybdenum-molybdenum bond (such as a double bond or any multiple bond with a bond order of 2-5). Further examples include halide-containing heteroleptic molybdenum compounds (i.e., compounds having different types of ligands). Particular examples of such precursors are compounds that include molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and α-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

When metal precursor vapor is delivered to the showerhead, it is typically mixed with a flow of a carrier gas, such as N₂, argon, helium, and the like, to provide a desired concentration of the precursor. This mixing is typically performed in a flow mixer, which has an outlet that is connected to the showerhead. It is noted that in many embodiments the metal precursor vapor is delivered to the mixing tube with a first flow of a carrier gas, and is then diluted with a second flow of a carrier gas. For clarity, this more concentrated flow of metal-containing precursor in a carrier gas will be referred to as metal precursor flow and the flow of carrier gas that does not include a precursor will be referred to as a carrier gas flow.

One of the problems that can be encountered during mixing of these flows is non-uniform delivery of the metal precursor to the showerhead. For example, peripheral regions near the edge of the showerhead may receive a flow with a lower concentration of metal precursor than more central portions of the showerhead. This, in turn, may lead to non-uniform distribution of the metal precursor in the processing chamber. A flow mixer that is configured for improving uniformity of mixing of the metal precursor with a carrier gas is provided. In some embodiments, the flow mixer delivers the metal precursor such that the concentration of the metal precursor at all showrehead outlets differs by no more than 2% by volume. In the described implementation, the flow mixer includes: (a) an outer fluidic conduit comprising an inlet for admitting the carrier gas into the outer fluidic conduit, a mixing zone for mixing the carrier gas with the metal-containing precursor and an outlet for removing the carrier gas mixed with the metal-containing precursor from the outer fluidic conduit: (b) an inner fluidic conduit positioned at least partially inside the outer conduit, wherein the inner fluidic conduit comprises an inlet for admitting the metal-containing precursor into the inner fluidic conduit, and an outlet configured to release the metal-containing precursor into the outer fluidic conduit, wherein a distance from the inlet of the inner fluidic conduit to the inlet of the outer fluidic conduit is greater than a distance from the outlet of the inner fluidic conduit to the inlet of the outer fluidic conduit, thereby supporting opposing flows of the carrier gas and of the metal-containing precursor in the flow mixer, wherein the distances refer to distances in a z-direction.

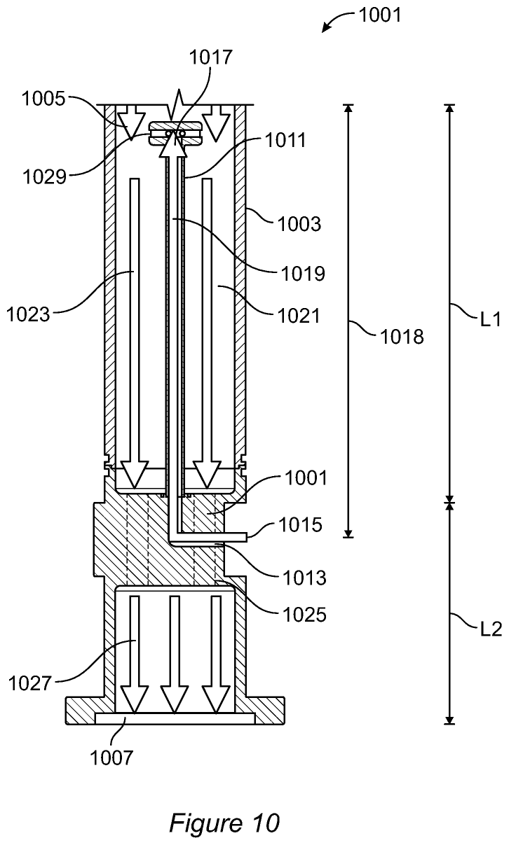

The described flow mixer is illustrated in FIG. 10, which shows a schematic side view of the flow mixer 1001, and a cross-sectional view of a portion that illustrates the inlet of the inner fluidic conduit. Referring to FIG. 10, the outer fluidic conduit 1003 has a generally cylindrical shape, and has an inlet (not shown) for admitting a carrier gas at the top of the outer fluidic conduit 1003. The inlet of the outer fluidic conduit is connected to a source of a carrier gas. The flow of the carrier gas (without the metal precursor) is shown by downward arrows 1005. The outlet 1007 of the outer fluidic conduit 1003 is located opposite to the inlet at the bottom of the outer fluidic conduit 1003. The outlet is adapted to be connected to a showerhead (not shown) and to deliver the flow 1009 of mixed metal-containing precursor with the carrier gas to the showerhead. An inner fluidic conduit 1011 resides inside the outer fluidic conduit (at least partially) and has a portion that is coaxial with the outer fluidic conduit 1003. The inner fluidic conduit 1011 has an inlet 1013 configured to admit the metal precursor from a source of the metal precursor. The metal precursor is typically flowed into the inner fluidic conduit in a mixture with a carrier gas, but this flow has a higher metal precursor concentration than a target concentration for the showerhead, and needs to be further diluted with a carrier gas in the mixing tube. The metal precursor flow entering the inner fluidic conduit 1011 is shown by arrow 1015. The outlet 1017 of the inner fluidic conduit 1011 is configured to release the metal-containing precursor which flows upwards as shown by arrow 1019, into the outer fluidic conduit 1003, where the metal precursor flow is mixed with the carrier gas flow: Notably, the distance 1018 from the inlet 1013 of the inner fluidic conduit 1011 to the outlet 1017 of the inner fluidic conduit 1013 in z-direction (vertical direction) is smaller than the distance from the inlet 1013 of the inner fluidic conduit 1011 to the inlet (not shown) of the outer fluidic conduit 1003 located at the very top of the outer fluidic conduit 1003. This configuration is capable to support opposing flows of the carrier gas (illustrated by downward arrow 1005) and of the metal-containing precursor (illustrated by an upward arrow 1019), which makes the mixing of flows more efficient.

The outer fluidic conduit 1003 has a mixing zone 1021, where the metal-containing precursor and the carrier gas flows are allowed to mix without restrictions forming the mixed flow, illustrated by the downward arrow 1023. It is important to provide a mixing zone of adequate length, as mixing occurring in this zone affects the uniformity of precursor concentration in the showerhead. In some embodiments the length of the mixing zone L1 in the z-direction is at least about 102 mm, such as at least about 127 mm. For example at a flow of 1,000 sccm and an outer diameter of the outer tube of about 41 mm, the about 102 mm long mixing zone provides adequate mixing. In some embodiments a ratio of a length L1 of the flow mixing zone in z-direction to an inner diameter of the outer fluidic conduit 1003 is at least about 2, such as at least about 3.

In some embodiments, such as in the embodiment shown in FIG. 10, the outer fluidic conduit 1003 further has a restriction zone 1025, where the mixed flow 1023 is restricted into a plurality of more narrow channels located inside the outer fluidic conduit 1003. For example, in some embodiments the restriction zone contains six more narrow non-communicating channels, which carry the mixed flow to the outlet 1007. The restriction zone has a length L2 (e.g., between about 1-about 5 mm) in z direction. The mixed flow in the restricted zone is shown by a downward arrow 1027.

In some embodiments, the flow mixer 1001 is designed, such that the outlet 1017 from the inner fluidic conduit 1013 includes a flow diverter 1029, configured to divert flow of the metal-containing precursor before the metal-containing precursor flow mixes with the carrier gas flow in the outer fluidic conduit 1003, such that the diverted flow of the metal-containing precursor retains a velocity component opposing the velocity direction of the carrier gas flow in the outer fluidic conduit.

The flow diverter may include two parallel flow restrictor plates, configured to restrict the flow of the metal-containing precursor between the plates. For example, the upward flow of the metal-containing precursor my be diverted in a lateral direction making a less than a 90 degree turn, thereby retaining a velocity component that opposes the downward direction of the carrier gas flow: Retaining this opposing velocity component is an important factor for improving efficiency of mixing. In some embodiments the flow diverter 1029 includes a delivery tee with a plurality (e.g. six) evenly spaced radial openings.

In some implementations, a ratio of an inner diameter of the outer fluidic conduit to an inner diameter of the inner fluidic conduit is between about 1.5-about 10, such as between about 1.5-about 5. In a specific example, an inner diameter of the outer fluidic conduit is about 40.5 mm, and an inner diameter of the inner fluidic conduit is about 4.8 mm. In some implementations, the flow mixer has a total length in z-direction of between about 76-about 510 mm, such as between about 102-about 508 mm, such as about 124.5 mm. The flow mixer can be made from a variety of materials that are compatible with the metal-containing precursors, including aluminum, stainless steel, and ceramic.

### Multi-Plenum Showerhead

In another aspect, a multi-plenum showerhead for delivery of a plurality of reactants to a processing chamber, is provided. The showerhead may be used for delivery of any combination of reactants, including but not limited to molybdenum-containing and tungsten-containing precursors described herein. In some embodiments, the multi-plenum showerhead includes (a) a showerhead faceplate having a first plurality of conduits for delivery of a first reactant and a second plurality of conduits for delivery of a second reactant, wherein the first plurality of conduits is configured to be fluidically isolated from the second plurality of conduits; and (b) a showerhead housing positioned about the perimeter of the showerhead faceplate, wherein the showerhead faceplate is releasably attached to the showerhead faceplate. Because the showerhead is configured to have a removable faceplate, cleaning of the faceplate, which typically contains very small channels, can be performed with high efficiency. For example, the faceplate may be cleaned with the solvent, e.g. by immersion of the faceplate into the solvent and/or purging of channels with a solvent. In some embodiments the faceplate includes openings with a diameter of about 1 mm or less, such as 0.5 mm or less, that can be efficiently cleaned after the faceplate is removed from the base.

In some embodiments, the multi-plenum showerhead is a dual-plenum showerhead, where the first plurality of conduits is configured for delivery of a reactant (e.g., H₂, NH₃, SiH₄, B₂H₆, a hydrocarbon etc.) and the second plurality of conduits is configured for delivery of a metal-containing precursor (e.g., a molybdenum-containing or tungsten-containing precursor).

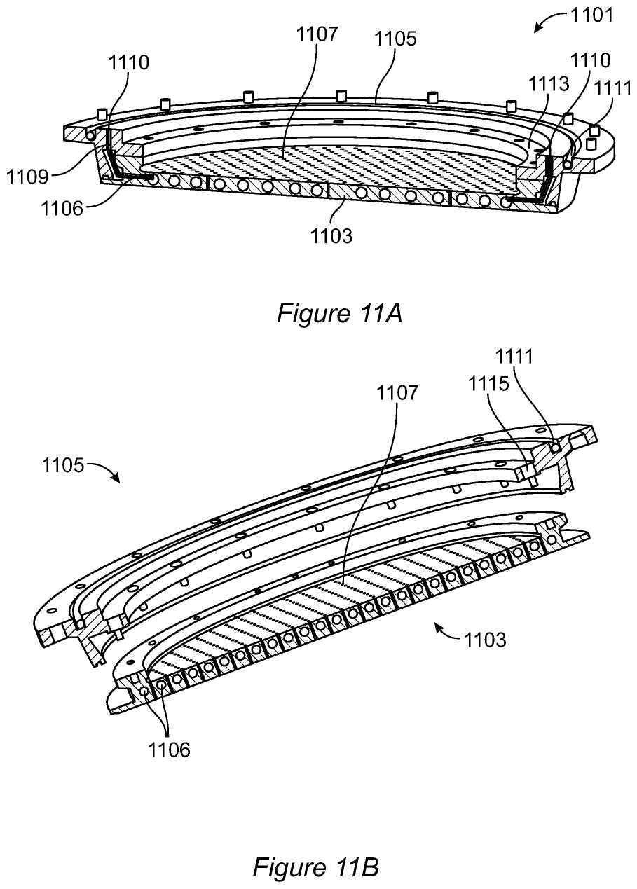

FIG. 11A shows a view of a portion of a dual-plenum showerhead 1101, which includes a faceplate 1103 and a housing 1105 attached to the faceplate 1103, where the housing 1105 is positioned about the perimeter of the faceplate 1103. The top portion of the faceplate 1103 contains a large number of openings of conduits 1107, configured to deliver a metal-containing precursor through the faceplate. The metal-containing precursor is delivered downward onto the faceplate, and is restricted by the showerhead housing on the sides. The faceplate 1103 also contains a plurality of fluidic conduits 1106, where fluidic conduits 1106 do not fluidically communicate with the metal precursor conduits 1107. The conduits 1106 are configured to receive a reactant (e.g., H₂, NH₃, etc.) from a reactant delivery annulus 1109 located in the housing 1105, and to laterally distribute the reactant through the showerhead faceplate 1103. The reactant conduits 1106 have a plurality of outlets on the bottom of the faceplate 1103 (not shown) configured for delivering the reactant to the processing chamber. These outlets, in some embodiments have diameters of about 1 mm or less or 0.5 mm or less. The outlets of both metal precursor conduits and reactant conduits open into the processing chamber. The conduits are designed such that the metal precursor and the reactant do not come into contact with each other in the body of the showerhead 1101.

While the showerhead faceplate 1103 serves to distribute and deliver the metal precursor and the reactant to the processing chamber without mixing them, the showerhead housing 1105 serves to confine a volume above the showerhead faceplate 1103 for the metal precursor, and to house a delivery annulus 1109 configured for delivery of the reactant to the reactant conduits 1106 of the showerhead faceplate 1103. The flow of the reactant through is shown by arrows 1110. The housing can further include a heater 1111, which may be annularly shaped, and embedded into a depression formed in the housing. The housing also typically includes a ledge 1113 for supporting an O-ring or another seal for sealing the showerhead to the metal precursor delivery line. FIG. 11B shows a portion of the showerhead faceplate 1103 and of the showerhead housing 1105 after the faceplate 1103 has been released from the housing 1105 (e.g., for cleaning). This view illustrates removable fasteners 1115 which are fitted into the openings in the housing 1105, and are configured to releasably attach the housing 1105 to the faceplate 1103 using openings about a perimeter of the faceplate 1103.

The showerhead faceplate can be manufactured from any materials, such as aluminum, stainless steel and ceramic materials, that are compatible with metal-containing precursors.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool: (2) curing of photoresist using a hot plate or furnace or UV curing tool: (3) exposing the photoresist to visible or UV, or eUV or x-ray light with a tool such as a wafer stepper: (4) developing the resist so as to selectively remove resist and thereby pattern it using a tool such as a wet bench. (5) transferring the resist pattern into an underlying film or work piece by using a dry or plasma-assisted etching tool; and (6) removing the resist using a tool such as an RF or microwave plasma resist stripper.

### Process Chamber Cleaning

Also provided herein are methods of cleaning the interior of process chambers and/or components in a process chamber. Some semiconductor device fabrication operations may involve various deposition processes to deposit various films to form integrated circuits and related devices by various methods including CVD, PECVD, ALD, or PEALD. A consequence of the deposition process is that the various materials are not only deposited on a substrate where the various materials are to be deposited, but also on the interior surfaces of the process chamber in which deposition processes occur. Consequently, the deposits from the various materials are formed on the interior surfaces of the process chamber, including interior walls of the process chamber or the surfaces of one or more parts in the process chamber, and the deposited materials may accumulate over time, forming a film or a particle. Additionally, the deposited material may dissolve, detach, thermally desorb, or evaporate through subsequent processes in the process chamber causing contamination of a substrate or features formed on a substrate. This contamination is one reason for low production yield/throughput, or the device reliability issue. Accumulated materials are periodically removed to avoid the contamination of the process chamber.

The methods described herein may be used to remove contaminants after deposition of metal-containing films, including those deposited by the methods described above. They may also be used to remove contaminants resulting from deposition of other types of films including dielectric films as described further below.

One way of removing contaminants deposited on the interior surfaces in the process chamber may involve introducing a plasma including fluorine (F) species. Radicals may be one or more species generated in a plasma, and plasma-activated species may include the radicals. The radicals may be referred to as radical species. Species may include source gas, plasma (e.g., radicals, ions, charged neutrals), or mixtures thereof. In some embodiments, the plasma may include radicals, ions, charged neutrals, or mixtures thereof. In one example, fluorine-containing species include fluorine-containing source gases, fluorine-containing plasma (e.g., radicals, ions, charged neutrals), or mixtures thereof. In another example, oxygen-containing species include oxygen-containing source gases, oxygen-containing plasma (e.g., radicals, ions, charged neutrals), or mixtures thereof.

For this type of cleaning, one or more source gases (e.g., cleaning gases) including nitrogen trifluoride (NF₃), fluorine (F₂), carbon tetrafluoride (CF₄), carbon hexafluoride (C₂F₆), octafluoropropane (C₃F₈), other fluorine-containing compounds (i.e., fluorine-containing reactants), or mixtures thereof, may be supplied to a plasma source. The plasma source may be an inductively coupled plasma reactor, a capacitively coupled plasma reactor, a microwave plasma reactor, a DC plasma reactor, or a laser-created plasma reactor. The plasma generated from the plasma source may include one or more radicals, and may flow into the process chamber to remove accumulated materials deposited on the interior surfaces of the process chamber.

### Cleaning of Molybdenum-Containing Films

Molybdenum nitride (MoNx, 0<X≤2) may be used for a gate electrode stack in a transistor structure. The molybdenum nitride film based gate electrode stack may provide a suitable work function for metal oxide semiconductor field effect transistor (MOSFET). Some applications, including fin field effect transistor (finFET) structures and dynamic random-access memory (DRAM) bit structures, may involve deposition of MoNx film for forming a gate electrode stack. MoNx may also be used in patterning a film due to its selectivity in wet etch.

A MoNx film may be deposited by any suitable deposition methods, e.g., ALD, PEALD, CVD, or PECVD using one or more molybdenum-containing precursors. The deposition methods may include any of those described above with reference to FIGS. 1A-11B. The cleaning methods are not limited to films deposited by those methods, any may be used to clean a chamber after deposition of a MoNx film by any appropriate method.

The MoNx film may be formed not only on a substrate where MoNx film is supposed to be formed, but also on interior surfaces of a process chamber. The interior surfaces include inner walls of the process chamber, or surfaces of any parts that may be located within the process chamber. For example, the interior surfaces may include inner wall surfaces of the process chamber, exterior surfaces of a showerhead, exterior surfaces of a pedestal, surfaces of a gas line, surfaces of a nozzle, surfaces of lift pins, surfaces of other chamber parts. After repeated deposition of MoNx films, the interior surfaces of a process chamber may also be deposited with MoNx and other materials that may have been deposited or etched in the process chamber, which may be periodically cleaned from the interior surfaces to avoid further contamination of a substrate in a subsequent semiconductor fabrication process.

### Process Flow

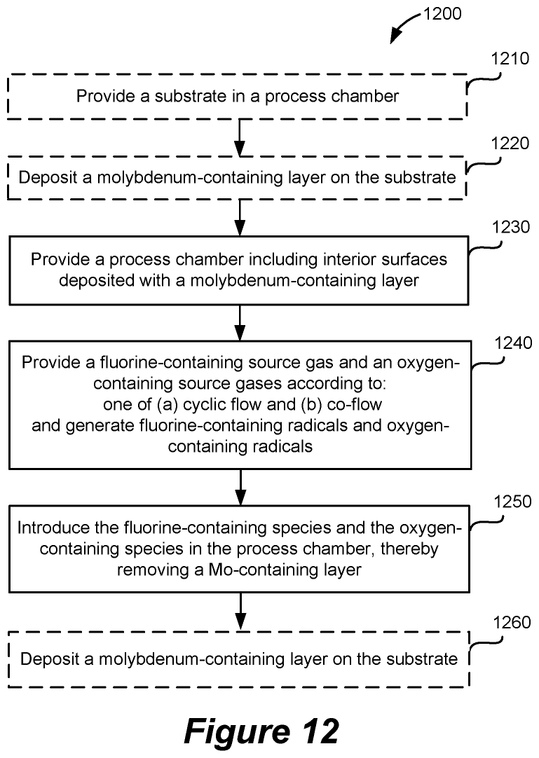

FIG. 12 illustrates a flow chart 1200 of an example method of cleaning the interior surfaces of a process chamber according to some embodiments. In optional operation 1210, a substrate may be provided in the process chamber for depositing a molybdenum-containing layer on a substrate. In some embodiments, a substrate with one or more features may be transported in the process chamber. For example, the one or more features on the substrate may be one or more partially fabricated integrated circuits. Prior to optional operation 1210, the substrate may be cleaned to remove any undesirable layer deposited on the substrate.

In optional operation 1220, a molybdenum-containing layer may be deposited in the one or more features on the substrate. The molybdenum-containing layer may include molybdenum metal, molybdenum nitride (MoNx), molybdenum oxynitride (MoONxNy, 0≤x≤1, 5=1-x), molybdenum oxide (MoOx, 0≤x≤1), molybdenum oxycarbonitride (MoNxOyCz, 0≤x≤1, 0≤ y≤1, y=1−x) or mixtures thereof. In some embodiments, the molybdenum-containing layer may be doped or undoped. For example, the molybdenum-containing layer may be doped with carbon.

The molybdenum-containing layer may be deposited using a molybdenum-containing precursor in the vapor deposition process, e.g., ALD, PEALD, CVD, or PECVD. Generally, molybdenum-containing precursors can include molybdenum in a wide range of oxidation states ranging from 0 to +6. In some embodiments, molybdenum compounds have molybdenum in low oxidation states of +3, +4 and −5. Provided methods are particularly useful for depositing molybdenum-containing materials from halogen-containing molybdenum-containing compounds, because silicon-containing reactants can assist in halogen scavenging, but halogen-free molybdenum-containing precursors can be used as well. Suitable molybdenum-containing precursors include molybdenum halides and oxyhalides, such as fluorides, chlorides, bromides, oxyfluorides, oxychlorides, and oxy bromides, where molybdenum may be in any of the oxidation states from +2 to +6.

Molybdenum-containing precursors for depositing ta molybdenum-containing layer may include the precursors discussed above. In some embodiments, molybdenum-containing precursors include molybdenum halide precursors and molybdenum oxyhalide precursors.

Examples of molybdenum halide precursors include molybdenum chloride. Molybdenum chloride is given by the formula MoClₓ, where x is 2, 3, 4, 5, or 6, and includes molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (e.g., fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

Molybdenum oxy halide precursors are given by the formula MoO_{y}X_{z}, where X is a halogen (fluorine (F), chlorine (Cl), bromine (Br), or iodine (I)) and y and z, are numbers greater than 0 such that MoO_{y}X_{z} forms a stable compound. Examples of molybdenum oxyhalide precursor include molybdenum tetrafluoride oxide (MoOF₄), molybdenum tetrachloride oxide (MoOCl₄), molybdenum dichloride dioxide (MoO₂Cl₂), molybdenum dibromide dioxide (MoO₂Br₂), and molybdenum oxyiodides (MoO₂I and Mo₄O₁₁I).

In some embodiments, the precursors have molecular weights of less than about 450 g/mol, such as less than about 400 g/mol.

In some embodiments the molybdenum containing precursor has a formula MoXₙYₘ, wherein X is a chalcogen (e.g., oxygen or sulfur), Y is a halogen (e.g., fluorine, chlorine, bromine, or iodine), n is 0, 1, or 2 and m is 2, 3, 4, 5, or 6. Examples of halogen-containing molybdenum-containing precursors include without limitation MoCl₅, Mo₂Cl₁₀, MoO₂Cl₂, and MoOCH₄. Another example of a halogen-containing molybdenum-containing precursor is MoF₆.

In some embodiments molybdenum-containing precursor includes carbonyl ligands. An example of a carbonyl-containing precursor is Mo(CO)₆.

Different molybdenum-containing precursors are described in U.S. Patent Application No. 62/816,648, entitled “precursors for deposition of molybdenum-containing films,” filed on Mar. 11, 2019, and U.S. Patent Application No. 63/366,888, entitled “remote plasma low temperature atomic layer deposition of metals,” filed Jun. 23, 2022, each of which is hereby incorporated by reference in its entirety and for all purposes.

In some embodiments, the molybdenum-containing layer may be formed in the one or more features of the substrate by ALD. In some embodiments, thermal ALD may be used to form the molybdenum-containing layer. In a thermal process, plasma is not used. ALD is a surface-mediated deposition technique in which doses of reactants are sequentially introduced into a process chamber. For example, one or more cycles of sequential doses of a molybdenum-containing precursor and one or more co-reactants may be used to deposit a molybdenum-containing layer. In one example, a molybdenum-containing precursor may be pulsed and adsorbed on the substrate at an elevated temperature to form a molybdenum-containing layer. A molybdenum-containing precursor may include hydrocarbon, and carbon in the molybdenum-containing precursor may not be completely removed when the molybdenum-containing layer is deposited. As a result, carbon may remain in the molybdenum-containing layer deposited on the inner surfaces. For example, the molybdenum-containing layer may be undoped or doped with carbon. For example, carbon may be included in the molybdenum-containing layer as a contaminant or dopant. In another example, carbon may be present on the surface of the molybdenum-containing layer as a very thin layer.

In some embodiments, a molybdenum-containing layer may include molybdenum oxynitride (MoOxNy). For example, the MoOxNy layer may be formed by flowing molybdenum halide or molybdenum oxyhalide precursor as a precursor and oxygen (O₂) and nitrogen (N₂) as co-reactants. The MoOxNy layer may be formed by flowing a molybdenum precursor described in U.S. Patent Application No. 62/816,648, entitled “precursors for deposition of molybdenum-containing films,” filed on Mar. 11, 2019, which is hereby incorporated by reference in its entirety and for all purposes. A mixture of oxygen and nitrogen with a predetermined mixing ratio may be introduced into the process chamber to react with a precursor to deposit the MoOxNy layer. The substrate may be heated to about 150° C. to about 650° C. The process chamber may be pressurized to a pressure that is between about 1 Torr and about 200 Torr. In some embodiments, the MoOxNy film may be reduced to form a MoNx film by flowing one or more reducing agents, such as nitrogen, argon, hydrogen, ammonia, other hydrogen-containing gasses, and mixtures thereof at a temperature of about 150° C. to about 650° C.

In operation 1230, a molybdenum-containing film is formed on interior surfaces of the process chamber. The molybdenum-containing film may constitute unwanted molybdenum-containing material formed on internal surfaces such as chamber walls, ceiling, showerhead, substrate support, gas lines, and other regions of the process chamber. In operations 1220, molybdenum-containing precursors may be flowed onto a substrate to form the molybdenum-containing layer. In some embodiments, depending on the parameters for depositing a molybdenum-containing layer, one or more molybdenum-containing precursors may also transport to locations in the process chamber other than the substrate, e.g., chamber walls, remote regions distant from the substrate, or surfaces of one or more chamber parts, e.g., a pedestal, a showerhead, gas lines, etc. The one or more molybdenum-containing precursors may form a deposit in the form of a layer or particles. This deposit may accumulate over a period of time when the one or more molybdenum-containing precursors are deposited in the process chamber or with the number of the substrates deposited with the molybdenum-containing layer. After a certain number of the substrates are deposited with a molybdenum-containing layer, or after a certain deposition or processing time in the process chamber is met, the substrate may be removed out of the process chamber for cleaning the interior surfaces of the process chamber. In one example, the molybdenum-containing layer may be formed in accordance with operation 120. In some embodiments, the presence of a molybdenum-containing film on the interior surfaces may be ascribed to a molybdenum-containing layer that survived an etch operation prior to the cleaning of the interior surfaces. In some embodiments, the molybdenum-containing film on the interior surfaces of the process chamber may include a carbon- and molybdenum-containing layer, e.g., an undoped or carbon-doped MoOx, an undoped or carbon-doped MoNx, an undoped or carbon-doped MoOxNy, or molybdenum metal. After the substrate is removed out of the process chamber, a chamber pressure may be adjusted to a certain pressure range prior to cleaning the interior surfaces of the process chamber. In some embodiments, the process chamber pressure may range between about 2 Torr and about 6 Torr, between about 2.5 Torr and about 5.5 Torr, between about 3 Torr and about 5 Torr, between about 0.5 Torr and about 2 Torr, between about 0.5 Torr and about 1.8 Torr, or between about 0.5 Torr and about 1.6 Torr.

After the molybdenum-containing film is formed on interior surfaces of the process chamber, in operation 1240, a fluorine-containing source gas and an oxygen-containing source gas may be supplied to a plasma source to generate a plasma including the fluorine-containing species and the oxygen-containing species. As discussed below, the fluorine-containing source gas and the oxygen-containing source gas may be supplied as a cyclic flow or as a co-flow.

In some embodiments, a fluorine-containing source gas may include nitrogen trifluoride, fluorine (F₂), molecular fluorine, carbon tetrafluoride, carbon hexafluoride, xenon difluoride, fluoromethane, difluoromethane, tetrafluoroethylene, hexafluoroethane, octafluoropropane, sulfur hexafluoride, or mixtures thereof. In some embodiments, an oxygen-containing source gas may include oxygen, ozone, carbon monoxide, carbon dioxide, nitrous oxide, nitrogen dioxide, or mixtures thereof. In some embodiments, the one or more source gases may be supplied with an inert gas (i.e., carrier gas) such as argon, helium, neon, krypton, xenon, or mixtures thereof. One or both of the fluorine-containing source gas and the oxygen-containing source gas may be mixed with the inert gas. Each of the fluorine-containing source gas and the oxygen-containing source gas may be ignited to generate a plasma including the fluorine-containing species (e.g., radicals) and the oxygen-containing species (e.g., radicals). Fluorine-containing radicals may be fluorine-containing species generated from a plasma, and may also include ions, charged neutrals, or mixtures thereof. Oxygen-containing radicals may be oxygen-containing species generated from a plasma, and may also include ions, charged neutrals, or mixtures thereof.

A plasma may be generated in-situ adjacent to a processing zone, where a deposition or etching operation occurs. Alternatively, a plasma may be generated from a remote plasma source. The remote plasma source may be located upstream of the process chamber, and may be separated from the process chamber by a showerhead. In some embodiments, the remote plasma source may be a sub-unit that may be detachably bolted to the side of the process chamber. The remote plasma source may be constructed such that a plasma from the remote plasma source may flow in a horizontal or vertical direction, depending on the location of the remote plasma source relative to the showerhead and/or the pedestal. In one example, a plasma may be supplied transverse to the showerhead from a remote plasma source positioned at a side of the process chamber.

A fluorine-containing source gas and an oxygen-containing source gas may be provided to the process chamber either cyclically or simultaneously (a co-flow) as will be described below.

### Cyclic Flow

In operation 1240, a fluorine-containing source gas and an oxygen-containing source gas may be cyclically supplied into a plasma source to generate the fluorine-containing species and the oxygen-containing species. In operation 1250, the fluorine-containing species and the oxygen-containing species generated in the plasma source may likewise be cyclically introduced into the process chamber. In some embodiments, the cyclic flow may include two operations: (a) supplying the fluorine-containing source gas in a plasma source, generating the fluorine-containing radicals (operation 1240), and introducing the fluorine-containing species into the process chamber (operation 1250), followed by (b) supplying the oxygen-containing source gas in the plasma source, generating the oxygen-containing species (operation 1240), and introducing the oxygen-containing species into the process chamber (operation 1250)). In other embodiments, a fluorine-containing source gas may be provided to a plasma source after an oxygen-containing source gas is provided to the plasma source.

In some embodiments, an appropriate amount of one or more inert gases may be pre-mixed with each of the fluorine-containing source gas and the oxygen-containing source gas before fluorine-containing radicals and oxygen-containing radicals are provided to the process chamber. In some embodiments, one of the species may be provided to the process chamber without striking a plasma. In one example, fluorine-containing species (e.g., fluorine-containing radicals) from a plasma and an oxygen-containing source gas, such as ozone, may be cyclically flowed into the process chamber. In another example, a fluorine-containing source gas, e.g., fluorine (F₂), and the oxygen-containing species (e.g., oxygen-containing radicals) may be cyclically flowed into the process chamber. Regardless of the type of the species introduced, the fluorine-containing species and the oxygen-containing species may cyclically flow towards the interior surfaces of the process chamber. One or both of the fluorine-containing species and the oxygen-containing species may react with a molybdenum-containing film, thereby removing the molybdenum-containing film from the interior surfaces. For example, fluorine-containing species may react with molybdenum in the molybdenum-containing film to form molybdenum fluoride, e.g., molybdenum hexafluoride (MoF₆), which may be volatile and may be removed from the process chamber by way of a vacuum pump. Oxygen-containing species, cyclically introduced into the process chamber, may oxidize carbon or carbon-containing compositions in the molybdenum-containing film to remove carbon by generating volatile byproducts, e.g., carbon monoxide (CO) or carbon dioxide (CO₂) from the molybdenum-containing film, accelerating the decomposition of the molybdenum-containing film from the interior surfaces.

### Co-Flow

In operation 1240, the fluorine-containing species and the oxygen-containing radicals may be co-flowed simultaneously towards the interior surfaces of the process chamber. For this co-flow, a fluorine-containing source gas, an oxygen-containing source gas, and an inert gas may be provided simultaneously in a plasma source. In some embodiments, more than one fluorine-containing source gases and/or more than one oxygen-containing source gases may be provided. The fluorine-containing source gas and the oxygen-containing source gas may be pre-mixed before they are supplied to the plasma source. Alternatively, they may be separately provided until they reach the entrance of the plasma source where they are co-flowed simultaneously. A plasma including the fluorine-containing species and the oxygen-containing species may be generated in the plasma source by igniting the plasma from the mixture of the source gases and inert gas. In operation 150, the fluorine-containing species and the oxygen-containing species generated in the plasma source may be simultaneously introduced towards the interior surfaces of the process chamber for cleaning the molybdenum-containing film. In some embodiments, one of the species may be provided to the process chamber without striking a plasma. In one example, fluorine-containing species (e.g., fluorine-containing plasma) from a plasma and an oxygen-containing source gas, such as ozone, may be co-flowed into the process chamber. In another example, a fluorine-containing source gas, e.g., fluorine, and an oxygen-containing species (e.g., oxygen-containing plasma) may be co-flowed into the process chamber.

In operation 1250, in some embodiments, volatile reaction byproducts such as molybdenum hexafluoride may be generated from the reaction between the fluorine-containing species and molybdenum, and may be removed from the process chamber by way of a vacuum pump. Oxygen-containing species may oxidize carbon or carbon-containing compositions that may be present in the molybdenum-containing film, and may generate other volatile reaction byproducts (e.g., CO or CO₂) from the molybdenum-containing film, thereby accelerating the decomposition of a molybdenum-containing film. The carbon concentration on the interior surfaces may reduce to zero or near zero level, thereby making the interior surfaces free of contaminants. For a co-flow, forming a volatile molybdenum fluoride byproduct and volatile carbon-containing byproduct (e.g., CO or CO₂) may occur substantially simultaneously.

After removing the molybdenum-containing film from the interior surfaces either by cyclic flow or simultaneous co-flow, an optional purge operation may follow by pulsing one or more inert gases (e.g., helium, neon, argon, krypton, xenon, or mixtures thereof) into the process chamber to remove any remaining fluorine-containing species, oxygen-containing species, or any reaction byproduct(s) from the process chamber.

In optional operation 160, a substrate may be provided in the process chamber for subsequent operation. For example, the substrate may be transported by a transfer tool for depositing a molybdenum-containing layer on the substrate. The molybdenum-containing layer may be deposited by ALD, PEALD, CVD. PECVD, or any suitable deposition process

### Processing Conditions for Cyclic Flow or Co-Flow

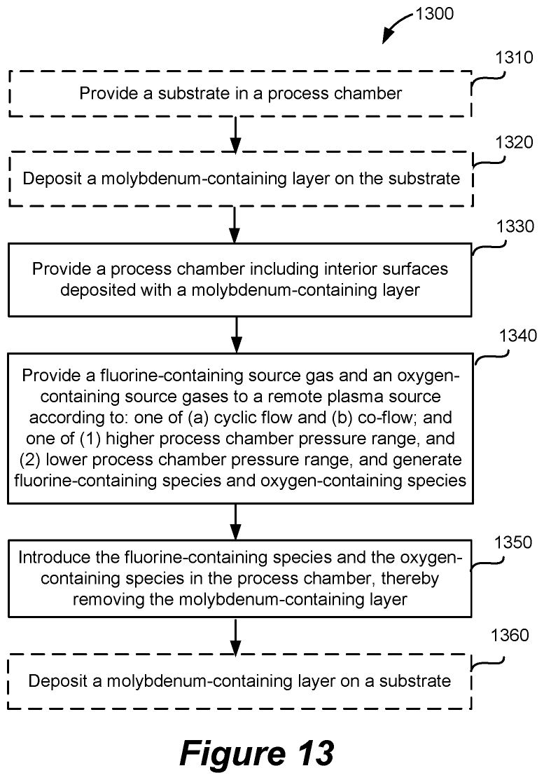

FIG. 13 illustrates a flow chart 1300 of an example method of cleaning interior surfaces of a process chamber according to some embodiments. Optional operations 1310, 1320, and operation 1330 in FIG. 13 may be substantially identical to optional operations 1210, 1220, and operation 1230 in FIG. 12, and further descriptions about optional operations 1310, 1320, and operation 1330 will be omitted.

In operation 1340, one or more fluorine-containing source gases (e.g., NF₃) and one or more oxygen-containing source gases (e.g., O₂) may be supplied to a remote plasma source, where a plasma including the fluorine-containing species and the oxygen-containing species may be generated and sustained. In some embodiments, NF₃ gas and O₂ gas may be supplied to the remote plasma source as source gases. An inert gas, e.g., helium, neon, argon, krypton, xenon, or mixtures thereof, may also be provided to the remote plasma source. The flow ratio between NF₃, O₂, and an inert gas may be adjusted as necessary. In some embodiments, a fluorine-containing source gas, an oxygen-containing source gas, and one or more inert gases may be introduced according to a cyclic flow or the simultaneous co-flow as discussed above. The cyclic flow or the simultaneous co-flow may be provided with certain processing conditions such as flow rates of the source gases and one or more inert gases, chamber pressure, and substrate temperature, which may individually or collectively contribute to the cleaning (etching) capability of the fluorine-containing species and the oxygen-containing species generated in the plasma source (e.g., remote plasma source). In some embodiments. Table 1 includes the processing conditions set A at higher chamber pressure range, which includes the processing conditions A1-A3. In some embodiments, Table 2 includes the processing conditions set B at lower chamber pressure range, which includes the processing conditions B1-B3.

The processing conditions in Table 1 and Table 2 may be designed based on the location and/or composition of a molybdenum-containing film on the interior surfaces of the process chamber. In some embodiments, higher chamber pressure may lead to a reduced ionization of the source gas and increased recombination. For example, the chamber pressures may be adjusted to about 2 Torr to about 6 Torr, about 2.5 Torr to about 5.5 Torr, or about 3 Torr to about 5 Torr (as shown in Table 1) to facilitate removing the molybdenum-containing film (e.g., MoNx) located at or near a pedestal or a carrier ring. In some embodiments, lower chamber pressure may facilitate increased ionization of the source gas and reduced recombination. Reduced recombination may be beneficial in removing the molybdenum-containing film formed on a ceiling or other interior surfaces where it takes a relatively longer time for the species (e.g., radicals and/or ions) to travel. For example, the presence of chamber parts or structures (e.g., showerhead) in the process chamber may delay or block the transport of the fluorine-containing species and/or the oxygen-containing species to the ceiling or other isolated area, in which case an increased number of radicals or ions with reduced recombination may be more efficient in removing the molybdenum-containing film. For example, the lower chamber pressures range of about 0.5 Torr to about 2 Torr, about 0.5 Torr to about 1.8 Torr, or about 0.5 Torr to about 1.6 Torr (as shown in Table 2) may be desirable in removing molybdenum-containing film (e.g., MoOx) deposited on an area where longer transport time for the species is required. In some embodiments, the presence of the carrier gas may serve the same effect as lowering the chamber pressure. For example, the flow rates of an inert gas are higher in Table 2 than in Table 1, and may further increase ionization of the source gas and reduce recombination than Table 1.

According to some embodiments, one or more processing conditions may be involved in removing the molybdenum-containing film. For cyclic flow, in some embodiments, a fluorine-containing source gas and an oxygen-containing source gas may be cyclically supplied to a plasma source according to any one of the processing conditions listed in Table 1 and Table 2. In some embodiments, a fluorine-containing source gas and an oxygen-containing source gas may be supplied to the plasma source under different processing conditions. One or more inert gases may be mixed with each of the fluorine- and oxygen-containing source gases. For co-flow, a fluorine-containing source gas, an oxygen-containing source gas, and an inert gas may be simultaneously supplied as a co-flow to a plasma source according to any one of the processing conditions in Table 1 and Table 2. In some embodiments, the co-flow may be repeated more than once according to another of the processing conditions in Table 1 and Table 2.

TABLE 1
processing conditions for fluorine-
and oxygen-containing source gases

| | Set A | | |
|---|---|---|---|
| Processing conditions | A1 | A2 | A3 |
| Substrate temperature (° C.) | 200-650 | 300-600 | 350-550 |
| Chamber Pressure (Torr) | 2-6 | 2.5-5.5 | 3-5 |
| Inert gas flow (slm*) | 1-2 | 1-2 | 1-1.8 |
| Fluorine-containing source gas (slm) | 0.5-3 | 0.5-3 | 0.5-2.5 |
| Oxygen-containing source gas (slm) | 0.5-2 | 0.5-1.8 | 0.5-1.5 |
| Time (seconds) | 2-60 | 2-60 | 2-60 |

*slm = standard liter per minute

TABLE 2
processing conditions of fluorine-
and oxygen-containing source gases

| | Set B | | |
|---|---|---|---|
| Processing conditions | B1 | B2 | B3 |
| Substrate temperature (° C.) | 200-650 | 300-600 | 350-550 |
| Chamber Pressure (Torr) | 0.5-2 | 0.5-1.8 | 0.5-1.6 |
| Inert gas flow (slm) | 6-9 | 6-8.8 | 6-8.5 |
| Fluorine-containing source gas (slm) | 0.5-1.5 | 0.5-1.5 | 0.5-1.2 |
| Oxygen-containing source gas (slm) | 0.5-1.5 | 0.5-1.5 | 0.5-1.2 |
| Time (seconds) | 2-60 | 2-60 | 2-60 |

Operation 1340 may be followed by operation 1350, where the fluorine-containing species and the oxygen-containing species generated in operation 1340 may be introduced into the process chamber. The fluorine-containing species and the oxygen-containing species may be introduced into the process chamber in the same way as the fluorine-containing source gas and the oxygen-containing source gas are supplied to a plasma source. For cyclic flow, a first source gas (e.g., fluorine-containing source gas) flowing at a flow rate in accordance with one of the processing conditions in A1-A3 and B1-B3 is mixed with an inert gas flowing at an appropriate flow rate and supplied to the plasma source, and then the first species generated from the first source gas may flow into the process chamber. Subsequently, a second source gas (e.g., oxygen-containing source gas) flowing at a flow rate in the processing condition selected for the first source gas is mixed with the inert gas flowing at an appropriate flow rate and supplied to the plasma source, where the second species is generated and flowed into the process chamber for cleaning the interior surfaces of the process chamber. In some embodiments, the total flow rates of the inert gases mixed with the first and second source gases may correspond to the inert gas flow rate in the processing condition selected for the first source gas.

For co-flow, a first source gas, a second source gas, and an inert gas may co-flow into the plasma source (e.g., remote plasma source) to generate a mixture including the first species and the second species, which are simultaneously flowed to the process chamber. The molybdenum-containing film may be removed from the interior surfaces when the molybdenum-containing film is exposed to the fluorine-containing species and the oxygen-containing species.

After the cleaning operation, an optional purging operation may be performed. Also, the operations 1340 and/or 1350 may be repeated once or more than once. In optional operation 1360, a new substrate may be transferred into the process chamber for subsequent operation such as deposition or etch operation. For example, a molybdenum-containing layer may be deposited on the new substrate.

### Cyclic Flow for Removal of Carbon- and Molybdenum-Containing Film

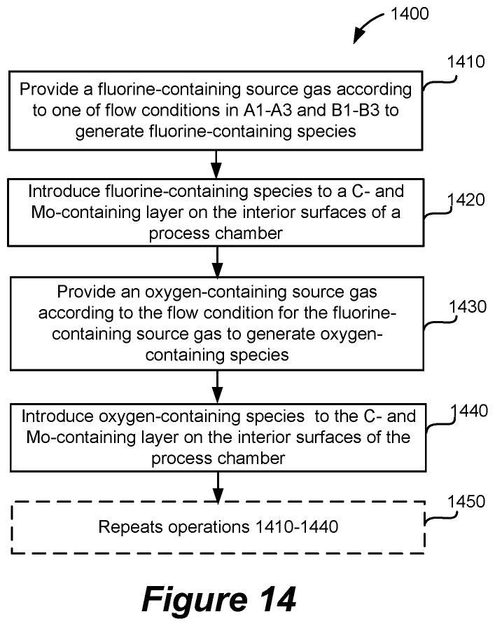

FIG. 14 is a flow chart of an example method of cleaning the interior surfaces of a process chamber deposited with carbon- and molybdenum-containing film according to some embodiments. The operations in the flow chart 1400 may be performed in accordance with a cyclic flow. The operations in the flow chart 1400 may be performed in different orders and/or with fewer, or additional operations. The flow chart 1400 begins from operation 1410, where the fluorine-containing source gas (e.g., NF₃) may be provided to a plasma source in accordance with one of the processing conditions described in A1-A3 and B1-B3 in Tables 1 and 2, thereby generating a fluorine-containing species. An appropriate portion of inert gas(es) selected for the fluorine-containing source gas in operation 1410 may also be provided to mix with the fluorine-containing source gas. In operation 1420, the fluorine-containing species generated may be introduced into the process chamber and react with a carbon- and molybdenum-containing film, e.g., carbon-containing MoOx, carbon-containing MoNx, or carbon-containing MoOxNy, to remove the carbon- and molybdenum-containing film from the interior surfaces of the process chamber. Fluorine-containing species may include fluorine-containing source gases, fluorine-containing plasma (e.g., radicals, ions, charged neutrals), or mixtures thereof. Subsequently, in operation 1430, the oxygen-containing source gas (e.g., O₂) may be supplied to the plasma source in accordance with the processing condition selected for the fluorine-containing source gas in operation 1410 to generate the oxygen-containing species in the plasma source. An appropriate portion of the inert gas(es) may also be provided to mix with the oxygen-containing source gas. In operation 1440, the oxygen-containing species generated in operation 1430 may be introduced into the process chamber for oxidizing carbon or carbon-containing compositions in the carbon- and molybdenum-containing film. In some embodiments, oxygen-containing species may include oxygen-containing source gases, oxygen-containing plasma (e.g., radicals, ions, charged neutrals), or mixtures thereof.

The flow rates for the fluorine-containing source gas in operation 1410 and the oxygen-containing source gas in operation 1430 may be selected from any of the processing conditions in Tables 1 and 2. The flow rates for operations 1410 and 1430 may be configured to be the same, or may be different from each other. After operation 1440 is complete, in operation 1450, operations 1410-1440 may be optionally repeated once or more than once as necessary.

### Co-Flow for Removal of Carbon- and Molybdenum-Containing Film

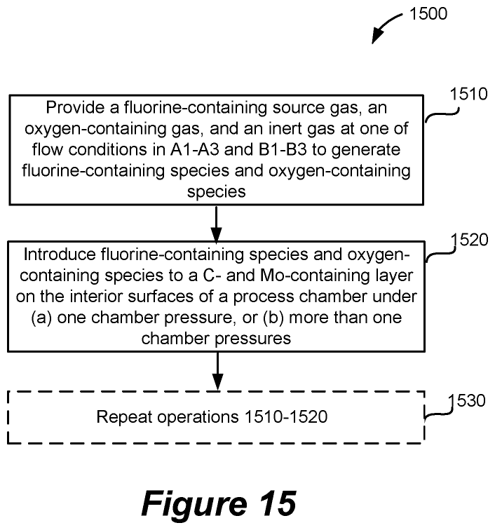

FIG. 15 is a flow chart of an example method of cleaning interior surfaces of a process chamber deposited with carbon- and molybdenum-containing film according to some embodiments. The operations in the flow chart 1500 may be performed in accordance with a co-flow. The operations in the flow chart 1500 may be performed in different orders and/or with fewer, or additional operations. In operation 1510, a fluorine-containing source gas (e.g., NF₃), an oxygen-containing source gas (e.g., O₂), and an inert gas may be supplied to a plasma source as a co-flow in accordance with one or more than one of the processing conditions A1-A3 and B1-B3 in Tables 1 and 2 to generate a fluorine-containing species and an oxygen-containing species in the plasma source. In operation 1520, the fluorine-containing species and the oxygen-containing species generated may be introduced into the process chamber to react with the carbon- and molybdenum-containing film.

In some embodiments, the processing condition may be one of the processing conditions described in A1-A3 and B1-B3, where the chamber pressure may not be changed until the chamber cleaning is complete. In some embodiments, the chamber cleaning may involve more than one of the processing conditions, and the process chamber pressure may be modified during cleaning. For example, the chamber may be exposed to a fluorine-containing species and an oxygen-containing species for a first duration at a first chamber pressure, then the chamber pressure may be changed to a second chamber pressure for a second duration. In some embodiments, the chamber pressure may change from a higher pressure to a lower pressure. For example, the first chamber pressure may be between about 2 Torr and about 6 Torr, between about 2.5 Torr and about 5.5 Torr, or between about 3 Torr and about 5 Torr, and the second chamber pressure may be between about 0.5 Torr and about 2 Torr, between about 0.5 Torr and about 1.8 Torr, or between about 0.5 Torr and about 1.6 Torr. In some embodiments, the chamber pressure may change from a lower pressure to a higher pressure. For example, the first chamber pressure may be between about 0.5 Torr and about 2 Torr, and the second chamber pressure may be about 2 Torr and about 6 Torr.

In some embodiments, fluorine-containing species may include fluorine-containing source gases, fluorine-containing plasma (e.g., radicals, ions, charged neutrals), or mixtures thereof, and oxygen-containing species may include oxygen-containing source gases, oxygen-containing plasma (e.g., radicals, ions, charged neutrals), or mixtures thereof. For example, during the first duration, the chamber may be exposed to a fluorine-containing plasma and an oxygen-containing plasma, and during the second duration, the chamber may be exposed to a fluorine-containing plasma and an oxygen-containing species in a plasma-free environment (e.g., ozone or other oxygen-containing source gas). Alternatively, during the first duration, the chamber may be exposed to a fluorine-containing plasma and an oxygen-containing species in a plasma-free environment, and during the second duration, the chamber may be exposed to a fluorine-containing plasma and an oxygen-containing plasma. An optional purging operation may be performed after operation 1520.

In optional operation 1530, operations 1510 and 1520 may be repeatedly performed once or more than once. The processing conditions in operation 1530 may be identical to or different from the flow conditions adopted in the operation 1510 performed prior to performing operation 1530.

### Apparatus

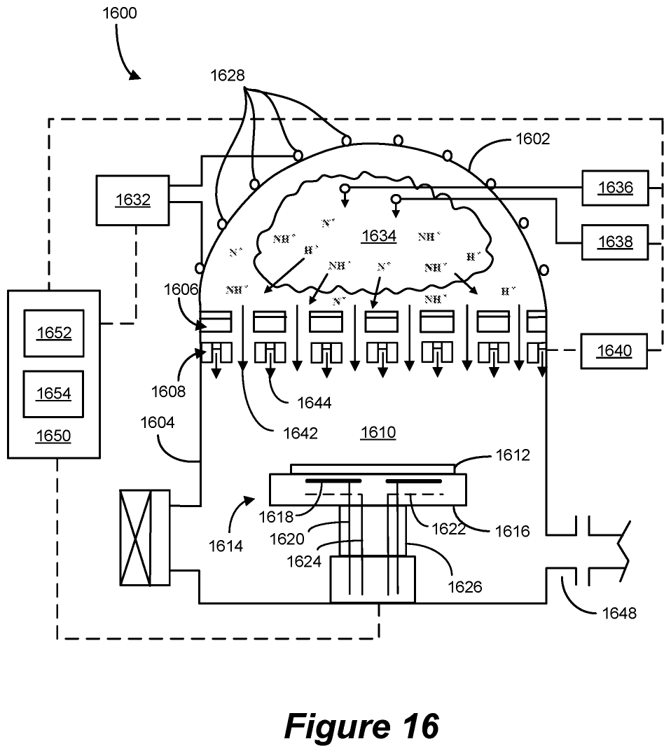

FIG. 16 illustrates a schematic diagram of an example processing apparatus with a remote plasma source according to some implementations. It will be understood that the process chamber in FIG. 16 may be used to deposit a silicon-containing layer or a molybdenum-containing layer, and/or to etch the silicon-containing layer or the molybdenum-containing layer formed in the process chamber according to some embodiments. In some embodiments, a silicon-containing layer or a molybdenum-containing layer may be formed in the process chamber, followed by etching in the same process chamber using a remote plasma source without exposing the silicon-containing layer or the molybdenum-containing layer to ambient atmosphere.

The plasma processing apparatus 1600 includes a remote plasma source 1602 separated from a process chamber 1604. The remote plasma source 1602 is fluidly coupled with the process chamber 1604 via a gas distributor or showerhead 1606. In some embodiments, the showerhead 506 includes an ion filter for filtering ions to limit ion bombardment damage to a substrate 1612. Radical species and/or ions are generated in the remote plasma source 1602, where the radical species may be supplied to the process chamber 1604. Precursors such as one or more molybdenum-containing precursors are supplied to the process chamber 1604 through one or more precursor gas outlets 1608 (e.g., manifolds) positioned downstream from the remote plasma source 1602 and from the showerhead 1606. A manometer, a butterfly valve, or any other pressure-monitoring device may be fluidly coupled to the process chamber 1604 to maintain a certain pressure range of the process chamber 1604 when the one or more molybdenum-containing precursors are flowing into the process chamber.

The substrate 1612 is supported on a substrate support structure or wafer pedestal 1614. The wafer pedestal 1614 may be configured with lift pins or other movable support members to position the substrate 1612 within a process zone (i.e., deposition/etch zone 1610). The substrate 1612 may be moved to a position closer or farther from the showerhead 1606. The wafer pedestal 1614 is shown in FIG. 16 as having elevated the substrate 1612 within the deposition/etch zone 1610.

In some embodiments, the wafer pedestal 1614 includes an electrostatic chuck 1616. The electrostatic chuck 1616 includes one or more electrostatic clamping electrodes 1618 embedded within a body of the electrostatic chuck 1616. In some embodiments, the one or more electrostatic clamping electrodes 1618 may be coplanar or substantially coplanar. The electrostatic clamping electrodes 1618 may be powered by a DC power source or DC chucking voltage (e.g., between about 200 V to about 2000 V) so that the substrate 512 may be retained on the electrostatic chuck 1616 by electrostatic attractive forces. Power to the electrostatic clamping electrodes 1618 may be provided via first electrical lines 1620. The electrostatic chuck 1616 may further include one or more heating elements 1622 embedded within the body of the electrostatic chuck 1616. The one or more heating elements 1622 may include resistive heaters. In some embodiments, the one or more heating elements 1622 are positioned below the one or more electrostatic clamping electrodes 1618. The one or more heating elements 1622 may be configured to heat the substrate 1612 to a temperature greater than about 450° C., greater than about 500° C., greater than about 550° C., greater than about 600° C., or greater than about 650° C. The one or more heating elements 1622 provide selective temperature control to the substrate 1612. Power to the one or more heating elements 1622 may be provided via second electrical lines 1624.

A coil 1628 is arranged around the remote plasma source 1602, where the remote plasma source 1602 includes an outer wall (e.g., quartz dome). The coil 1628 is electrically coupled to a plasma generator controller 1632, which may be used to form and sustain plasma within a plasma region 1634 via inductively coupled plasma generation. In some embodiments, the plasma generator controller 1632 may include a power supply for supplying power to the coil 1628, where the power can be in a range between about 300 W and about 15 KW per station, or between about 1 KW and about 10 KW per station during plasma generation. In some embodiments, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 1634, radical species may continuously be generated using plasma excitation during a layer formation (e.g., film deposition) and/or remote plasma treatment.

In some embodiments, fluorine-containing radicals including fluorine radicals (F*), hydrogen-containing radicals including hydrogen radicals (H*), nitrogen-containing radicals including nitrogen radicals (N*), oxygen-containing radicals including oxygen radicals (O*), carbon-containing radicals including carbon radicals (C*), amine-containing radicals including amine radicals (NH*, NH₂*), or combinations thereof, are generated in the plasma region 1634 under approximately steady-state conditions during steady-state film deposition or a remote plasma treatment as controlled by the plasma generator controller 1632, though transients may occur at the beginning and end of film deposition and/or remote plasma etch. In one example, fluorine-containing radicals may be generated in the plasma region 1634. In another example, oxygen-containing radicals may be generated in the plasma region 1634. In yet another example, both fluorine-containing radicals and oxygen-containing radicals may be generated in the plasma region 1634. Though FIG. 16 shows nitrogen (N*) and amine radicals (NH*), it will be understood that the foregoing radicals are illustrative only and that other radicals may be present additionally or alternatively to the radicals depicted in FIG. 16.

A supply of ions and radicals may be continuously generated within the plasma region 1634 while one or more source gases are being supplied to the remote plasma source 1602. Ions generated in the plasma region 1634 may be filtered out by the ion filter of the showerhead 1606. That way, radicals generated in the plasma region 1634 may be supplied to the substrate 1612 in the process chamber 1604 while limiting ion bombardment. Conditions in the remote plasma source 1602, including a composition of the source gas provided to the remote plasma source 1602 and RF power supplied to the coil 1628, may be controlled to optimize generation of desired radical species in the plasma region 1634. In some embodiments, the source gas may include an oxygen-containing reactant such as oxygen, ozone, carbon monoxide, carbon dioxide, nitrous oxide, nitrogen dioxide, or mixtures thereof, fluorine-containing reactant such as nitrogen trifluoride, fluorine (F₂), molecular fluorine, carbon tetrafluoride, carbon hexafluoride, xenon difluoride, fluoromethane, difluoromethane, tetrafluoroethylene, hexafluoroethane, octafluoropropane, sulfur hexafluoride, or mixtures thereof. In some embodiments, the source gas may include nitrogen trifluoride, fluorine (F₂), oxygen, or combinations thereof.

In some embodiments, the source gas may be mixed with one or more additional gases. These one or more additional gases may be supplied to the remote plasma source 1602. In some embodiments, the source gas is mixed with one or more additional gases to form a gas mixture, where the one or more additional gases can include a carrier gas. Non-limiting examples of additional gases can include helium, neon, argon, krypton, xenon, or mixtures thereof. The one or more additional gases may support or stabilize steady-state plasma conditions within the remote plasma source 1602 or aid in transient plasma ignition or extinction processes. In FIG. 16, a source gas supply 1636 is fluidly coupled with the remote plasma source 1602 for supplying the source gas. While not shown another source gas supply may be fluidly coupled with the remote plasma source 1602 for supplying another source gas. For some embodiments, about 5 sccm to about 4,000 sccm, or about 200 sccm to about 4,000 sccm, or about 500 sccm to about 3,000 sccm, or about 500 sccm to about 2,000 sccm, or about 500 sccm to about 1,500 sccm of source gas may be supplied from a source gas supply 1636. In addition, an additional gas supply 1638 is fluidly coupled with the remote plasma source 1602 for supplying the one or more additional gases. For some embodiments, one or more carrier gases (inert gases), e.g., helium, neon, argon, krypton, xenon or mixtures thereof, may be supplied to the remote plasma source 1602. For some embodiments, about 1,000 sccm to about 9,000 sccm, or about 1,000 sccm to about 2,000 sccm, or about 6,000 sccm to about 9,000 sccm of the one or more carrier gases may be supplied from the additional gas supply 1638. While the embodiment in FIG. 16 depicts the gas mixture of the source gas and the one or more additional gases being introduced through separate gas outlets, it will be understood that the gas mixture may be introduced directly into the remote plasma source 1602. That is, a pre-mixed dilute gas mixture may be supplied to the remote plasma source 1602 through a single gas outlet.

Plasma-activated species 1642, such as excited nitrogen, hydrogen, carbon, oxygen, and/or fluorine radicals, flow out of the remote plasma source 1602 and into the process chamber 1604 via one or more gas outlets (e.g., showerhead 1606). The one or more gas outlets may include one or more manifolds. A manometer, butterfly valve, or other pressure-monitoring device may be fluidly coupled to the process chamber 1604 to maintain a certain pressure range of the process chamber 1604 when a fluorine-containing species and an oxygen-containing species are flowing into the process chamber. In some embodiments, a process chamber pressure may operate in a low-pressure regime between about 0.5 Torr and about 2 Torr or a high-pressure regime between about 2 Torr and about 6 Torr. Plasma-activated species 1642 within the showerhead 1606 and within the process chamber 1604 are generally not subject to continued plasma excitation therein. The showerhead 1606 may have a plurality of gas ports to diffuse the flow of plasma-activated species 1642 into the process chamber 1604. In some embodiments, the plurality of gas ports may be mutually spaced apart. In some embodiments, the plurality of gas ports may be arranged as an array of regularly spaced apart channels or through-holes extending through a plate separating the remote plasma source 1602 and the process chamber 1604. The plurality of gas ports may smoothly disperse and diffuse exiting radicals (including plasma-activated species 1642) from the remote plasma source 1602 into the deposition/etch zone 1610 of the process chamber 1604 while filtering out ions.

With the delivery of the plasma-activated species 1642 to the process chamber 1604 from the showerhead 1606, precursors 1644 (or other process gases) may be introduced into the process chamber 1604. The precursors 1644 may include molybdenum-containing precursors. The precursors 1644 may be introduced via precursor gas outlets 1608, where the precursor gas outlets 1608 may be fluidly coupled with a precursor supply source 1640. The precursor gas outlets 1608 may include mutually spaced apart openings so that the flow of the precursors 1644 may be introduced in a direction parallel with the plasma-activated species 1642 flowing from the showerhead 1606. In some embodiments, the precursor gas outlets 1608 may be located downstream from the showerhead 1606. In some embodiments, the precursor gas outlets 1608 are part of the showerhead 1606 such as in a dual-plenum showerhead. The dual-plenum showerhead may provide separate outlets/passages for the plasma-activated species 1642 and the precursors 1644 to avoid mixing in the showerhead 1606. That way, the precursors 1644 may flow into the process chamber 1604 via the showerhead 1606 without exposure to plasma in the remote plasma source 1602. The precursor gas outlets 1608 may be located upstream from the deposition/etch zone 1610 and the substrate 1612. The deposition/etch zone 1610 is located within the interior of the process chamber 1604 between the precursor gas outlets 1608 and the substrate 1612.

In film deposition process, a substantial fraction of the precursors 1644 may be prevented from mixing with plasma-activated species 1642 in the showerhead 1606 or adjacent to the showerhead 1606. In some embodiments, precursors 1644 may be delivered to the substrate 1612 in dose phases of ALD cycles separate from plasma-activated species 1642 delivered to the substrate 1612 during plasma exposure phases of the ALD cycles. Adsorbed precursors 1644 may react with radicals of the plasma-activated species 1642 during plasma exposure phases of the ALD cycles to deposit film, such as a silicon-containing layer or a molybdenum-containing layer. In some embodiments, precursors 1644 may be delivered to the substrate 1612 in a continuous manner to interact with plasma-activated species 1642 in a deposition/etch zone 1610 to deposit film by CVD. In some embodiments, the plasma-activated species 1642 may be delivered to the substrate 1612 without delivery of the precursors 1644 to etch a silicon-containing layer or a molybdenum-containing layer deposited on the substrate, or on the interior surfaces of the process chamber, such as interior walls.

Gases may be removed from the process chamber 1604 via an outlet 1648 that is fluidly coupled to a pump (not shown). Thus, radical species or purge gases may be removed from the process chamber 1604.

In some embodiments, a thermal shield (not shown) may be positioned underneath the wafer pedestal 1614. The thermal shield serves as a thermal insulator under the wafer pedestal 1614 to mitigate heat loss via thermal radiation, thereby reducing the amount of power needed to maintain the wafer pedestal 1614 at a particular elevated temperature and also preventing other components within the process chamber 1604 from overheating due to excess heat radiated from the wafer pedestal 1614. For example, the thermal shield may be radially offset from the stem 1626 and may have a thin annular-shaped body with a high view factor relative to the underside of the electrostatic chuck 1616. Thus, the annular-shaped thermal shield may reduce radiative heat loss from the wafer pedestal 1614.

In some embodiments, a controller 1650 (e.g., system controller) is in operative communication with the plasma processing apparatus 1600. In some embodiments, the controller 1650 includes a processor system 1652 (e.g., microprocessor) configured to execute instructions held in a data system 1654 (e.g., memory). In some embodiments, the controller 1650 may be in communication with the plasma generator controller 1632 to control plasma parameters and/or conditions in the remote plasma source 1602. In some embodiments, the controller 1650 may be in communication with the wafer pedestal 1614 to control pedestal elevation, electrostatic chucking and dechucking, and temperature. In some embodiments, the controller 1650 may control other processing conditions, such as RF power settings, frequency settings, duty cycles, pulse times, pressure within the process chamber 1604, pressure within the remote plasma source 1602, gas flow rates from the source gas supply 1636, gas flow rates from the additional gas supply 1638 and other sources, temperature of the wafer pedestal 1614, and temperature of the process chamber 1604, among other processing conditions.

The controller 1650) may contain instructions for controlling process conditions for the operation of the plasma processing apparatus 1600. The controller 1650 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 1650 or they may be provided over a network.

In certain embodiments, the controller 1650 controls all or most activities of the plasma processing apparatus 1600 described herein. For example, the controller 1650 may control all or most activities of the plasma processing apparatus 1600 associated with film deposition and/or a remote plasma etch. The controller 1650 may also control all or most activities of the plasma processing apparatus 1600 associated with in situ chamber cleaning. The controller 1650 may execute system control software including sets of instructions for controlling the timing, gas composition, gas flow rates, chamber pressure, chamber temperature, RF power levels, substrate position, substrate temperature, and/or other parameters. Other computer programs, scripts, or routines stored on memory devices associated with the controller 1650 may be employed in some embodiments. In a multi-station reactor, the controller 1650 may include different or identical instructions for different apparatus stations, thus allowing the apparatus stations to operate either independently or synchronously.

In some embodiments, the controller 1650 may include instructions configured to perform operations such as depositing a molybdenum-containing layer on the substrate 1612, and exposing interior surfaces of the process chamber 1604 to plasma-activated species 1642 generated in the remote plasma source 1602 to remove molybdenum-containing film formed on interior surfaces of the process chamber 1604. In some embodiments, exposing the interior surfaces of the process chamber 1604 to the plasma-activated species 1642 occurs by modulating one or more of the following parameters: chamber pressure, substrate temperature, time of exposure, and flow rates of the one or more source gases or one or more carrier gases.

In some embodiments, the plasma processing apparatus 1600 may include a user interface associated with controller 1650. The user interface may include a display screen, graphical software displays of the plasma processing apparatus 1600 and/or process conditions, and user input devices such as pointing devices, keyboards, touch screens, microphones, etc. The computer program code for controlling the above operations can be written in any conventional computer readable programming language. Aspects of the controller 1650 in FIG. 16 are further described by the description above of the controller 929 in FIG. 9.

### Cleaning of High-K Dielectric Materials

In some embodiments, various films other than molybdenum may be deposited during semiconductor device fabrication operations. The thin films for the integrated circuit (IC) fabrication operations may include dielectric materials. The dielectric materials may include metal-containing oxides, nitrides, or carbides. For example, gate dielectric for a transistor may be formed by depositing various oxides or nitrides, such as silicon oxide (SiO₂), hafnium oxide (HfO₂), zirconium oxide (ZrO₂), silicon oxynitride (SiON), or mixtures thereof. In addition to gate dielectrics, dielectric materials may be used for other elements of semiconductor devices such as insulating features in metallization layers, isolation trenches, and memory cell structures. Some of the various thin films may including dielectric materials such as high-k dielectric materials deposited on the features or substrate. The metal-containing dielectric materials may be deposited using a precursor by a suitable deposition process such as ALD. PEALD, CVD, epitaxial growth, or PECVD. The precursor (e.g., a gaseous precursor) may react to form a metal-containing layer on the substrate, but the precursor may also transport to another location within the process chamber, where it may be deposited as a condensed form (e.g., solid film, particle, or wall deposit). Depending on the deposition temperature and/or the sublimation temperature, the metal-containing dielectric materials, as deposited on the chamber wall or other chamber component, may sublimate, transport, flake off, or otherwise re-deposit on other components or surfaces within the process chamber. The re-deposition of the metal-containing dielectric materials may occur on the substrate, thereby modifying the composition of the thin films on the substrate, creating a device reliability issue and adversely affect the manufacturing throughput. The process chamber may be cleaned periodically to remove the metal-containing dielectric materials from the inner surfaces of the process chamber.

Certain criteria may be considered in designing and conducting a chamber cleaning process. First, the temperature of the process chamber wall or other component being cleaned may be kept relatively low during the chamber cleaning operation to reduce potential damage to chamber components from exposure to thermal energy and/or to reduce energy consumption. For example, keeping the temperature of the process chamber wall consistently above 200° C. may require constant operation of heaters and may increase the likelihood of oxidation of aluminum or aluminum-containing alloy(s) used for construction of the process chamber. In some embodiments, during the chamber cleaning, the temperature of the process chamber wall may be preferably kept at about 125 to about 200° C., or less than about 200° C. Second, an intermediate chamber pressure range may be maintained during the chamber cleaning. Reaching a low chamber pressure may require a powerful vacuum pump and may consequently require additional time before starting the chamber cleaning operation, thereby increasing the overall chamber cleaning cycle. High chamber pressure, particularly in a non-inert environment, may form an undesirable oxide or other film on the inner surfaces of the process chamber. In some embodiments, the chamber pressure may be preferably kept at about 0.5 to about 50 Torr. Third, the etch rate of a film from chamber components may be sufficiently high that the overall chamber cleaning cycle has a short duration. In some embodiments, the etch rate may be preferably about 500 to about 1,000 angstroms per minute. Fourth, the process chamber cleaning may be designed so as to generate a volatile reaction product rather than a non-volatile reaction product that can require additional cleaning operations. Fifth, the one or more chemicals used in cleaning may be readily available and have a relatively low cost. Also, the chemicals may be ones that do not chemically react with the materials of the chamber wall or other component being cleaned.

Provided herein are methods for cleaning one or more dielectric materials from one or more components of a process chamber. The one or more components may include surfaces of a process chamber, a pedestal, a showerhead, a foreline, etc. The chamber cleaning operation may include two-part cleaning operation including (i) introducing fluorine-containing species (such as fluorine radicals produced by a remote plasma), and (ii) introducing one or more thermal etchants in the process chamber. Thermal etching uses gas-phase reagents to react with a substrate surface and to etch materials from the substrate surface chemically and/or thermally. As used herein, thermal etching may also be referred to as “chemical etching” and vice versa. Thermal etching can be applied over a wide range of materials. Selectivity may be desired in thermal etch reactions so that one material is removed in the presence of other materials. Selectivity m etching has many applications in semiconductor device fabrication and surface cleaning. The selectivity may be higher in thermal etching compared to other conventional etching techniques, such as plasma etching or sputtering. Thermal etching generally involves a solid etch material and a gaseous eich precursor. An etch precursor (e.g., thermal etchant) is any reactant gas in a thermal etch reaction that reacts with the solid etch material to facilitate removal of the solid etch material from a substrate surface. In some implementations, an etch precursor may modify a surface layer of the substrate surface, and thermal energy may be applied to eich the modified surface layer. The one or more thermal etchants may include a halide such as a chloride or bromide compound. In the first part, the fluorine-containing species may react with the dielectric material, generating a fluorine-containing reaction product such as a fluoride of a metal in the dielectric material. The fluorine-containing reaction product may be non-volatile. In the second part, the thermal etchant may react with the fluorine-containing reaction product to produce a volatile reaction product, which may be a chloride or a bromide of a metal in the dielectric material. The cleaning operation may also include removing the volatile reaction product from the process chamber. In some embodiments, a metal fluoride reaction product and the thermal etchant react by a ligand exchange reaction to produce a volatile chloride or bromide of the same metal. The ligand exchange reaction may refer to a reaction replacing a fluorine in a metal fluoride with halogen element to form a metal halide. The halogen element may include Br or Cl.

The two-part cleaning process in accordance with some embodiments may reasonably satisfy some or all of the above-mentioned criteria for a process chamber cleaning process. For example, the two-part cleaning process may involve keeping the temperature of the process chamber below approximately 200° C., therefore preventing high energy consumption and potential oxidation of metal components such as aluminum-containing components or inner walls of the process chamber. In some embodiments, the two-part cleaning process does not require low chamber pressure during the cleaning operation, therefore reducing the time for overall cleaning cycle. For example, the two-part cleaning process may involve the chamber pressure of about 0.5 to about 100 Torr. According to some embodiments, high etch rate (about 500 to about 1,000 angstroms per minute) may be obtained by the two-part cleaning process. Also, as described above, the two-part cleaning process may include generation of a volatile reaction product via the second part of the process (exposure of the chamber to a thermal etchant). The volatile reaction product may be relatively easily removed from the process chamber using, for example, a vacuum pump. In addition, the thermal etchants involved in the two-part cleaning process may include halogen elements that are not reactive with the aluminum or aluminum-containing materials from which one or more components are made of. Also, no major upgrade to the processing apparatus including a process chamber would be necessary in cleaning the process chamber by the two-part cleaning process according to some embodiments.

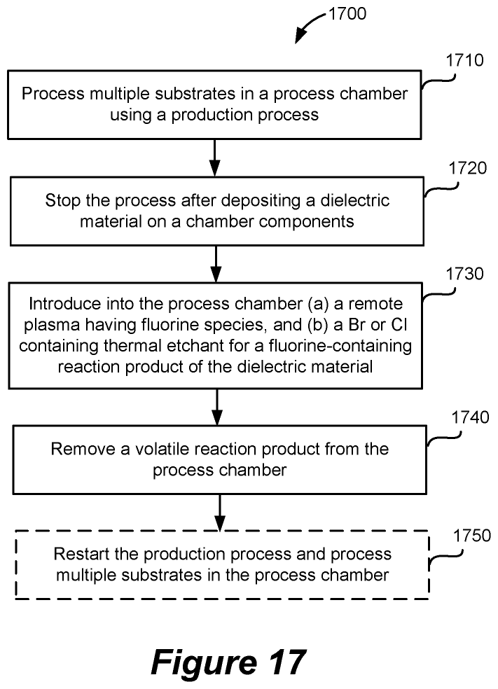

Generally, the methods disclosed herein are used to remove a dielectric material from the interior surfaces or other component of the process chamber. The dielectric materials may include metal containing oxides such as hafnium oxide, zirconium oxide, aluminum oxide, tin oxide, yttrium oxide, lanthanum oxide, or mixtures thereof. The dielectric materials may include metal containing nitrides such as hafnium nitride, zirconium nitride, aluminum nitride, or mixtures thereof. The dielectric materials may be removed by exposing the dielectric materials to a fluorine-containing species and a non-fluorine halogen-containing species. The halogen may include bromine (Br) or chlorine (Cl). The reactions according to some embodiments may generate only volatile product that may be relatively easily removed from the process chamber. In some embodiments, the methods are performed at the temperature of about 50 to about 650° C. FIG. 17 illustrates a flow chart of an example of removing a dielectric material in accordance with some embodiments. The operations of the flow chart 100 may be performed in different orders and/or with different, fewer, or additional operations. In operation 110, multiple substrates may be processed in a process chamber using a production process. The production process may include depositing a dielectric film on one or more substrates by any suitable deposition route such as ALD, PEALD, CVD, or PECVD by flowing a chemical precursor, one or more reactants, or one or more purge gases. The dielectric film may include any of many possible metal containing oxides. For example, it may comprise hafnium oxide, zirconium oxide, aluminum oxide, tin oxide, yttrium oxide, lanthanum oxide, or mixtures thereof. Metal containing nitrides, carbides, oxynitrides, oxy carbides, and the like may also be deposited according to some embodiments. For example, the metal containing nitrides may include hafnium nitride, zirconium nitride, aluminum nitride, or mixtures thereof. During the deposition on a substrate, the dielectric film may also be formed on the interior surfaces of the process chamber or the surfaces of other components positioned in the process chamber. The dielectric film formed on the surfaces of the process chamber or other components may get thicker with the repeated production process in the process chamber. While much of the discussion herein focuses on production processes that are deposition processes, the invention is not limited to deposition processes. Any production processes that produce dielectric films on a process chamber component may employ a cleaning process as described herein. For example, the production process may include etching or otherwise removing a dielectric film from one or more substrates. The processed substrates may include one or more features formed thereon.

Operation 1710 involves processing multiple substrates. After each of these substrates is processed, it is removed from the process chamber. For example, a transfer tool may be used in removing the substrate out of the process chamber without breaking a vacuum.

In operation 1720, the production process may be stopped. In some embodiments, a semiconductor device fabrication process may be stopped. In some embodiments, while the process is stopped, no further wafers are processed using the production process. Instead, the process chamber or a component therein is cleaned to remove a film formed thereon.

In operation 1730, a remote plasma having a fluorine-containing species and a Br or Cl containing thermal etchant may be introduced into the process chamber to remove a dielectric material from the interior surfaces. While much of the discussion herein focuses on using fluorine-containing species generated by a remote plasma, the disclosed cleaning processes are not limited to remote plasma sources. For example, fluorine radicals produced by any method may be employed.

A process gas may be flowed into the remote plasma source where RF power is applied to the remote plasma source to generate plasma-activated species (e.g., radicals/ions) of the process gas. The process gas may include a fluorine-containing chemistry. In some embodiments, the source gas for generating the plasma may include nitrogen fluoride (NF₃), tetrafluoromethane (CF₄), trifluoromethane (CHF₃), difluoromethane (CH₂F₂), fluoromethane (CH₃F), sulfur hexafluoride (SF₆), octafluoropropane (C₃F₈), octafluorocyclobutane (C₄F₈), hexafluorocyclobutene (C₄F₆), 1,2,3,3,4-pentafluorocyclobutene-4-ylradical (C₄F₅), fluorine (F₂) or mixtures thereof.

In some embodiments, the thermal etchant may include hydrogen bromide (HBr), hydrogen chloride (HCl), boron trichloride (BCl₃), or mixtures thereof, or boron bromide (BBr₃), phosphorous trichloride (PCl₃), carbon tetrachloride (CCl₄), nitrogen trichloride (NCl₃), or mixtures thereof.

In some embodiments, a remote plasma may be generated in a remote plasma source that may be fluidly coupled to the process chamber. The remote plasma may include the plasma-activated species. The plasma-activated species may include fluorine-containing species. The remote plasma source for generating the remote plasma may include an inductively coupled plasma (ICP), a transformer coupled plasma (TCP), a capacitively coupled plasma (CCP), a microwave plasma, a DC plasma, a laser-created plasma, or other plasma technique known in the art. The plasma may be delivered from the remote plasma source into the process chamber so that the plasma-activated species are distributed towards the one or more internal surfaces of the process chamber. In some embodiments, the plasma is delivered from the remote plasma source into the process chamber through a showerhead. Additionally or alternatively, the plasma is delivered from the remote plasma source into the process chamber through a distributor that preferentially directs the plasma to the one or more internal surfaces of the process chamber.

In some embodiments, the fluorine-containing species and the Br or Cl containing thermal etchant may be co-flowed into the process chamber for a predetermined time to react with and remove the dielectric material on the interior surfaces of the process chamber. In some embodiments, one or more fluorine-containing process gases may be flowed from a process gas supply (e.g., first process gas supply) into the remote plasma source where RF power is applied to the remote plasma source to generate a remote plasma including plasma-activated species (e.g., radicals/ions) of the fluorine-containing process gases. The plasma-activated species may include fluorine-containing species. In some embodiments, the Br or Cl containing thermal etchant may be supplied from a process gas supply (e.g., second process gas supply) to the remote plasma source, in which the remote plasma including the fluorine-containing species and the Br or Cl containing thermal etchant may be pre-mixed and co-flowed in the process chamber. In another example, a remote plasma including the fluorine-containing species and the Br or Cl containing thermal etchant may be separately supplied to the entrance of the process chamber, and they may be mixed in the process chamber. In some embodiments, the fluorine-containing species and the thermal etchant are flowed cyclically. Each cycle may include a first phase of flowing the fluorine-containing species and a second phase of flowing the thermal etchant.

In some embodiments, the remote plasma (which may produce the fluorine-containing species) may not electronically activate the Br or Cl containing thermal etchant. For example, the Br or Cl containing thermal etchant may not be mixed with or may not react with the fluorine-containing species within the remote plasma. Once introduced in the process chamber, the plasma-activated fluorine-containing species may react with a dielectric material to form a fluorine-containing reaction product. For example, a metal containing oxide may be converted into a non-volatile metal fluoride. Substantially at the same time, in co-flow embodiments, the non-volatile metal fluoride may react with the Br or Cl containing thermal etchant to produce a Br or Cl containing product (e.g., a metal bromide or a metal chloride) that is volatile. The reaction of the metal fluoride and the thermal etchant may be the ligand exchange reaction. In the case of HfO₂, the HfO₂ may react with a fluorine-containing species to form a non-volatile HfF₄. The HfF₄ is non-volatile, and may react with BCl₃, the Br or Cl containing thermal etchant, to produce a volatile reaction product (e.g., HfCl₄). During or after operation 1730, the volatile reaction product(s) may be removed from the interior surfaces of the process chamber, leaving the interior surfaces free of the dielectric material.

In some embodiments, a remote plasma having a fluorine-containing species and a Br or Cl containing thermal etchant may be cyclically introduced. A remote plasma including the fluorine-containing species may be introduced first in the process chamber for a predetermined time. Subsequently the Br or Cl containing thermal etchant may be introduced in the process chamber for a predetermined time. Although the fluorine-containing species is introduced prior to the introduction of the Br or Cl containing thermal etchant, a dielectric material (e.g., metal containing oxides) may be removed from the interior surfaces of the process chamber according to a reaction sequence that is substantially similar to that of the co-flow embodiment described above.

In some embodiments, the cyclic introduction of the remote plasma including the fluorine-containing species and the Br or Cl containing thermal etchant may be optionally repeated in accordance with a process recipe. For example, the cyclic introduction may be repeated more than once.

In some embodiments, the chamber pressure in operation 1730 may be about 0.5 to about 100 Torr, or about 1 to about 80 Torr. The chamber temperature may be about 50 to about 650° C. or about 50 to about 450° C. The etch rate of the dielectric material may be about 500 to about 1,000 angstroms per minute.

In some embodiments, water and/or alcohol such as methyl alcohol, ethyl alcohol, or propyl alcohol is added in operation 1730. For the cyclic introduction, the water or alcohol may be introduced in the process chamber separate from the introduction of the remote plasma or the Br or Cl containing thermal etchant. For the co-flow, the water or alcohol, the remote plasma, and Br or Cl containing thermal etchant may be co-flowed in the process chamber. In some cases, the addition of water and/or alcohol increases the etch rate of the dielectric material.

In operation 1740, one or more volatile reaction product may be removed from the process chamber via a vacuum pump that is fluidly coupled to the process chamber, thereby leaving the interior surfaces of the process chamber free of the dielectric materials. For example, the one or more volatile reaction products may also include O₂, F₂, or Cl₂.

In operation 1750, one or more substrates may be optionally provided in the process chamber to restart the production process. The substrates may be transferred into the process chamber by a transfer tool for depositing a dielectric material on the features or on the substrates. Deposition process may be repeated until the thickness of a thin film, a wall deposit, or particles on the interior surfaces of the process chamber exceeds a predetermined threshold.

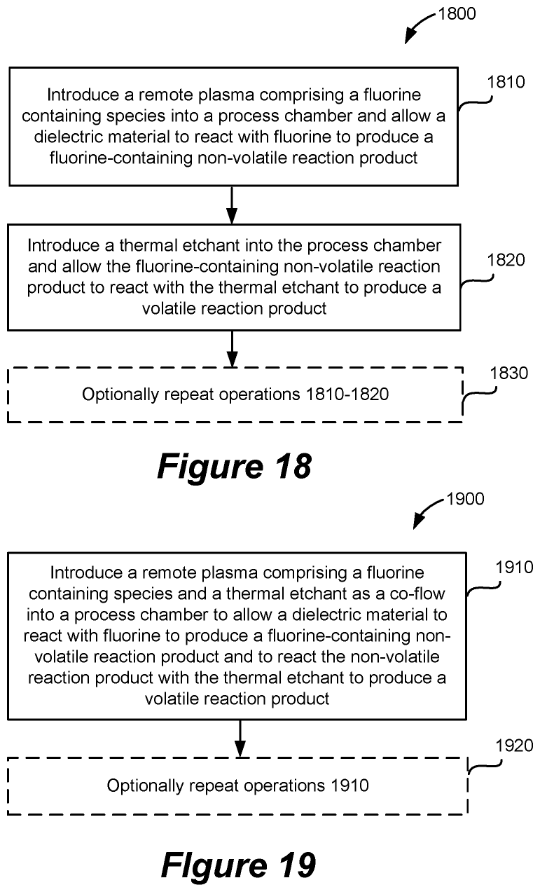

FIG. 18 illustrates a flow chart of an example of removing a dielectric material in accordance with some embodiments. The operations of the flow chart 1800 may be performed in different orders and/or with different, fewer, or additional operations. The flow chart 1800 may relate to a cyclic flow of a fluorine-containing species and a Br or Cl containing thermal etchant.

In operation 1810, a remote plasma including a fluorine-containing species is introduced into the process chamber, and a dielectric material deposited on the interior surfaces of the process chamber reacts with the fluorine-containing species to produce a fluorine-containing non-volatile reaction product.

In some embodiments, the time to expose the dielectric material to the fluorine-containing species may depend on the diffusion of fluorine in the dielectric material and the chamber temperature. It is to be appreciated that the time for introducing the fluorine-containing species or the thermal etchant may be identical or substantially identical to the time to expose the interior surfaces or the dielectric material on the interior surfaces to the fluorine-containing species or the thermal etchant. In some embodiments, the reaction between the fluorine-containing species and a dielectric material may be completed when a fluorine-containing non-volatile reaction product (e.g., HfF₄) is formed in the entire dielectric material to be removed. For example, longer exposure time to the fluorine-containing species may be necessary for a dielectric material where fluorine diffuses slowly. For a dielectric material where fluorine diffuses quickly, reduced exposure time may be necessary in introducing the fluorine-containing species into the process chamber. The exposure time may have an inverse proportional relationship with the chamber temperature during the introduction of the fluorine-containing species. For example, it may take longer exposure time when the chamber temperature is relatively low. In some embodiments, the dielectric material may be exposed to the fluorine-containing species for about 30 to about 300 seconds. For example, the fluorine-containing species (i.e., fluorine species) is introduced to the process chamber for about 30 to about 300 seconds.

In operation 1820, a thermal etching may be performed by introducing a thermal etchant including Br or Cl into a process chamber, and a dielectric material deposited on the interior surfaces of the process chamber reacts with the fluorine-containing species to produce a fluorine-containing non-volatile reaction product. The thermal etchant (e.g., BCl₃) may be provided to the process chamber to react with the fluorine-containing non-volatile reaction product (e.g., HfF₄) such that the fluorine-containing non-volatile reaction product is converted to a volatile reaction product (HfCl₄). In some embodiments, the non-volatile reaction product may be exposed for about 30 to about 300 seconds. For example, a thermal etchant may be introduced to the process chamber for about 30 to about 300 seconds.

A two-step etch reaction including operations 1810 and 1820 may involve converting a non-volatile reaction product formed in operation 1810 to a volatile reaction product in operation 1820. A dielectric material such as a metal containing oxide or a metal containing nitride may be converted to a metal containing fluoride (e.g., the non-volatile reaction product) by exposing to the fluorine-containing species in operation 1810. In operation 1820, the fluorine ligand in the metal containing fluoride may be replaced with another non-fluorine halogen ligand such as Br or Cl in the thermal etchant to form a more volatile reaction product than the metal containing fluoride. The metal element in the metal containing oxide (or nitride) may include hafnium, zirconium, tin, aluminum, or mixtures thereof.

In some embodiments, a single cycle including a full conversion of the dielectric coating and a thermal etching is all that is needed in removing the dielectric material. The fluorine-containing species may diffuse into the entire thickness of the dielectric material to be removed, and convert the entire or substantially entire thickness to a metal fluoride. Subsequently, fluorine ligands in the entire coating may be replaced by the Br or Cl ligand to form a volatile reaction product to complete the etching process.

In operation 1830, the operations 1810-1820 may be optionally repeated more than once according to a process recipe. In some embodiments, a cycle including a partial diffusion/conversion and a thermal etching may be repeated more than once to remove the dielectric materials. Instead of fully penetrating the fluorine-containing species through the entire dielectric material to be removed, in the first cycle, the dielectric materials may be exposed to the fluorine-containing species for a predetermined time period and converted to fluoride for subsequent thermal etching. In the one or more next cycles, the remaining dielectric materials may undergo the same process as the first cycle until the entire dielectric material is removed from the interior surfaces of the process chamber. In one example, the etch rate for the dielectric material may be about 500) to about 1,000 angstroms per minute.

FIG. 19 illustrates a flow chart of an example of removing a dielectric material in accordance with some embodiments. The flow chart 1900 may relate to a co-flow of the fluorine-containing species and the Br or Cl containing thermal etchant. In operation 1910, a remote plasma including a fluorine-containing species and a Br or Cl containing thermal etchant may be co-flowed into the process chamber. In some embodiments, a remote plasma and a thermal etchant may be introduced for about 0.1 to about 600 seconds. The co-flow according to operation 1910 may reduce the overall etching cycle time, compared to the cyclic flow. In operation 1910, formation of metal containing fluoride (i.e., non-volatile reaction product) by the fluorine-containing species, and formation of the volatile reaction product by reacting with thermal etchant may substantially occur at the same time. Water vapor and/or alcohol such as methyl alcohol, ethyl alcohol, or propyl alcohol may be mixed with the fluorine-containing species and the Br or Cl containing thermal etchant to accelerate the etching of the dielectric material. In operation 1920, operation 1910 may be performed more than once according to a process recipe.

Hafnium oxide (HfOx) is an example of a metal-containing dielectric material that may be deposited on the substrate by, e.g., ALD, PEALD, CVD, or PECVD using one or more hafnium-containing precursors. Hafnium oxide is sometimes used for forming a gate dielectric stack. During deposition of hafnium oxide on the substrate, hafnium oxide may also be formed as a thin film, wall deposit, or particles on the inner surfaces of the process chamber or the surfaces of one or more components in the process chamber. Cleaning hafnium oxide deposits from a wall or component is a challenging problem.

According to some embodiments, hafnium oxide formed on the inner surfaces of the process chamber or components may be react with fluorine-containing species such as NF₃ plasma to form hafnium tetrafluoride (HfF₄) and oxygen according to the following reaction:

4F*+HfO₂→HfF₄ (non-volatile)+O₂ (1)

The reaction product, HfF₄, is not volatile, and may form solid particles within the process chamber or stay on the inner surfaces of the process chamber as a contamination source. An additional operation may be necessary to remove non-volatile HfF₄ from the process chamber.

In some embodiments, hafnium oxide may be removed from the inner surfaces of the process chamber by reacting with boron trichloride (BCl₃) according to the following reaction:

4BCl₃+3HfO₂→3HfCl₄ (volatile)+2B₂O₃ (2)

The reaction involving BCl₃ may produce a volatile reaction product. HfCl₄, which may be relatively easily removed from the process chamber via vacuum pump, while a non-volatile B₂O₃ may still stay within the process chamber. Thus, an additional reaction may be needed to avoid forming non-volatile B₂O₃ and/or converting it to a volatile product.

In some embodiments, HfO₂ may be exposed to a fluorine-containing species (i.e., fluorine species or fluorine-containing radicals) and BCl₃, and the following reactions (3) and (4) may occur.

4F*+HfO₂→HfF₄+O₂ (3a)

3HfF₄+4BCl₃→3HfCl₄ (volatile)+4BF₃ (3b)

12F*+3HfO₂+4BCl₃→3HfCl₄(volatile)+4BF₃+3O₂ (4)

In the reactions (3a) and (3b), the fluorine species is introduced in the process chamber first, and BCl₃ is introduced in the process chamber after the fluorine species is introduced in the process chamber. In the first step of the reaction (3a), HfO₂ may react with a fluorine species to generate a non-volatile HfF₄. In the second stage of the reaction (3b), BCl₃ is provided to react with HfF₄ to produce a volatile HfCl₄ that may be removed from the process chamber with BF₃. In the reaction (4), the fluorine species and BCl₃ are co-flowed in the process chamber. The co-flow of the fluorine species and BCl₃ may still undergo similar reaction sequences as the reaction (3), and produce volatile products, e.g., HfCl₄, O₂, and BF₃. Regardless of the order of introducing the fluorine species and the BCl₃, HfO₂ may have a preference to react with the fluorine species at first and then the resulting HfF₄ and BCl₃ undergo a ligand exchange reaction to produce the volatile HfCl₄. The above reactions can be generalized to any reactions that first react a metal containing dielectric with a fluorine species (e.g., fluorine radicals) and then react the resulting metal fluoride with a chlorine or bromine containing species via a ligand exchange reaction to produce a volatile metal chloride or metal bromide.

### Applications

The interior surfaces of the process chamber or surfaces of the components positioned in the process chamber deposited with a dielectric material may be cleaned according to some embodiments. The interior surfaces may include the inner walls of the process chamber, a pedestal, a showerhead, a foreline, or other components that may be in contact with the precursor and other reactants, thereby forming a thin film, a wall deposit, or a particle on the interior surfaces. The dielectric material may include a metal containing oxide or a metal containing nitride with a metal element such as hafnium, zirconium, tin, aluminum, or mixtures thereof, and may include hafnium oxide, zirconium oxide, tin oxide, yttrium oxide, lanthanum oxide, aluminum oxide, hafnium nitride, zirconium nitride, aluminum nitride, or mixtures thereof. Removing the dielectric material according to some embodiments may involve removing a dielectric material that may produce a non-volatile reaction product by reacting with a fluorine-containing species, with a ligand (e.g., fluorine) in the non-volatile reaction product capable of being replaced with another ligand for producing a metal compound that may be more volatile than the non-volatile reaction product.

### Apparatus

An apparatus of the present disclosure is configured for process chamber clean such as a plasma clean followed by thermal etching. The apparatus may be configured for other processing operations such as deposition, development, and etch operations. In some embodiments, the apparatus is configured to perform all wet etch and dry etch operations. The apparatus may include a single wafer chamber or multiple stations in the same process chamber. With multiple stations in the same process chamber, various processing operations such as those described in the present disclosure may be performed in different stations in the same process chamber.

The apparatus may be configured to include a remote plasma source separated from a process chamber. In some embodiments, the remote plasma source may be positioned upstream of the process chamber. The remote plasma source may be fluidly coupled with the process chamber via a showerhead to the process chamber. The remote plasma source may also be fluidly coupled with one or more gas supplies to receive one or more process gases including fluorine to generate a fluorine-containing species.

The apparatus may include a process gas supply to supply a thermal etchant to the process chamber via a gas line. In some embodiments, the process gas supply may be fluidly coupled to the remote plasma source where the thermal etchant may be mixed with a remote plasma generated in the remote plasma source, and a mixture is delivered in the process chamber. In some embodiments, the process gas supply may provide thermal etchant directly from the process gas supply to the process chamber without mixing with the remote plasma until the thermal etchant is introduced in the process chamber. The additional gas supply may be equipped with a heater to control the temperature of the thermal etchant in the process chamber.

The apparatus may also be configured to include an evacuating system such as vacuum pump to remove any fluorine-containing species, thermal etchants, any reaction product from the process chamber during or after the chamber cleaning.

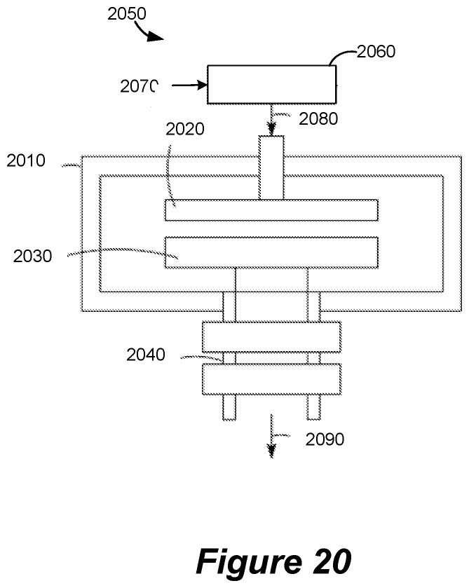

FIG. 20 shows a cross-section of an example remote plasma system fluidly couple to an example process chamber in accordance with some embodiments. The process chamber 2010 may include a showerhead 2020, a pedestal 2030 for supporting a substrate including one or more features formed on the substrate. The pedestal 2030 may be coupled to a gate valve 2040, which may be opened to exhaust process gas and any reaction product from the process chamber 2010. The remote plasma system 2050 may include a remote plasma source 2060 in which a process gas 2070 may be flowed from a first process gas supply (not shown here) and RF power is applied to the remote plasma source 2060 to generate plasma activated species (e.g., radicals/ions of fluorine-containing species) of the process gas. The process gas may include nitrogen fluoride (NF₃), tetrafluoromethane (CF₄), trifluoromethane (CHF₃), difluoromethane (CH₂F₂), fluoromethane (CH₃F), sulfur hexafluoride (SF₆), octafluoropropane (C₃F₈), octafluorocyclobutane (C₄F₈), hexafluorocyclobutene (C₄F₆), 1,2,3,3,4-pentafluorocyclobutene-4-ylradical (C₄F₅), fluorine (F₂), or mixtures thereof. The remote plasma source 2060 may include an ICP, a TCP, a CCP, a microwave plasma, a DC plasma, or a laser-created plasma. The plasma activated species generated in the remote plasma source 2060 may be supplied to the process chamber 2010 via a gas inlet 2080 that is the fluidly coupled to the showerhead 2020. A thermal etchant described herein may be provided from a second process gas supply (not shown here) that is fluidly coupled to the process chamber 2010 to deliver the thermal etchant in the process chamber. In some embodiments, the second process gas supply may be fluidly coupled to the remote plasma source 2050. The process chamber 2010 may also include a vacuum pump 2090 for removing a process gas and reaction product from the process chamber 2010.

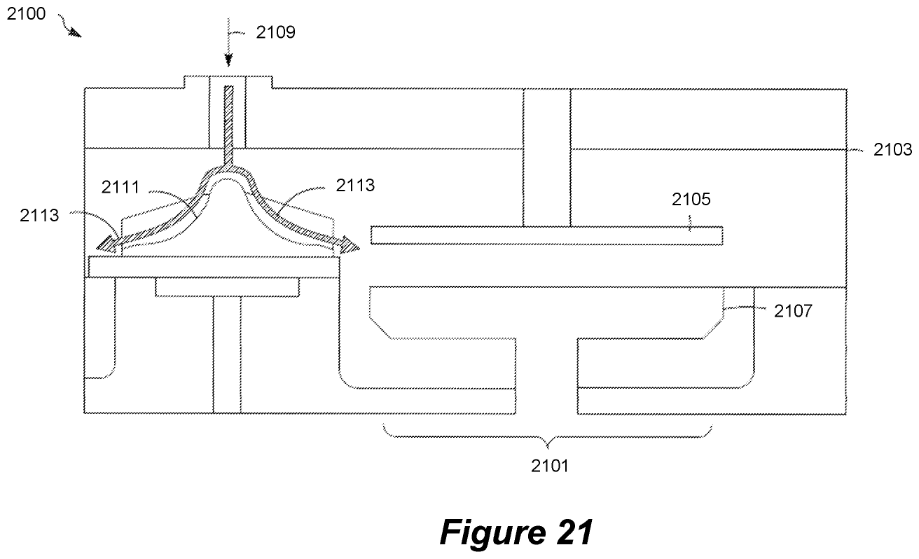

FIG. 21 shows a cross-section of one station of a multi-station processing tool using an example remote plasma device in accordance with some embodiments. The one station of the multi-station substrate processing tool 2100 may include a remote plasma cleaning device 2111 which may be fluidly coupled to a remote plasma source (not shown here), and a process chamber 2103. Each station may also include a showerhead 2105 and a pedestal 2107 configured to support a substrate (not shown in FIG. 21). The remote plasma cleaning device 2111 may be configured to direct the plasma activation species (e.g., fluorine-containing species or fluorine species) into a volume (e.g., microvolume) between the showerhead 2105 and the pedestal 2107. The plasma activation species may be generated in the remote plasma source by receiving a process gas described herein from a first process gas supply (not shown here) and igniting a plasma. In some embodiments, the remote plasma cleaning device 2111 may be positioned above the showerhead 2105 to deliver the fluorine-containing species in a downward direction. In some embodiments, the fluorine-containing species may be configured to deliver the fluorine-containing species in an upward direction.

In some embodiments, the fluorine-containing species may be supplied from the remote plasma source positioned upstream of the remote plasma cleaning device 2111. The fluorine-containing species may enter the process chamber 2103 of the multi-station processing tool 2100 via a process-gas inlet 2109 that is fluidly coupled to the remote plasma source (not shown here). The fluorine-containing species may then split into substantially uniform flows 2113 on either side of the remote plasma cleaning device 2111, and transport to various locations within the process chamber 2103.

In some embodiments, a thermal etchant described herein may be provided from a second process gas supply (not shown here) that is fluidly coupled to the process chamber 2103 to deliver the thermal etchant in the process chamber 2103. In some embodiments, the second process gas supply may be fluidly coupled to the remote plasma source.

Referring back to FIG. 7, a schematic illustration of an example process station that is suitable for depositing dielectric material (e.g., hafnium oxide) using ALD and/or CVD is shown. In some embodiments, either of ALD and/or CVD may be plasma enhanced. The process station 700 may be cleaned from a dielectric material such as metal containing oxides or metal containing nitrides deposited on the inner surfaces of the process chamber using methods provided herein. For simplicity, the process station 700 is depicted as a standalone process station having a process chamber 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below: may be adjusted programmatically by one or more computer controllers.

As described earlier herein, the process station 700 fluidly communicates with a reactant delivery system 701 for delivering process gases to a showerhead 706. The reactant delivery system 701 optionally includes a mixing vessel 704 for blending and/or conditioning process gases, for delivery to showerhead 706. One or more mixing vessel inlet valves 720 may control introduction of process gases to mixing vessel 704. Similarly, a showerhead inlet valve 705 may control introduction of processes gases to the showerhead 706. Where plasma exposure is used, plasma may also be delivered to the showerhead 706 or may be generated in the process station 700. In some embodiments, a remote plasma may be generated from the remote plasma source outside the process station 700. The remote plasma including fluorine species may be delivered from the remote plasma source (not shown) to the mixing vessel 704 via a gas line (not shown) to mix with other process gas, such as a thermal etchant described herein, or other reactants such as water vapor, methyl alcohol, ethyl alcohol, or propyl alcohol. The mixture may be introduced in the process chamber 702. In some embodiments, the remote plasma may be delivered via a separate gas line to the process chamber 702 without mixing with the thermal etchant or other reactants. In some embodiments, a remote plasma source in FIG. 20, or a portion or an entirety of the remote plasma cleaning device in FIG. 21 may be fluidly coupled to the process chamber 702 to provide a remote plasma.

FIG. 7 further includes an optional vaporization point 703 for vaporizing liquid reactant to be supplied to the mixing vessel 704, which is fluidly coupled with the process chamber 702. For example, a thermal etchant, e.g., boron bromide (BBr₃), phosphorous trichloride (PCl₃), carbon tetrachloride (CCl₄), nitrogen trichloride (NCl₃), or mixtures thereof, may be vaporized at the optional vaporization point 703 prior to mixing with a remote plasma or being separately provided to the process chamber. The optional vaporization point 703 may also be configured to vaporize alcohol such as methyl alcohol, ethyl alcohol, or propyl alcohol. In some embodiments, a liquid flow controller (LFC) upstream of vaporization point 703 may be provided for controlling a mass flow of liquid for vaporization and delivery to process station 700. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 706 distributes process gases toward substrate 712. In the embodiment shown in FIG. 7, the substrate 712 is located beneath showerhead 706 and is shown resting on a pedestal 708. Showerhead 706 may have any suitable shape, and may have any suitable number and arrangement of ports for distributing process gases to substrate 712.

In some embodiments, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. The use of microvolume significantly reduces the cycle time because of faster purge, and higher precursor partial pressure in the microvolume,

In some embodiments, pedestal 708 may be raised or lowered to expose substrate 712 to a volume between the substrate 712 and the showerhead 706. It will be appreciated that, in some embodiments, pedestal height may be adjusted programmatically by a suitable computer controller 750. In some embodiments, the showerhead 706 may have multiple plenum volumes with multiple temperature controls.

In some embodiments, pedestal 708 may be temperature controlled via heater 710. In some embodiments, the pedestal 708 may be heated to a temperature of about 50 to about 650° C., or about 50 to about 450° C. during non-plasma thermal exposure as described in disclosed embodiments. In some embodiments, the heater 710 of the pedestal 708 may include a plurality of independently controllable temperature control zones.

Further, in some embodiments, pressure control for process station 700 may be provided by a butterfly valve (or gate valve) 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to the process station 700.

In some embodiments, a position of showerhead 706 may be adjusted relative to pedestal 708 to vary a volume between the substrate 712 and the showerhead 706. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Where plasma may be used, for example in operations for depositing a dielectric material on the substrate, showerhead 706 and/or pedestal 708 electrically communicate with a radio frequency (RF) power supply 714 and matching network 716 for powering a plasma. Thus, one or both of the showerhead 706 and the pedestal 708 may be powered for plasma generation. In some embodiments, the plasma energy may be controlled by controlling one or more of a process station pressure, a gas concentration, an RF source power, an RF source frequency, and a plasma power pulse timing. For example, RF power supply 714 and matching network 716 may be operated at any suitable power to form a plasma having a desired composition of radical species. Examples of suitable powers are up to about 1000 W.

In some embodiments, instructions for a controller may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more process station parameters may be included in a recipe phase. For example, a recipe phase may include instructions for setting a flow rate of one or more fluorine-containing process gases, or a Br or Cl containing thermal etchant, such as HCl, HBr, or BCl₃, and time delay instructions for the recipe phase. In some embodiments, the controller may include any of the features described below with respect to system controller 850 of FIG. 8.

Referring back to FIG. 8, a schematic illustration of an example multi-station processing tool suitable for depositing and removing a dielectric film in accordance with some embodiments is shown. In some embodiments, one or more hardware parameters of the process tool 800 including those discussed in detail below may be adjusted programmatically by one or more computer controllers 850.

A process station may be configured as a module in a cluster tool. FIG. 8 depicts a semiconductor process cluster tool architecture with vacuum-integrated deposition modules suitable for implementation of the deposition and etching operations described herein. Such a cluster process tool architecture can include a remote plasma source as described herein.

FIG. 8 also shows a schematic view of an embodiment of a multi-station processing tool 800 with an inbound load lock 802 and an outbound load lock 804, either or both of which may include a remote plasma source. A robot 806 at atmospheric pressure is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 includes a remote plasma source, the wafer may be exposed to a remote plasma treatment to treat the substrate surface in the load lock prior to being introduced into a processing chamber 814. A remote plasma generated from the remote plasma source may be supplied to each process station (described below) for cleaning the interior surfaces according to methods described herein. In some embodiments, the remote plasma source may be fluidly coupled to a first process gas supply (not shown here) to receive a process gas from the first process gas supply, and a second process gas supply (not shown here) to receive a thermal etchant from the second process gas supply. The second process gas supply may also be fluidly coupled to each process chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the process station on a pedestal of a first station shown in the process station for processing. While the embodiment depicted in FIG. 8 includes load locks, it will be appreciated that, in some embodiments, direct entry of a wafer into a process station may be provided.

The depicted processing chamber 814 includes four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between thermal and plasma process modes. Additionally or alternatively, in some embodiments, processing chamber 814 may include one or more matched pairs of thermal and plasma process stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog, and/or digital input/output connections, stepper motor controller boards, etc.

In some embodiments, system controller 850) controls all of the activities of process tool 800. In some embodiments, parameters adjusted by system controller 850) may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

In some embodiments, the system controller 850 may be configured with instructions to perform the following operations: provide, in the process chamber 814, a semiconductor substrate to form a dielectric material on the one or more features on the substrate: remove forming the dielectric material on the substrate; remove the semiconductor substrate from the process chamber 814, wherein dielectric material is formed on one or more internal surfaces of the processing chamber 814: expose, without the semiconductor substrate in the processing chamber 814, the one or more internal surfaces of the processing chamber 814 to a fluorine-containing species to form a non-volatile reaction product; and expose, without the semiconductor substrate in the processing chamber 814, the one or more internal surfaces of the processing chamber 814 to a thermal etchant to convert the non-volatile reaction product to a volatile reaction product. In some embodiments, the system controller 850 may be further configured with instructions to introduce the fluorine-containing species and the thermal etchant into the process chamber as a co-flow or a cyclic flow. Additional aspects of the system controller 850 of FIG. 8 are described earlier herein and not repeated here. A controller as described above with respect to any of FIG. 7, 8, 20, or 21 may be implemented with the tool in FIG. 8.

### Prevention of Aluminum Fluoride Re-Deposition on a Showerhead During Clean

In some embodiments, semiconductor device manufacturing typically involves various deposition processes to deposit one or more silicon-containing films to form integrated circuits and related devices by various methods including CVD, PECVD. ALD, or PEALD. A consequence of the deposition process is that one or more silicon-containing materials are not only deposited on a substrate where the various materials are to be deposited, but also on interior surfaces of the process chamber in which deposition processes occur. Consequently, films from the various materials are formed on the interior surfaces of the process chamber, and the materials may accumulate over time to form a deposition byproduct. The deposition byproduct may include a silicon-based material, e.g., silicon oxide, silicon carbide, or silicon nitride. The deposition byproduct may dissolve, detach, thermally desorb, or evaporate through subsequent processes in the process chamber causing contamination of a substrate or features formed on a substrate. This contamination is one reason for low production yield/throughput, or device reliability issue. Deposition byproducts accumulated on the internal surfaces of the process chamber are periodically removed to avoid the contamination of the process chamber.

One way of removing contaminants in the process chamber is to introduce a plasma flow including fluorine (F)-containing species. For this type of cleaning, one or more source gases (e.g., cleaning gases) including nitrogen fluoride (NF₃), carbon tetrafluoride (CF₄), carbon hexafluoride (C₂F₆), octafluoropropane (C₃F₈), and other fluorine-containing compounds (i.e., fluorine-containing reactants), may be used. One or more source gases may be supplied to a plasma source. The plasma source may be an inductively coupled plasma reactor, a capacitively coupled plasma reactor, a microwave plasma reactor, a DC plasma reactor, or a laser-created plasma reactor. A plasma flow generated from the plasma source may flow into the process chamber to clean interior surfaces of the process chamber. The plasma flow may include fluorine-containing species (encompassing fluorine-based radicals), oxygen-containing species (encompassing oxygen-based radicals), and an inert gas. Examples of such F-containing clean processes are described above with reference to FIGS. 12-21.

Aluminum fluoride may be formed on the surface regions of internal part(s) or internal wall(s) made of aluminum or aluminum containing material by the reaction between aluminum and fluorine-containing species introduced for a plasma cleaning. Aluminum fluoride may be deposited on the wall at low temperature, and may thermally desorb above about 450° C. Aluminum fluoride may be aluminum trifluoride (AlF₃) and may cause contamination of the substrate or features of the substrate in subsequent processes. In some cases, the aluminum trifluoride is a gaseous contaminant that diffuses to the showerhead and may deposit/adsorb on the showerhead, thereby causing contamination of the substrate or features of the substrate in subsequent processes.

One aspect of the embodiments relates to a method of cleaning a process chamber by providing a plasma flow into the process chamber at a predetermined temperature described herein. The plasma source is fluidly coupled to the process chamber via a showerhead. The plasma flow may have a sufficient flow rate to prevent diffusion of a gaseous contaminant from reaching one or more locations of the process chamber. The plasma flow from a plasma source may include fluorine-containing species. Fluorine-containing species in the plasma flow may react with the deposition byproducts, removing the deposition byproduct from the on the internal surfaces of the process chamber. A gaseous byproduct may be generated as a result of the reaction between the fluorine-containing species and the deposition byproducts. The gaseous byproduct may be removed out of the process chamber.

Another aspect of the embodiments relates to a method of preventing contamination of a showerhead in the process chamber by introducing a plasma flow including fluorine-containing species. While fluorine-containing species removes silicon-based deposition products from the internal surfaces of the process chamber, fluorine-containing species may react with aluminum in the aluminum containing parts, and form aluminum fluoride such as aluminum trifluoride (AlF₃). By keeping the process chamber temperature at a predetermined temperature, aluminum fluoride may thermally desorb from the surface to be in a gaseous phase. The plasma flow with a sufficient flow rate may prevent gaseous aluminum fluoride from arriving at the surface of the showerhead, keeping the showerhead surface substantially aluminum fluoride free. The chamber cleaning and preventing the contamination of the showerhead may be achieved by providing a plasma flow according to some embodiments. This can occur at the predetermined temperature. A substrate may be transferred into the chamber for depositing a film at the predetermined temperature without modifying the process chamber temperature.

Referring back to FIG. 16, a schematic illustration of an example plasma processing apparatus according to some embodiments is shown. It will be understood that the plasma processing apparatus in FIG. 16 may be used to deposit a film by ALD, PEALD, CVD, or PECVD, and/or to clean the process chamber by delivering a plasma flow according to some embodiments. The process chamber (or “chamber”) cleaning of the present disclosure may include delivering a plasma flow containing fluorine-containing species to remove deposition byproducts from one or more surface regions of inner parts or inner surfaces of a plasma processing apparatus, and to limit diffusion of gaseous contaminants from a specific location within the process chamber. In some embodiments, the apparatus in FIG. 16 may be used to deposit a film by remote plasma CVD and also may be used to clean the process chamber by providing a plasma flow containing fluorine-containing species.

According to some embodiments, a plasma flow generated from a remote plasma source may be supplied into a process chamber after a substrate is removed from the process chamber. The process chamber may be kept at a predetermined temperature. The plasma flow including fluorine-containing species may be delivered at a sufficient flow rate to clean the internal surfaces of the process chamber by reacting with deposition byproducts while substantially preventing a gaseous contaminant (e.g., gaseous aluminum fluoride) in the process chamber from re-depositing on the surface of a showerhead in the process chamber. As a result, the showerhead surface may be maintained substantially aluminum fluoride free. A substrate may be transferred into the process chamber for depositing a film on the substrate. Deposition of the film on the substrate may occur prior to or after the chamber cleaning. The chamber cleaning (including preventing showerhead contamination) and the film deposition may be performed sequentially without changing the process chamber temperature and/or without exposing the substrate to ambient atmosphere. In some embodiments, the chamber cleaning and the film deposition may be repeated without changing the process chamber temperature. The process chamber temperature may be the temperature in the environment adjacent to the substrate. In some instances, the process chamber temperature corresponds to the pedestal temperature.

The plasma processing apparatus 1600 in FIG. 16 includes a remote plasma source 1602 separated from a process chamber 1604. The remote plasma source 1602 is fluidly coupled with the process chamber 1604 via a gas distributor or a showerhead 1606. A coil 1628 may be arranged around the remote plasma source 1602, where the remote plasma source 1602 includes an outer wall (e.g., ceramic dome). In some embodiments, the remote plasma source 1602 includes an outer wall that comprises a ceramic material resistant to fluorine-containing species. The outer wall may be a semicircle shape or an oval shape. In some embodiments, the outer wall may be made of ceramic material. The coil 1628 is electrically coupled to a plasma generator controller 1632, which may be used to form and sustain plasma within a plasma region 1634 via an inductively coupled plasma generation, a capacitively coupled plasma generation, a microwave plasma generation, a DC plasma generation, or a laser-created plasma generation. In some embodiments, the plasma generator controller 1632 may include a power supply for supplying power to the coil 1628, where the power can be in a range between about 500 watts (W) and about 15 kilowatts (KW) per station, or between about 2 kW and about 10 KW per station during plasma generation. In some embodiments, electrodes or antenna for parallel plate plasma generation, an inductively coupled plasma generation, a capacitively coupled plasma generation, a microwave plasma generation, a DC plasma generation, or a laser-created plasma generation may be used to generate a continuous supply of radicals via plasma excitation. In some embodiments, radicals and/or ions may be generated by inductively coupled plasma generation. In some embodiments, radicals and/or ions may be generated by a microwave plasma, a direct current (DC) plasma, or a laser-created plasma. Regardless of the mechanism used to ignite and sustain the plasma in the plasma region 1634, radical species may continuously be generated using plasma excitation.

A supply of ions and radicals may be continuously generated within the plasma region 1634 while one or more source gases are being supplied to the remote plasma source 1602. Ions generated in the plasma region 1634 may be filtered out by the ion filter of the showerhead 1606. That way, radicals generated in the plasma region 1634 may be supplied to a substrate 1612 in the process chamber 1604 while limiting ion bombardment. Conditions in the remote plasma source 1602, including a composition of the source gas provided to the remote plasma source 1602 and RF power supplied to the coil 1628, may be controlled to optimize generation of desired radical species in the plasma region 1634.

In FIG. 16, a source gas supply 1636 is fluidly coupled with the remote plasma source 1602 for supplying the source gas. In some embodiments, one or more source gases may include an oxygen-containing reactant such as oxygen (O₂), carbon dioxide (CO₂), or nitrogen dioxide (NO₂), fluorine-containing reactant such as nitrogen trifluoride (NF₃), fluorine (F₂), carbon tetrafluoride (CF₄), or carbon hexafluoride (C₂F₆), hydrogen-containing reactant such as hydrogen (H₂) or methane (CH₄), inert gas such as argon (Ar), or nitrogen-containing reactant such as nitrogen (N₂), ammonia (NH₃), diazene (N₂H₂), or hydrazine (N₂H₄), carbon-containing reactant such as acetylene (C₂H₂), or propene (C₃H₆), or mixtures thereof.

It is to be understood that a mixture of source gases for film deposition may not be the same as a mixture of source gases for chamber cleaning. The films to be deposited may be a silicon based film including doped or undoped silicon carbide, e.g., oxygen doped silicon carbide (SiCO), nitrogen doped silicon carbide (SiCN), and nitrogen and oxygen doped silicon carbide (SiOCN). For many, doped silicon carbides have at most about 50% atomic of dopant atoms, whether those atoms are oxygen, nitrogen, or atoms of another element. The doping level provides desired film properties. The silicon based film may also include silicon oxide (SiOx), silicon nitride (SixNy), or oxygen doped silicon nitride (SiON). A gas mixture supplied to the remote plasma source for film deposition process may include, but not limited to oxygen (O₂), carbon dioxide (CO₂), nitrogen dioxide (NO₂), hydrogen (H₂), methane (CH₄), argon (Ar), nitrogen (N₂), ammonia (NH₃), diazene (N₂H₂), hydrazine (N₂H₄), acetylene (C₂H₂), propene (C₃H₆), or mixtures thereof.

A gas mixture for chamber cleaning may include fluorine containing gas such as nitrogen trifluoride (NF₃), fluorine (F₂), carbon tetrafluoride (CF₄), or carbon hexafluoride (C₂F₆). For example, a gas mixture may include but not limited to nitrogen trifluoride (NF₃), fluorine (F₂), oxygen (O₂), carbon dioxide (CO₂), nitrogen dioxide (NO₂), hydrogen (H₂), argon (Ar), nitrogen (N₂), or mixtures thereof.

Types of radical species generated in the remote plasma source 1602 may be determined by the source gases supplied to the remote plasma source 1602. In some embodiments, depending on the nature of the source gases, a mixture of radical species including hydrogen radicals (H*), nitrogen radicals (N*), oxygen radicals (O*), fluorine radicals (F*), amine radicals (NH*, NH₂*), carbon radicals (C*), or mixtures thereof may be generated in the plasma region 1634 under approximately steady-state conditions during steady-state film deposition or chamber cleaning as controlled by the plasma generator controller 1632, though transients may occur at the beginning and end of film deposition and/or chamber cleaning.

An additional gas supply 1638 is fluidly coupled with the remote plasma source 1602 for supplying the one or more additional gases. While the embodiment in FIG. 16 depicts the gas mixture of the source gas and the one or more additional gases being introduced through separate gas outlets, it will be understood that the gas mixture may be introduced directly into the remote plasma source 1602. That is, a pre-mixed dilute gas mixture may be supplied to the remote plasma source 1602 through a single gas outlet. The one or more additional gases can include a carrier gas. Non-limiting examples of additional gases may include helium (He), neon (Ne), argon (Ar), krypton (Kr), xenon (Xe), and nitrogen (N₂). The one or more additional gases may support or stabilize steady-state plasma conditions within the remote plasma source 1602 or aid in transient plasma ignition or extinction processes.

In some embodiments, a gas conduit from the gas source (not shown) through the source gas supply 1636 into the remote plasma source 1602, and/or a gas conduit from a gas source (not shown) through the additional gas supply 1638 into the remote plasma source 1602 may be designed to withstand high gas flow rate according to some embodiments.

In some embodiments, a co-reactant, which is not the primary silicon-containing precursor or a hydrogen radical, is introduced during the deposition reaction. In some embodiments, the plasma processing apparatus is configured to introduce the co-reactant through the source gas supply 1636 or the additional gas supply 1638, in which case the co-reactant is at least partially converted to plasma. Examples of such co-reactants include carbon dioxide (CO₂), carbon monoxide (CO), water (H₂O), methanol (CH₃OH), oxygen (O₂), ozone (O₃), nitrogen (N₂), nitrous oxide (N₂O), ammonia (NH₃), diazene (N₂H₂), methane (CH₄), ethane (C₂H₆), acetylene (C₂H₂), ethylene (C₂H₄), diborane (B₂H₆), and mixtures thereof. Such materials may be used as nitriding agents, oxidizers, reductants, etc.

Plasma-activated species 1642, such as excited nitrogen, hydrogen, carbon, oxygen, fluorine, and/or amine radicals, flow out of the remote plasma source 1602 and into the process chamber 1604 via the showerhead 1606. In some embodiments, plasma-activated species 1642 may be the plasma flow: Plasma-activated species 1642 within the showerhead 1606 and within the process chamber 1604 are generally not subject to continued plasma excitation therein. The showerhead 1606 may have a plurality of gas ports to diffuse the flow of plasma-activated species 1642 into the process chamber 1604. In some embodiments, the plurality of gas ports may be mutually spaced apart. In some embodiments, the plurality of gas ports may be arranged as an array of regularly spaced apart channels or through-holes extending through a plate separating the remote plasma source 1602 and the process chamber 1604. The plurality of gas ports may smoothly disperse and diffuse exiting radicals (including plasma-activated species 1642) from the remote plasma source 1602 into the deposition zone 1610 of the process chamber 1604 while filtering out ions. Once passing through the plurality of gas ports in the showerhead 1606, plasma-activated species 1642 (i.e., plasma flow) may flow further in a downward direction, or substantially downward direction. In some embodiments, a plasma flow may include fluorine-containing species and other plasma-activated species.

With the delivery of the plasma-activated species 1642 to the process chamber 1604 from the showerhead 1606, one or more silicon-containing precursors 1644 (or other process gases) may be introduced into the process chamber 1604 for depositing a silicon based film. The silicon-containing precursors 1644 may be introduced via gas outlets 1608, where the gas outlets 1608 may be fluidly coupled with a silicon-containing precursor supply source 1640. The gas outlets 1608 may include mutually spaced apart openings so that the flow of the silicon-containing precursors 1644 may be introduced in a direction parallel with the plasma-activated species 1642 flowing from the showerhead 1606. In some embodiments, the gas outlets 1608 may be located downstream from the showerhead 1606. In some embodiments, the gas outlets 1608 are part of the showerhead 1606 such as in a dual-plenum showerhead. The dual-plenum showerhead may provide separate outlets/passages for the plasma-activated species 1642 and the silicon-containing precursors 1644 to avoid mixing in the showerhead 1606. That way, the silicon-containing precursors 1644 may flow into the process chamber 1604 via the showerhead 1606 without exposure to plasma in the remote plasma source 1602. The gas outlets 1608 may be located upstream from the deposition zone 1610 and the substrate 1612. The deposition zone 1610 is located within the interior of the process chamber 1604 between the gas outlets 1608 and the substrate 1612. In some embodiment, a direct plasma may be formed in the process chamber. For generating a direct plasma, in some embodiments, a plasma processing apparatus may be provided or modified to include an upper electrode, a lower electrode, and an RF generating system that may generate and output an RF voltage to one of the upper electrode and the lower electrode while the other of the upper electrode and the lower electrode may be grounded or floating. In some embodiments, the RF generating system may include an RF voltage generator and a matching network. A direct plasma may include a fluorine-containing species and other plasma-activated species. In some embodiments, a direct plasma may be formed at a location near the showerhead.

In some embodiments, silicon-containing precursor may include at least one or more Si—Si bonds and/or at least one or more Si H bonds. Silicon-containing precursors suitable for use in accordance with disclosed embodiments may include: silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

In some embodiments, silicon-containing precursor may also include a halosilane. A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, 1-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursor may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino) silane (SiH₂(NHC(CH₃)₃)₂ (BTBAS), diisopropylaminosilane (DIPAS), tert-butyl silylcarbamate, SiH(CH₃)—(N(CH₃)₂)₂, SiHCl—(N(CH₃)₂)₂, (Si(CH₃)₂NH); and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In addition to silicon-containing precursors, the environment adjacent the substrate may include one or more radical species, preferably in a substantially low energy state. Radicals may include hydrogen radicals, nitrogen radicals, oxygen radicals, amine radicals, carbon radicals, or mixtures thereof. In some embodiments, all, or substantially all, or a substantial fraction of the hydrogen atom radicals can be in the ground state, e.g., at least about 90% or about 95% of the hydrogen atom radicals adjacent the substrate may be in the ground state. In some implementations, when the excited hydrogen atom radicals lose their energy, or relax, the excited hydrogen atom radical may become a substantially low energy state hydrogen atom radical or a ground state hydrogen atom radical. Hydrogen atom radicals in a substantially low energy state or ground state can be capable of selectively breaking Si—H and Si—Si bonds while generally preserving Si—O, Si—N, and/or Si—C bonds. In some implementations, process conditions may be provided so that excited hydrogen atom radicals lose energy or relax to form substantially low energy state or ground state hydrogen atom radicals.

In a film deposition process, a substantial fraction of the silicon-containing precursors 1644 may be prevented from mixing with plasma-activated species 1642 in the showerhead 1606 or adjacent to the showerhead 1606. In some embodiments, silicon-containing precursors 1644 may be delivered to the substrate 1612 in dose phases of ALD cycles separate from plasma-activated species 1642 delivered to the substrate 1612 during plasma exposure phases of the ALD cycles. Adsorbed silicon-containing precursors 1644 may react with radicals of the plasma-activated species 1642 during plasma exposure phases of the ALD cycles to deposit film. In some embodiments, silicon-containing precursors 1644 may be delivered to the substrate 1612 in a continuous manner to interact with plasma-activated species 1642 in a deposition zone 1610 to deposit a film by CVD. The radicals of the plasma-activated species 1642 may mix with the silicon-containing precursors 1644 in the gas phase during CVD formation of the film.

Gases may be removed from the process chamber 1604 via an outlet 1648 that is fluidly coupled to a pump (not shown). Thus, radical species or purge gases may be removed from the process chamber 1604.

The substrate 1612 is supported on a substrate support structure or wafer pedestal (i.e., pedestal) 1614. The pedestal 1614 may be configured with lift pins or other movable support members to position the substrate 1612 within a deposition zone 1610. The substrate 1612 may be moved to a position closer or farther from the showerhead 1606. The pedestal 1614 may also adjust the temperature of the substrate 1612 in some embodiments, which can provide some selective control over thermally activated surface reactions on the substrate 1612.

The pedestal 1614 may be prepared by ceramic materials. In one embodiment, the pedestal 1614 may be made of aluminum nitride, which may be suitable in a high temperature process, e.g., a plasma processing environment without causing any thermal damage to the pedestal 1614. Other surfaces of the process chamber 1604 may be formed of ceramic materials such as aluminum nitride.

In some embodiments, the pedestal 1614 includes an electrostatic chuck 1616. The electrostatic chuck 1616 may include one or more electrostatic clamping electrodes 1618 embedded within a body of the electrostatic chuck 1616. In some embodiments, the one or more electrostatic clamping electrodes 1618 may be coplanar or substantially coplanar. The electrostatic clamping electrodes 1618 may be powered by a DC power source or DC chucking voltage (e.g., between about 200 V to about 2000 V) so that the substrate 1612 may be retained on the electrostatic chuck 1616 by electrostatic attractive forces. Power to the electrostatic clamping electrodes 1618 may be provided via first electrical lines 1620. The electrostatic chuck 1616 may further include one or more heating elements 1622 embedded within the body of the electrostatic chuck 1616. The one or more heating elements 1622 may include resistive heaters. In some embodiments, the one or more heating elements 1622 are positioned below the one or more electrostatic clamping electrodes 1618. The one or more heating elements 1622 may be configured to heat the substrate 1612 to a temperature greater than about 450° C., greater than about 500° C., greater than about 550° C. greater than about 600° C., or greater than about 650° C. The one or more heating elements 1622 provide selective temperature control to the substrate 1612. Power to the one or more heating elements 1622 may be provided via second electrical lines 1624.

In some embodiments, a thermal shield (not shown) may be positioned underneath the pedestal 1614. The thermal shield serves as a thermal insulator under the pedestal 1614 to mitigate heat loss via thermal radiation, thereby reducing the amount of power needed to maintain the pedestal 1614 at a particular elevated temperature and also preventing other components within the process chamber 1604 from overheating due to excess heat radiated from the pedestal 1614. For example, the thermal shield may be radially offset from the stem 1626 and may have a thin annular-shaped body with a high view factor relative to the underside of the electrostatic chuck 1616. Thus, the annular-shaped thermal shield may reduce radiative heat loss from the pedestal 1614.

The controller 1650 may contain instructions for controlling process conditions for the operation of the plasma processing apparatus 1600. The controller 1650 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 1650 or they may be provided over a network.

In certain embodiments, the controller 1650 controls all or most activities of the plasma processing apparatus 1600 described herein. For example, the controller 1650 may control all or most activities of the plasma processing apparatus 1600 associated with film deposition and/or a chamber cleaning. In some embodiments, the controller 1650 includes a processor system 1652 (e.g., microprocessor) configured to execute instructions held in a data system 1654 (e.g., memory). In some embodiments, the controller 1650 may be in communication with the plasma generator controller 1632 to control plasma parameters and/or conditions in the remote plasma source 1602. In some embodiments, the controller 1650 may be in communication with the pedestal 1614 to control pedestal elevation (substrate position), electrostatic chucking and dechucking, and temperature. In some embodiments, the controller 1650 may control other processing conditions, such as RF power settings, frequency settings, duty cycles, pulse times, pressure within the process chamber 1604, pressure within the remote plasma source 1602, gas composition, and gas flow rates from the source gas supply 1636, gas composition, and gas flow rates from the additional gas supply 1638 and other sources, temperature of the pedestal 1614, and temperature of the process chamber 1604, among other processing conditions.

In some embodiments, the controller 1650 may include instructions configured to perform operations such as heating the process chamber 1604 to a predetermined temperature, delivering a plasma flow from the remote plasma source 1602 into the process chamber 1604 through the showerhead 1606, and limiting a gaseous contaminant from the showerhead 1606. In some embodiments, the plasma flow includes a fluorine-containing reactant such as nitrogen trifluoride. For example, the plasma flow includes an oxygen-containing species (encompassing oxygen-based radicals), a fluorine-containing species (e.g., fluorine-based radicals), and an inert gas. The inert gas may include nitrogen, argon, helium, neon, krypton, or mixtures thereof. In some embodiments, the predetermined temperature may range from about 450° C. to about 650° C.

In some embodiments, the controller 1650 may include instructions configured to perform operations such as introducing a first dose of a silicon-containing precursor 1644 in a vapor phase to adsorb on the substrate 1612, and exposing the substrate 1612 to plasma-activated species 1642 of a source gas generated in the remote plasma source 1602, where the adsorbed silicon-containing precursor 1644 reacts with the plasma-activated species 1642 to deposit a silicon-containing film. In some embodiments, the controller 1650 may include instructions configured to perform operations such as setting the chamber pressure in the process chamber 1604 to between 0.6 Torr and about 30 Torr, or about 1 Torr and about 30 Torr, and setting a substrate temperature to an elevated temperature between about 200° C. and about 700° C. In some embodiments, the controller 1650 may include instructions configured to perform operations such as applying a first voltage to the electrostatic chuck 1616 of the pedestal 1614 for electrostatically clamping the substrate 1612 in the process chamber 1604, reversing a polarity of the first voltage applied to the electrostatic chuck 1616, applying a second voltage to the electrostatic chuck 1616 that is less than the first voltage, reversing a polarity of the second voltage applied to the electrostatic chuck 1616, and removing the substrate 1612 from the electrostatic chuck 1616. In some embodiments, the controller 1650 may include instructions configured to perform chamber cleaning using the plasma flow containing the fluorine-containing reactant and film deposition on the substrate 1612 using the silicon-containing precursors 1644 and plasma-activated species 1642.

In some embodiments, the plasma processing apparatus 1600 may include a user interface associated with controller 1650. The user interface may include a display screen, graphical software displays of the plasma processing apparatus 1600 and/or process conditions, and user input devices such as pointing devices, keyboards, touch screens, microphones, etc. The computer program code for controlling the above operations can be written in any conventional computer readable programming language. Additional aspects of the controller 1650 are described earlier herein and not repeated here.

In some embodiments, a process chamber for an example plasma processing apparatus may be used, depending on a process recipe, to deposit a thin layer by any suitable deposition method such as ALD, PEALD, CVD, or PECVD, and/or to clean the interior surfaces of the process chamber according to embodiments herein.

In some embodiments, the process chamber may include a remote plasma source positioned on the top portion of the process chamber. The remote plasma source may be a dome, and include a coil around the remote plasma source. The remote plasma source may include a plasma region within the remote plasma source. The remote plasma source may be fluidly coupled to the process chamber via a showerhead.

In some embodiments, a source gas inlet may be positioned on the top of the remote plasma source while the source gas inlet may be positioned on other locations of the remote plasma source. The source gas inlet may be fluidly coupled to the remote plasma source to supply one or more source gases from one or more gas sources into the remote plasma source. Radical species such as nitrogen radicals, fluorine radicals, hydrogen radicals, oxygen radicals, argon radicals, carbon radicals, or mixtures thereof, may be generated in the plasma region to form a plasma flow. In some embodiments, where the chamber cleaning is necessary, a plasma flow including fluorine radicals may be generated. The plasma flow may flow in a downward direction or substantially downward direction through multiple gas ports in a showerhead. As used herein, a downward direction or substantially downward direction may refer to a direction that is perpendicular or substantially perpendicular to a major plane of the showerhead. The plasma flow may further flow down toward a pedestal spaced from the showerhead by a predetermined distance.

In some embodiments, the pedestal may include one or more heating elements embedded within the pedestal or thermally coupled to the pedestal. The heating elements may be coupled to a controller, and may be configured to heat a substrate supported on the pedestal to a temperature suitable for a process such as film deposition. The heating elements may also be operable in the absence of a substrate within the process chamber. The process chamber may further include an outlet for removing any gas out of the process chamber.

In some embodiments, a controller may be coupled to one or more gas sources to control the flow rate of one or more source gases entering the remote plasma source. In some embodiments, the flow rate of the plasma flow flowing through the showerhead may be proportional to the flow rate of the source gases. As the flow rate of the source gases increases, the flow rate of plasma flow may also increase. In some embodiments, the plasma flow flowing through the showerhead may form a plasma volume extending from the showerhead to the pedestal. Depending on the surface area of the showerhead and the pedestal, the entire surface of the pedestal may be exposed to the plasma volume. With the plasma flow including fluorine-containing species, a material deposited on the pedestal may react with incoming flow of fluorine-containing species. In some embodiments, depending on the flow rate of the source gases (and corresponding plasma flow), the plasma flow contacting the surface of the pedestal may displace gas flow adjacent to the pedestal to other locations in the process chamber.

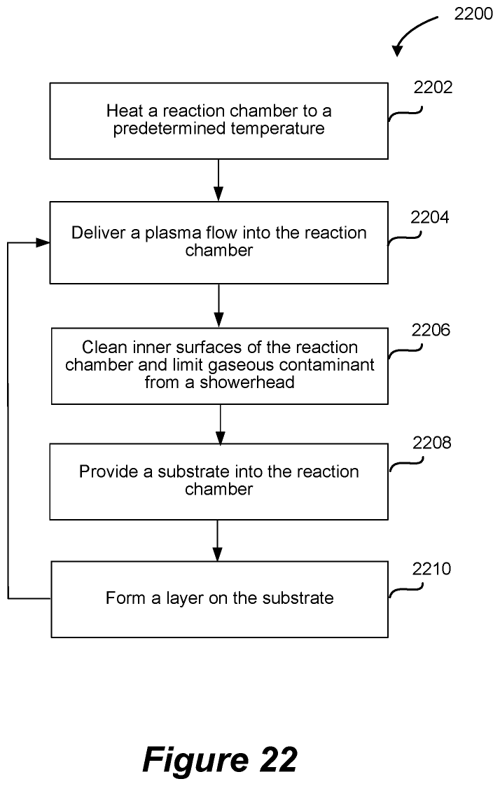

FIG. 22 presents a process flow diagram 2200 for cleaning a process chamber according to some embodiments. The process flow diagram 2200 describes some embodiments of cleaning an interior surface of the process chamber to remove chamber contamination, and subsequently depositing a substantially contamination-free film such as silicon based film. The process chamber cleaning may include delivering a high flow rate plasma flow including fluorine-containing species into the process chamber and limiting the contaminant flow away from a specific location within the process chamber. For example, the high flow rate plasma flow including fluorine-containing species limits the contaminant flow away from a showerhead. Two processing steps of cleaning the process chamber and depositing a silicon based film may be performed without substantially changing the process chamber temperature and/or the process chamber pressure. That way, chamber cleaning and deposition may be performed without introducing an air break in between operations. In some embodiments, the process chamber cleaning and a film deposition are performed while the process chamber temperature is maintained at a predetermined temperature.

Semiconductor fabrication processes include a cleaning process where films deposited on an inner surface of the process chamber or surface regions of internal parts are removed by supplying one or more etch compositions into the interior of the process chamber after a predetermined number of depositions. The etch compositions may contain fluorine-containing species, which may react with, for example, silicon-containing films on the wall to dissociate into gaseous etch byproduct. The process chamber includes internal parts or inner surfaces made from aluminum, anodized aluminum, and aluminum including alloy or ceramic material. In some embodiments, fluorine-containing species in the etch compositions may also react with aluminum to form aluminum fluoride on the surface of aluminum containing parts.

Aluminum fluoride may be gaseous or condensed depending on the temperature where aluminum fluoride is formed. Aluminum fluoride may thermally desorb from the pedestal above about 450° C., and transport to another location in the process chamber, and may be re-deposited at a different location as a condensed form (e.g., solid film or particle), creating another contamination source. Re-deposition may occur on the surface regions of an internal parts or inner surface of the process chamber. One internal part may be the showerhead. Aluminum fluoride may travel toward the showerhead and re-deposit on the showerhead surface. For example, needle-shaped aluminum fluoride flakes may be formed on the showerhead.

Re-deposited aluminum fluoride is undesirable in that it may be inadvertently deposited on one or more features of a semiconductor substrate in a subsequent process. During subsequent deposition or other substrate process, gaseous aluminum fluoride, or a mixture of gaseous aluminum fluoride and other reactants may be adsorbed on the features on a substrate. This may modify, for example, an electrical property or chemical composition of the film deposited in the subsequent deposition. As a result, a semiconductor device may have a likelihood of having a reliability issue due to unwanted impurities, or may not suitably function as designed. Aluminum fluoride re-deposited on the process chamber wall may flake off and fall onto the floor or other parts of the process chamber, and can be one source for chamber contamination.

Removal of aluminum fluoride from the surface of the process chamber may require additional steps including but not limited to cooling down the process chamber, disassembly, and cleaning. Also, aluminum fluoride deposit is relatively hard to remove. These additional steps may contribute to delayed processing time and correspondingly reduced throughput.

Prior to operation 2202, a substrate may be transferred out of the process chamber. Prior to removing the substrate, one or more films may be deposited on the substrate at a predetermined temperature. The process chamber temperature may be controlled by operating one or more heating elements within the pedestal or the electrostatic chuck that supports a substrate. In some embodiments, the process chamber temperature may be substantially identical to the substrate temperature. In some embodiments, the process chamber temperature may range between about 450° C. and about 650° C. or between about 500° C. and about 600° C. or between about 530° C. and about 570° C. The process chamber temperature may be kept until the chamber cleaning is complete. The one or more films may be a silicon-based layer. For example, the silicon based layer may include silicon oxide, silicon carbide, silicon oxycarbide, silicon carbonitride, or silicon oxycarbonitride. During the one or more film depositions, a film may also be formed on interior surfaces of the process chamber. For example, the film may be formed on the inner wall to form a deposition byproduct that may accumulate with deposition time. For example, the deposition byproduct may include silicon, e.g., silicon oxide, silicon carbide, or silicon nitride.

Where the process chamber temperature is below the predetermined temperature (e.g., the process chamber not in operation, etc.), the process chamber temperature may increase to a predetermined temperature in operation 2202. In some embodiments, the predetermined temperature may be determined based on the temperature above which a metal fluoride thermally desorbs. For example, aluminum fluoride may evaporate above about 450° C., and the predetermined temperature may range between about 450° C. and about 650° C. or between about 500° C. and about 600° C., or between about 530° C. and about 570° C. In some embodiments, the process chamber temperature may be increased to the predetermined temperature when depositing film on the substrate. The process chamber temperature may be increased prior to chamber cleaning at operation 2204.

In operation 2204, a plasma flow may be delivered to the process chamber. For this, one or more source gases are supplied to a remote plasma source to generate a plasma flow. As described herein, in some embodiments, the one or more source gases may include: oxygen-containing reactant such as oxygen (O₂), carbon dioxide (CO₂), or nitrogen dioxide (NO₂), fluorine-containing reactant such as nitrogen trifluoride (NF₃), fluorine (F₂), carbon tetrafluoride (CF₄), or carbon hexafluoride (C₂F₆), hydrogen-containing reactant such as hydrogen (H₂) or methane (CH₄), inert gas such as argon (Ar), or nitrogen-containing reactant such as nitrogen (N₂), ammonia (NH₃), diazene (N₂H₂), or hydrazine (N₂H₄), or mixtures thereof. In some embodiments, the source gases may include an oxygen-containing reactant, a fluorine-containing reactant, and an inert gas. Source gases may be supplied to the remote plasma source as a gas mixture, while separate gases may be provided to the remote plasma source. In some embodiments, the flow rate of the source gases to a remote plasma source range between about 1 and about 50 liters per minute (lpm), between about 1 and about 30 lpm, or between about 1 and about 20 lpm. In some embodiments, the process chamber temperature at operation 2204 may be configured to be the same as the temperature at operation 2202.

In some embodiments, plasma is generated in the remote plasma source. The plasma may include ions, radicals, and charged neutrals of the one or more source gases. The plasma may be generated using an inductively-coupled plasma (ICP) reactor, a capacitively-coupled plasma (CCP) reactor, a microwave plasma reactor, a DC plasma reactor, or a laser-created plasma reactor. For example, the plasma may be generated using an ICP reactor. The plasma generated in the remote plasma source may be delivered to the process chamber via the showerhead as a plasma flow.

A plasma flow generated from the remote plasma source may include hydrogen radicals, nitrogen radicals, oxygen radicals, fluorine radicals, amine radicals, argon radicals, or mixtures thereof. In some instances, the plasma flow includes at least fluorine radicals. In some embodiments, the process chamber pressure during the chamber cleaning by delivering a plasma flow may range from between about 0.6 Torr and about 30 Torr, or between about 1 Torr to about 30 Torr. The plasma flow may be supplied to the interior of the process chamber after the process chamber temperature reaches the predetermined temperature. In some embodiments, heating the process chamber and delivering a plasma flow may occur substantially concurrently.

In some embodiments, the remote plasma source may be positioned above the process chamber. A plasma flow generated above the process chamber may pass through a showerhead in a downward direction or substantially downward direction toward the pedestal. In other embodiments, a remote plasma source may be positioned at other location of the plasma processing apparatus. For example, a remote plasma source may be a sub-unit that is detachably bolted to the side of the plasma processing apparatus. The remote plasma source may be constructed such that a plasma flow from the remote plasma source may flow in a horizontal direction or in a diagonal direction, depending on the location of the remote plasma source relative to the showerhead, toward a showerhead. In one example, a plasma flow may be supplied transverse to the showerhead from a remote plasma source positioned at a side of the process chamber.

Once a plasma flow including fluorine radicals is delivered into the process chamber, fluorine radicals in the plasma flow may contact a deposition byproduct on the surface regions of internal parts or inner surfaces of the process chamber. Upon contact with the fluorine-containing species, the deposition byproduct may dissociate into a gaseous byproduct. The gaseous byproduct may transport within the process chamber until it is removed out of the process chamber via an outlet that is fluidly coupled to a pump.

In operation 2206, the deposition byproduct in the process chamber is etched away, and the transport of gaseous contaminant to the showerhead surface is prevented. In some embodiments, the gaseous contaminant includes a metal fluoride. In some embodiments, the gaseous contaminant includes aluminum fluoride. It is to be understood that, in some embodiments, the process chamber temperature at operation 2206 may be maintained to be substantially the same as the temperatures at operations 2202, 2204. For example, the process chamber temperature of between about 450° C. and about 650° C., between about 500° C. and about 600° C., or between about 530° C. and about 570° C. may be maintained to be substantially the same from the onset of operation 2202 until operation 2206 is complete.

When introduced into the process chamber through the showerhead, the plasma flow with a sufficient flow rate may contact the deposition byproduct on the inner surfaces of the process chamber. Fluorine-containing species may react with the deposition byproduct, and may generate a gaseous byproduct, such as silicon tetrafluoride (SiF₄).

The plasma flow may also react with aluminum in the aluminum containing part to form aluminum fluoride. For example, fluorine-containing species may react with the pedestal made of aluminum nitride to form aluminum fluoride on the pedestal surface. Depending on the process chamber temperature (or substrate temperature), either condensed or gaseous aluminum fluoride may form. In some embodiments, condensed aluminum fluoride may be converted to gaseous phase above a certain temperature. For example, aluminum fluoride may thermally desorb above about 450° C. The plasma flow may limit the diffusion of gaseous contaminant (e.g., aluminum fluoride) from the showerhead. The plasma flow may prevent gaseous aluminum fluoride from contaminating the surface of the showerhead, leaving the showerhead surface substantially contamination free.

In some embodiments, the flow rate of a plasma flow may be in a proportional relationship with the flow rate of the one or more source gases supplied to the remote plasma source. For example, the flow rate of a plasma flow may increase by increasing the flow rate of the source gases entering the remote plasma source. The velocity of a plasma flow may be configured to be greater than the velocity of gaseous aluminum fluoride that may be non-directional and random. In case a high flow rate plasma flow containing fluorine-containing species is supplied from the showerhead toward the pedestal at a predetermined temperature, diffusion of gaseous aluminum fluoride will be limited from entering into the plasma volume, and the showerhead would not be substantially exposed to gaseous aluminum fluoride.

In some embodiments, the flow rate of the one or more source gases may be at least 10 lpm, or at least 13 lpm, or at least 16 lpm. In some embodiments, the flow rate of the one or more source gases may be less than about 22 lpm, or less than about 25 lpm, or less than about 28 lpm. In some embodiments, the source gases may include nitrogen trifluoride with the flow rate of about 1-about 5 lpm, or about 1.5-about 4 lpm, or about 1.8-about 4 lpm, oxygen with the flow rate of about 3-10 lpm, or about 3.5-about 8 lpm, or about 4-about 7 lpm, argon with the flow rate of about 0-about 16 lpm, or about 0.01-about 10 lpm, or about 0.1-about 7 lpm, or mixtures thereof. In some embodiments, the flow rate of the source gases may be 1-about 50 lpm, or 1-about 30 lpm, or 1-about 20 lpm.

As gaseous aluminum fluoride may be limited in entering the volume of the plasma flow, a lower surface of the showerhead facing the pedestal may not be substantially exposed to the gaseous aluminum fluoride, and the showerhead surface may be maintained to be substantially contamination free after cleaning the chamber according to some embodiments for longer than 20 min, or 25 minutes, or 30 minute, or 40 minute, or 60 minutes. In some embodiments, cleaning the chamber according to some embodiments may not substantially require additional steps of chamber disassembly, cleaning, and chamber assembly to remove aluminum fluoride on the showerhead.

It is to be understood that the above flow rate ranges for the source gases may vary to achieve a substantially contamination free showerhead surface depending on the design of plasma processing apparatus. For example, the flow rate of the source gases may vary depending on the process chamber size, process chamber pressure, and/or process chamber temperature etc.

At operation 2208, after the showerhead is prevented from being contaminated by a gaseous contaminant (e.g., aluminum fluoride), a substrate may be provided into the process chamber from another chamber or another station for film deposition. The substrate may be supported on the pedestal for film deposition, and a silicon based film described herein may be deposited on the substrate. In some embodiments, the process chamber temperature at operation 2208 is set to be substantially the same as the temperature at operations 2202, 2204, and 2206. For example, the process chamber temperature may be between about 450° C. and about 650° C., or between about 500° C. and about 600° C., or between about 530° C. and about 570° C. In case a film deposition is performed prior to operation 2202, the process chamber temperature at operations 2202, 2204, 2206, and 2208 may be substantially the same as the temperature at the film deposition prior to operation 2202.

A film may be deposited on the substrate in the process chamber at operation 2210. The film such as doped or undoped silicon carbide and other films as described herein may be deposited by ALD, PEALD, CVD, PECVD, or any suitable deposition process. The films to be deposited may be a silicon based film including doped or undoped silicon carbide, e.g., oxygen doped silicon carbide (SiCO), nitrogen doped silicon carbide (SiCN), and nitrogen and oxygen doped silicon carbide (SiOCN). The silicon based film may also include silicon oxide (SiOx), silicon nitride (SixNy), or oxygen doped silicon nitride (SiON). During the deposition process at operation 2210, silicon-containing precursors may be flowed to the substrate. The silicon-containing precursors may react with remote plasma provided from the remote plasma source, where the Si—H bonds and/or Si—Si bonds in silicon-containing precursors may be broken and serve as reactive sites for forming bonds between the silicon-containing precursors in the deposited silicon based film. The broken bonds can also serve as sites for cross-linking during thermal processing conducted during or after deposition. Bonding at the reactive sites and cross-linking can form a primary backbone or matrix collectively in the resulting silicon carbide film.

The temperature in the environment adjacent to the substrate may be a deposition temperature that facilitates the deposition reaction. The deposition temperature may be sometimes limited by the application of the device containing a silicon based film. In some embodiments, the process chamber temperature at operation 2210 may be set to be substantially the same as the temperatures at operations 2202, 2204, 2206, and 2208, and may be between about 450° C. and about 650° C., or between about 500° C. and about 600° C., or between about 530° C. and about 570° C. In case a film deposition is performed prior to operation 2202, the process chamber temperature at operations 2202, 2204, 2206, 2208, and 2210 may be substantially the same as the temperature at the film deposition prior to operation 2202. The process chamber pressure may be any suitable pressure to produce reactive radicals in a process chamber. For example, the pressure may be between about 0.6 Torr and about 30 Torr, or about 1 Torr and about 30 Torr, such as in embodiments implementing an inductively coupled plasma.

One or more film depositions at operation 2210 may be performed before cleaning the interior of the process chamber with a plasma flow. For example, a film may be deposited on the substrate in the process chamber. The substrate may be exposed to the silicon-containing precursor, radical species, co-reactant, and/or carrier gas until a film with a certain thickness range is obtained. In some embodiments, the process chamber temperature during operation 2210) may be set to be the same as the predetermined temperature at operations 2202, 2204, 2206, and 2208. Therefore, from the onset of the heating the process chamber at operation 2202 until the completion of a film deposition at operation 2210, the process chamber temperature may not vary, instead may be kept at a predetermined temperature.

After film deposition at operation 2210, the substrate may be transferred out of the process chamber to another process chamber or another station module for the next processing step. Another substrate may be transferred into the process chamber for more film depositions. After performing a predetermined number of depositions, the process chamber may be cleaned according to some embodiments described herein. In one example, the process chamber temperature may be kept at the predetermined temperature after depositing one or more films at operation 2210. The process chamber cleaning process may begin by delivering a high flow rate plasma flow containing fluorine into the process chamber (operation 2204). As described above for operation 2204, the high flow rate plasma flow containing fluorine-containing species may be introduced from the remote plasma source into the process chamber via the showerhead to remove deposition byproduct and prevent gaseous contaminant (e.g., aluminum fluoride) from contaminating the showerhead. The process chamber temperature at operation 2204 may be maintained to be the same or substantially the same as the temperature operation 2210. As described herein, gaseous aluminum fluoride generated during the chamber cleaning is limited from the showerhead by the high flow rate plasma flow, leaving the showerhead surface substantially free of fluoride contamination.

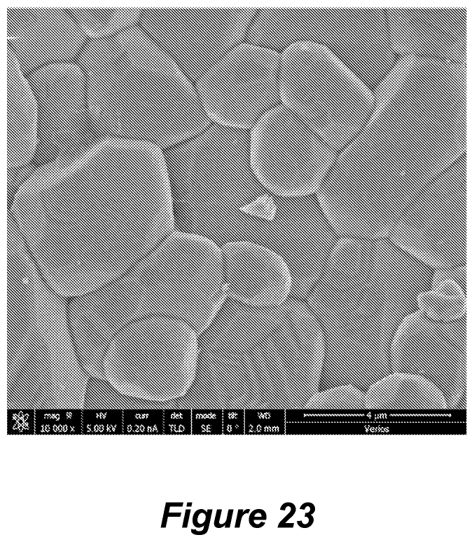

FIG. 23 is an image of a scanning electron micrograph (SEM) of a ceramic coupon positioned on a lower surface of a showerhead after chamber cleaning by a plasma flow according to some embodiments. The coupon was positioned on a center of the lower surface of the showerhead spaced from the pedestal with a predetermined spacing. A plasma flow was generated by a remote plasma source that is fluidly coupled with the process chamber through the showerhead and located upstream of the process chamber from an inductively coupled plasma generator such that the remote plasma source delivers a plasma flow to the process chamber. The flow rate for the source gases including fluorine to a remote plasma source was set to be about 15-about 22 lpm. The pedestal temperature was set between about 500° C. and about 600° C. The coupon was exposed to the plasma flow for about 10 hours before it was removed for identifying the presence of aluminum fluoride. As shown in FIG. 23, only grains are shown in the ceramic coupon. Substantially no sign of aluminum fluoride flakes or particles was observed. This indicates that providing a high flow rate plasma flow according to some embodiments is effective in substantially preventing the re-deposition of aluminum fluoride on the showerhead.

Having the surface regions of internal parts or inner walls of a process chamber cleaned by a plasma flow according to some embodiments has a plurality of advantages. At a suitable temperature between about 450° C. and about 650° C., or between about 500° C. and about 600° C., or between about 530° C. and about 570° C., a high flow rate plasma flow including fluorine-containing species generated from a remote plasma source may effectively limit diffusion of gaseous aluminum fluoride from a showerhead, thereby obtaining a substantially contaminant-free showerhead. Also, the process chamber cleaning by a plasma flow and subsequent deposition can be performed at the substantially same temperature without cooling down the process chamber for chamber cleaning. In addition, process chamber cleaning and subsequent film deposition may be performed using the same hardware without introducing new hardware components and without requiring disassembly of hardware components. Accordingly, increased throughput and reduced manufacturing time are achieved.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of forming a metal-containing layer on a semiconductor substrate, the method comprising:
performing at least one of:
(a) co-flowing a metal-containing precursor and a reactant into a processing chamber housing the semiconductor substrate; and
(b) after (a), flowing the reactant into a processing chamber housing the semiconductor substrate, wherein the reactant does not react with gas-phase metal-containing precursor.

2. The method of claim 1, wherein (b) comprises reacting surface-bound metal-containing precursor with the reactant in an absence of plasma to form a metal-containing layer on the semiconductor substrate.

3. The method of claim 2, wherein the formed metal-containing layer is a substantially carbon-free molybdenum-containing or tungsten-containing layer that has a carbon content of less than about 5 atomic %, wherein the layer is selected from the group consisting of a layer of molybdenum (Mo), tungsten (W), molybdenum nitride (MoN), tungsten nitride (WN), molybdenum oxynitride (MoON), tungsten oxynitride (WON), molybdenum boride (MoB), tungsten boride (WB), molybdenum silicide (MoSi), tungsten silicide (WSi), and combinations thereof.

4. The method of claim 1, wherein the metal-containing precursor is a halide-free, carbonyl-free compound that comprises at least one ligand, wherein the at least one ligand is bound to a metal selected from the group consisting of molybdenum and tungsten.

5. The method of claim 4, wherein the halide-free, carbonyl-free compound does not include metal-carbon bonds and metal-oxygen double bonds.

6. The method of claim 2, wherein the formed metal-containing layer has a carbon content of less than about 2 atomic %.

7. The method of claim 1, wherein the formed metal-containing layer is selected from the group consisting of Mo, MoN, and MoON.

8. A method of cleaning a process chamber, the method comprising:
flowing a fluorine-containing species into the process chamber, wherein the process chamber comprises a molybdenum-containing film formed on interior surfaces of the process chamber; and
flowing an oxygen-containing species into the process chamber with the fluorine-containing species cyclically or simultaneously to clean the process chamber, wherein the molybdenum-containing film is removed from the interior surfaces of the process chamber.

9. A method of cleaning a dielectric material from one or more components of a process chamber, the method comprising:
(a) introduce into the process chamber (i) a remote plasma containing a fluorine species, and (ii) a thermal etchant that undergoes a ligand exchange reaction with a fluorine-containing reaction product of the dielectric material to produce a volatile reaction product; and
(b) remove the volatile reaction product from the process chamber.

10. A method of cleaning a process chamber, the method comprising:
heating the process chamber to a predetermined temperature; and
delivering a plasma flow from a remote plasma source into the process chamber through a showerhead to clean the process chamber, wherein the remote plasma source is fluidly coupled with the process chamber through the showerhead and located upstream of the process chamber, wherein the plasma flow limits diffusion of a gaseous contaminant from the showerhead.
